(19) United States
(12) Patent Application Publication
(10) Pub. No.: US 2009/0159950 A1
(43) Pub. Date: Jun. 25, 2009

(54) Semiconductor Device and manufacturing Method of Semiconductor Device

(75) Inventors: Masayoshi Ishibashi, Tokyo (JP); Midori Kato, Asaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/338,113

(22) Filed: Dec. 18, 2008

(30) Foreign Application Priority Data
Dec. 20, 2007 (JP) JP2007-328747

(51) Int. Cl. H01L 29/788; H01L 21/3205

(52) U.S. Cl. 257/315; 438/593; 257/E29.3; 257/E21.295

(57) ABSTRACT

A conductor pattern including a gate electrode and an auxiliary pattern spaced apart by a narrow gap is formed on a substrate, an insulating film for a gate insulating film is formed so as to cover the same, a resist film is formed thereon, and the resist film is exposed from a back surface side of the substrate. In the exposure, the conductor pattern functions as a mask, but a resolution is reduced so that the resist film cannot resolve the dimension of the gap, whereby a portion corresponding to the gap is not formed in the resist pattern after development. By the lift-off method using the resist pattern, the source and drain electrodes aligned with the gate electrode are formed. The shape of the source and drain electrodes can be adjusted to an arbitrary shape by adjusting the shape of the auxiliary pattern.

### CROSS-REFERENCE TO RELATED APPLICATION

The present application claims priority from Japanese Patent Application No. JP 2007-328747 filed on Dec. 20, 2007, the content of which is hereby incorporated by reference into this application.

### TECHNICAL FIELD OF THE INVENTION

The present invention relates to a semiconductor device and a manufacturing method of the semiconductor device. In particular, it relates to a technique effectively applied to a thin film transistor formed on a translucent substrate and a manufacturing technique thereof.

### BACKGROUND OF THE INVENTION

With the development of the ubiquitous network in recent years, the importance of information terminal equipment that is easy to carry around has been increasing. For such information terminal equipment, not only the performance of information processing speed and display characteristic but also easiness in carrying around such as “thin and light” and “less likely to break on damage” are required. Therefore, in place of a glass substrate that is relatively heavy and likely to break used in the prior art, the use of a resin substrate that is light, flexible and less likely to break for a display element used in the information terminal equipment has been considered. However, the resin substrate is inferior to the glass substrate in the heat resistance, and thus is difficult to use in a conventional silicon process.

Therefore, as a fabricating technique for a transistor circuit capable of being fabricated at low temperature, a transistor circuit fabricating technique using an organic semiconductor has been studied. With the use of such a technique, the reduction of process temperature to about 150° C. which is lower than that of the silicon process can be achieved, so that a resin substrate with low heat resistance can be used. Further, since it can be fabricated through a printing technique in principle, the significant reduction in manufacturing cost can be expected.

International Publication WO 2005/024956 (Patent Document 1) and Japanese Patent Application Laid-Open Publication No. 2006-269709 (Patent Document 2) disclose a technique using the backside exposure.

### SUMMARY OF THE INVENTION

The studies by the inventors of the present invention have revealed the following.

The manufacturing process by the printing technique is inferior in processing dimension and alignment accuracy compared with the conventional silicon process generally using lithography and dry etching. In particular, alignment between wiring layers of the device is a large problem in the resin substrate because of the large heat distortion thereof.

In order to solve the problem of alignment that arises when fabricating the organic transistor circuit on the resin substrate, a method of fabricating a source-drain electrode whose position is aligned with the gate electrode by using the backside exposure and a photosensitive hydrophobic film is disclosed in International Publication WO 2005/024956 (Patent Document 1). In this method, light is irradiated onto the photosensitive hydrophobic film applied on the gate insulating film from the back surface side of the substrate to fabricate a hydrophobic region on the gate insulating film. Thereafter, a conductive electrode pattern is formed at a position other than the hydrophobic region by applying conductive ink. At this time, the gate electrode pattern functions as a photomask, and the hydrophobic film other than that immediately below the gate electrode is removed by photolithography. Therefore, the positions of the gate electrode and the source-drain electrode are automatically aligned.

When the above-described organic transistor circuit fabricating method by the self alignment using the backside exposure and the photosensitive hydrophobic film is used, advantages such as the automatic alignment of the positions of the gate electrode and the source-drain electrode and the reduction in the number of process steps can be achieved even if the substrate is heat distorted. However, in the method of International Publication WO 2005/024956 (Patent Document 1), the electric capacitance component is large because the gate electrode structure is special, and the deterioration of the semiconductor easily occurs because it is necessary to process the semiconductor into a stripe form by using the lithography technique so as to obtain a uniform channel width and the hydrophobic region of the base substrate needs to be processed. Furthermore, since “cross linkage action” and “non-penetration action” of the conductive ink are both used when fabricating the source-drain electrode, the pattern shape and the ink viscosity are limited.

Also, when two conductor patterns of different layers and intersecting in a plane are to be formed on the substrate, the conductor pattern on the side close to the substrate becomes a mask in a region where the two conductor patterns intersect if the backside exposure is simply used, and the conductor pattern on the side distant from the substrate cannot be satisfactorily formed. This limits the configuration of the transistor circuit formed on the substrate, and becomes a disadvantage for the miniaturization and higher performance of the semiconductor device.

Further, when the source-drain electrode is formed by using a photomask separately prepared in the backside exposure, the ends of the gate electrode can be aligned with the opposing ends of the source electrode and the drain electrode, but the outline position of the source-drain electrode may shift with respect to the gate electrode due to the shift in alignment between the photomask and the substrate in exposure. If the arrangement of the electrodes and the wirings on the substrate is designed in view of the shift, the semiconductor device enlarges (area increase) because of the necessity of margin. For the miniaturization (area reduction) of the semiconductor device, it is desirable that the opposing ends of the source electrode and the drain electrode are aligned with the ends of the gate electrode and the shift (variation) of the outline position of the source-drain electrode with respect to the gate electrode is suppressed as much as possible. Further, for higher performance of the semiconductor device, it is also desirable that the shift (variation) of the outline position of the source-drain electrode with respect to the gate electrode is suppressed as much as possible.

If accurate alignment between the photomask and the substrate is necessary in exposure, an expensive exposure device having an alignment mechanism is required, which increases the manufacturing cost of the semiconductor device.

An object of the present invention is to provide a technique capable of enhancing the performance of the semiconductor device.

Another object of the present invention is to provide a technique capable of miniaturizing the semiconductor device.

The above and other objects and novel characteristics of the present invention will be apparent from the description of this specification and the accompanying drawings.

The typical ones of the inventions disclosed in this application will be briefly described as follows.

A semiconductor device according to a representative embodiment comprises: a substrate; a first conductor pattern formed on the substrate and including a first pattern and a second pattern spaced apart from each other via a gap; an insulating film formed on the substrate so as to cover the first conductor pattern; and a second conductor pattern formed on the insulating film, wherein the second conductor pattern is formed in alignment with the first conductor pattern so as not to be planarly overlapped with the first conductor pattern obtained when the first pattern and the second pattern are coupled by removing the gap.

Also, in a manufacturing method of a semiconductor device according to another representative embodiment, after a first conductor pattern including a first pattern and a second pattern spaced apart from each other via a gap is formed on the substrate, an insulating film is formed on the substrate so as to cover the first conductor pattern, and then a first resist film is formed on the insulating film. Thereafter, the first resist film is exposed from a back surface side of the substrate and then the first resist film is developed, thereby forming a first resist pattern. The formed first resist pattern has a pattern shape corresponding to the first conductor pattern obtained when the first pattern and the second pattern are coupled by removing the gap. Then, a second conductor pattern is formed on the insulating film in a region not covered with the first resist pattern.

Also, in a manufacturing method of a semiconductor device according to another representative embodiment, after a first conductor pattern including a first pattern, a second pattern and a first connection pattern which connects the first and second patterns is formed on the substrate, an insulating film is formed on the substrate so as to cover the first conductor pattern, and then a first resist film is formed on the insulating film. Thereafter, the first resist film is exposed from a back surface side of the substrate and then the first resist film is developed, thereby forming a first resist pattern. The formed first resist pattern has a pattern shape corresponding to the first conductor pattern obtained when the first pattern and the second pattern are separated by removing the first connection pattern. Then, a second conductor pattern is formed on the insulating film in a region not covered with the first resist pattern.

The effects obtained by typical ones of the inventions disclosed in this application will be briefly described below.

According to a representative embodiment, performance of the semiconductor device can be enhanced.

In addition, the semiconductor device can be miniaturized.

### BRIEF DESCRIPTIONS OF THE DRAWINGS

FIG. 1 is a plan view showing the principal part of a thin film transistor of a first reviewed example;

FIG. 2 is a cross sectional view of the line A1-A1 of FIG. 1;

FIG. 3 is a plan view showing the principal part in the manufacturing process of a thin film transistor of a second reviewed example;

FIG. 4 is a cross sectional view of the line A2-A2 of FIG. 3;

FIG. 5 is a cross sectional view showing the manufacturing process of the thin film transistor continued from FIG. 4;

FIG. 6 is a plan view of a mask used in the exposure process of FIG. 5;

FIG. 7 is a plan view showing the principal part in the manufacturing process of the thin film transistor continued from FIG. 5;

FIG. 8 is a cross sectional view of the line A2-A2 of FIG. 7;

FIG. 9 is a plan view showing the principal part in the manufacturing process of the thin film transistor continued from FIG. 7;

FIG. 10 is a cross sectional view of the line A2-A2 of FIG. 9;

FIG. 11 is a plan view showing the principal part in the manufacturing process of the thin film transistor continued from FIG. 9;

FIG. 12 is a cross sectional view of the line A2-A2 of FIG. 11;

FIG. 13 is a plan view showing an example where a formed position of the semiconductor layer is shifted in a thin film transistor;

FIG. 14 is a plan view showing another example where a formed position of the semiconductor layer is shifted in a thin film transistor;

FIG. 15 is a circuit diagram showing an active matrix circuit;

FIG. 16 is a plan view showing the principal part in the manufacturing process of a semiconductor device according to a first embodiment of the present invention;

FIG. 17 is a cross sectional view of the line A3-A3 of FIG. 16;

FIG. 18 is a cross sectional view showing the principal part in the manufacturing process of the semiconductor device continued from FIG. 17;

FIG. 19 is a plan view of a mask used in the exposure process of FIG. 18;

FIG. 20 is a plan view of another mask used in the exposure process of FIG. 18;

FIG. 21 is a plan view showing the principal part in the manufacturing process of the semiconductor device continued from FIG. 18;

FIG. 22 is a cross sectional view of the line A3-A3 of FIG. 21;

FIG. 23 is a cross sectional view of the line B3-B3 of FIG. 21;

FIG. 24 is a plan view showing the principal part in the manufacturing process of the semiconductor device continued from FIG. 21;

FIG. 25 is a cross sectional view of the line A3-A3 of FIG. 24;

FIG. 26 is a cross sectional view of the line B3-B3 of FIG. 24;

FIG. 27 is a plan view showing the principal part in the manufacturing process of the semiconductor device continued from FIG. 24;

FIG. 28 is a cross sectional view of the line A3-A3 of FIG. 27;

FIG. 29 is a cross sectional view showing the principal part in the manufacturing process of the semiconductor device continued from FIG. 28;

FIG. 30 is a plan view showing the principal part in another manufacturing process of the semiconductor device according to the first embodiment of the present invention;

FIG. 31 is a cross sectional view of the line A4-A4 of FIG. 30;

FIG. 32 is a plan view showing the principal part in the manufacturing process of the semiconductor device continued from FIG. 30;

FIG. 33 is a cross sectional view of the line A4-A4 of FIG. 32;

FIG. 34 is a cross sectional view showing the principal part in the manufacturing process of the semiconductor device continued from FIG. 32;

FIG. 35 is a plan view of a mask used in the exposure process of FIG. 34;

FIG. 36 is a plan view of another mask used in the exposure process of FIG. 34;

FIG. 37 is a plan view showing the principal part in the manufacturing process of the semiconductor device continued from FIG. 34;

FIG. 38 is a cross sectional view of the line A4-A4 of FIG. 37;

FIG. 39 is a cross sectional view of the line B4-B4 of FIG. 37;

FIG. 40 is a plan view showing the principal part in the manufacturing process of the semiconductor device continued from FIG. 37;

FIG. 41 is a cross sectional view of the line A4-A4 of FIG. 40;

FIG. 42 is a cross sectional view of the line B4-B4 of FIG. 40;

FIG. 43 is a cross sectional view showing the principal part in the manufacturing process of a semiconductor device according to a second embodiment of the present invention;

FIG. 44 is a plan view showing the principal part in the manufacturing process of the semiconductor device continued from FIG. 43;

FIG. 45 is a cross sectional view of the line A5-A5 of FIG. 44;

FIG. 46 is a plan view showing the principal part in the manufacturing process of the semiconductor device continued from FIG. 44;

FIG. 47 is a cross sectional view of the line A5-A5 of FIG. 46;

FIG. 48 is a cross sectional view of the line B5-B5 of FIG. 46;

FIG. 49 is a cross sectional view of the line C5-C5 of FIG. 46;

FIG. 50 is a plan view showing the principal part in the manufacturing process of the semiconductor device continued from FIG. 46;

FIG. 51 is a cross sectional view of the line A5-A5 of FIG. 50;

FIG. 52 is a plan view showing the principal part in the manufacturing process of the semiconductor device continued from FIG. 50;

FIG. 53 is a cross sectional view of the line A5-A5 of FIG. 52;

FIG. 54 is a cross sectional view of the line B5-B5 of FIG. 52;

FIG. 55 is a cross sectional view of the line C5-C5 of FIG. 52;

FIG. 56 is an explanatory view showing a relationship between a film thickness of a resist film and minimum resolvable dimension of the resist film;

FIG. 57 is a plan view showing the principal part in the manufacturing process of the semiconductor device continued from FIG. 52;

FIG. 58 is a cross sectional view of the line A5-A5 of FIG. 57;

FIG. 59 is a cross sectional view of the line B5-B5 of FIG. 57;

FIG. 60 is a cross sectional view of the line C5-C5 of FIG. 57;

FIG. 61 is a plan view showing the principal part in the manufacturing process of the semiconductor device continued from FIG. 57;

FIG. 62 is a cross sectional view of the line A5-A5 of FIG. 61;

FIG. 63 is a plan view showing the principal part in the manufacturing process of a semiconductor device according to a third embodiment of the present invention;

FIG. 64 is a cross sectional view of the line A6-A6 of FIG. 63;

FIG. 65 is a plan view showing the principal part in the manufacturing process of the semiconductor device continued from FIG. 63;

FIG. 66 is a cross sectional view of the line A6-A6 of FIG. 65;

FIG. 67 is a cross sectional view of the line B6-B6 of FIG. 65;

FIG. 68 is a plan view showing the principal part in the manufacturing process of the semiconductor device continued from FIG. 65;

FIG. 69 is a cross sectional view of the line A6-A6 of FIG. 68;

FIG. 70 is a plan view showing the principal part in the manufacturing process of the semiconductor device continued from FIG. 68;

FIG. 71 is a cross sectional view of the line A6-A6 of FIG. 70;

FIG. 72 is a plan view showing the principal part in the manufacturing process of the semiconductor device continued from FIG. 70;

FIG. 73 is a cross sectional view of the line A6-A6 of FIG. 72;

FIG. 74 is a cross sectional view of the line B6-B6 of FIG. 72;

FIG. 75 is a plan view showing the principal part in the manufacturing process of the semiconductor device continued from FIG. 72;

FIG. 76 is a cross sectional view of the line A6-A6 of FIG. 75;

FIG. 77 is a cross sectional view of the line B6-B6 of FIG. 76;

FIG. 78 is a plan view showing the principal part in the manufacturing process of a semiconductor device according to a fourth embodiment of the present invention;

FIG. 79 is a partially enlarged plan view of FIG. 78;

FIG. 80 is a plan view showing the principal part in the manufacturing process of the semiconductor device continued from FIG. 78;

FIG. 81 is a partially enlarged plan view of FIG. 80;

FIG. 82 is a cross sectional view of the line A7-A7 of FIG. 80;

FIG. 83 is a cross sectional view of the line B7-B7 of FIG. 81;

FIG. 84 is a plan view showing the principal part in the manufacturing process of the semiconductor device continued from FIG. 80;

FIG. 85 is a partially enlarged plan view of FIG. 84;

FIG. 86 is a cross sectional view of the line A7-A7 of FIG. 84;

FIG. 87 is a cross sectional view of the line B7-B7 of FIG. 85;

FIG. 88 is a plan view showing the principal part in the manufacturing process of the semiconductor device continued from FIG. 84;

FIG. 89 is a cross sectional view of the line A7-A7 of FIG. 84;

FIG. 90 is a plan view showing the principal part in the manufacturing process of a semiconductor device according to a fifth embodiment of the present invention;

FIG. 91 is a partially enlarged plan view of FIG. 90;

FIG. 92 is a plan view showing the principal part in the manufacturing process of the semiconductor device continued from FIG. 90;

FIG. 93 is a cross sectional view of the line A8-A8 of FIG. 92;

FIG. 94 is a plan view showing the principal part in the manufacturing process of the semiconductor device continued from FIG. 90;

FIG. 95 is a partially enlarged plan view of FIG. 94;

FIG. 96 is a cross sectional view of the line A8-A8 of FIG. 94;

FIG. 97 is a cross sectional view of the line B8-B8 of FIG. 95;

FIG. 98 is a plan view showing the principal part in the manufacturing process of the semiconductor device continued from FIG. 94;

FIG. 99 is a partially enlarged plan view of FIG. 98;

FIG. 100 is a cross sectional view of the line A8-A8 of FIG. 98;

FIG. 101 is a cross sectional view of the line B8-B8 of FIG. 99;

FIG. 102 is a circuit diagram showing a ring oscillator;

FIG. 103 is a plan view showing the principal part in the manufacturing process of a semiconductor device according to a sixth embodiment of the present invention;

FIG. 104 is a cross sectional view of the line A9-A9 of FIG. 103;

FIG. 105 is a plan view showing the principal part in the manufacturing process of the semiconductor device continued from FIG. 103;

FIG. 106 is a cross sectional view of the line A9-A9 of FIG. 105;

FIG. 107 is a plan view showing the principal part in the manufacturing process of the semiconductor device continued from FIG. 105;

FIG. 108 is a cross sectional view of the line A9-A9 of FIG. 107;

FIG. 109 is a plan view showing the principal part in the manufacturing process of the semiconductor device continued from FIG. 107;

FIG. 110 is a cross sectional view of the line A9-A9 of FIG. 109;

FIG. 111 is a plan view showing the principal part in the manufacturing process of the semiconductor device continued from FIG. 109;

FIG. 112 is a cross sectional view of the line A9-A9 of FIG. 111;

FIG. 113 is a plan view showing the principal part in the manufacturing process of the semiconductor device continued from FIG. 111; and

FIG. 114 is a cross sectional view of the line A9-A9 of FIG. 113.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Hereinafter, embodiments of the present invention will be described in detail with reference to the accompanying drawings. Note that components having the same function are denoted by the same reference numbers throughout the drawings for describing the embodiments, and the repetitive description thereof will be omitted. Also, the description of the components having the same function is not repeated in principle unless particularly required in the following embodiments.

Also, in the drawings used in the embodiments, hatching is omitted in some cases even in a cross sectional view and hatching is applied in some cases even in a plan view so as to make the drawings easy to see.

### First Embodiment

A thin film transistor of a bottom gate structure reviewed by the inventors will be first described. The bottom gate structure mentioned here is a structure in which the gate electrode is positioned on the substrate side (i.e., lower layer side) compared with the source electrode and the drain electrode. On the other hand, the top gate structure is a structure in which the source electrode and the drain electrode are positioned on the substrate side (i.e., lower layer side) compared with the gate electrode.

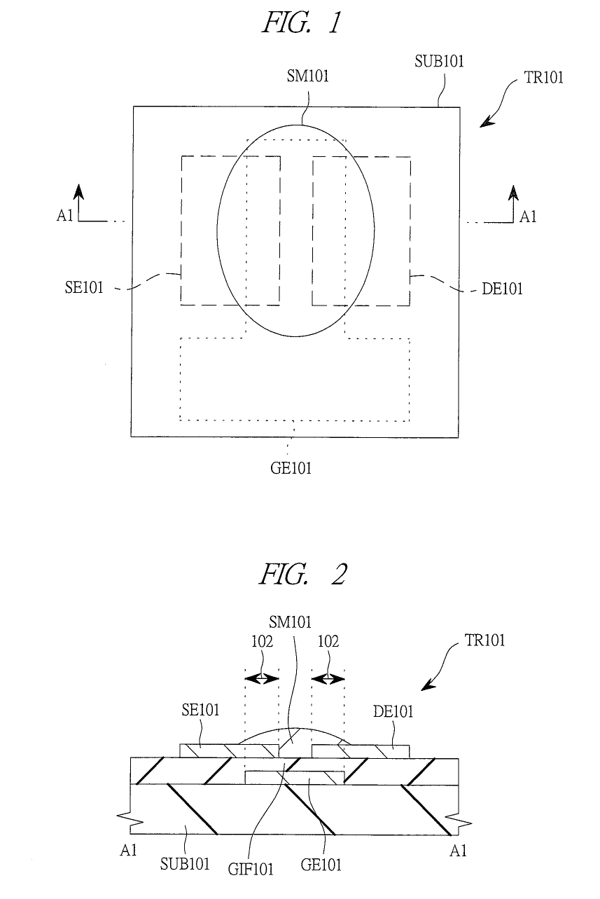

FIG. 1 is a plan view (plan view of principal part) showing a thin film transistor of a bottom gate structure of a first reviewed example reviewed by the inventors, and FIG. 2 is a cross sectional view thereof (cross sectional view of principal part). FIG. 2 substantially corresponds to the cross sectional view of the line A1-A1 of FIG. 1.

A thin film transistor TR101 of the bottom gate structure shown in FIGS. 1 and 2 has a structure in which a lowermost electrode layer having a gate electrode GE101, an upper electrode layer having a gate insulating film GIF101, a source electrode SE101 and a drain electrode DE101, and a semiconductor layer SM101 are stacked in this order from below on a substrate SUB101. The source electrode SE101 and the drain electrode DE101 are spaced apart from each other, and the space therebetween is filled with the semiconductor layer SM101. A channel region is formed in the semiconductor layer SM101 between the source electrode SE101 and the drain electrode DE101.

As shown in FIGS. 1 and 2, the thin film transistor of normal bottom gate structure has the gate electrode GE101, the source electrode SE101 and the drain electrode DE101 overlapped partially. More specifically, in the overlapping regions 102 shown in FIG. 2, the gate electrode GE101 is overlapped with the source electrode SE101 and the drain electrode DE101 when viewed in a plane (plane parallel to the main surface of the substrate SUB101).

The reason why the regions in which the gate electrode GE101 is overlapped with the source electrode SE101 and the drain electrode DE101 in a plane, that is, the overlapping regions 102 are produced is as follows. When fabricating the thin film transistor TR101 of the bottom gate structure, if the source electrode SE101 and the drain electrode DE101 are formed by using the normal lithography and printing technique, misalignment of the source electrode SE101 and the drain electrode DE101 (actually formed position is shifted from the originally intended forming position) occurs frequently. When the source electrode SE101 or the drain electrode DE101 is formed spaced apart from the gate electrode GE101, the thin film transistor TR101 may not properly operate as a transistor. Thus, the overlapping region 102 where the gate electrode GE101 is overlapped with the source electrode SE101 and the drain electrode DE101 in a plane needs to be provided at the design stage in view of the misalignment so that the thin film transistor TR101 can operate as a transistor even if misalignment occurs in forming the source electrode SE101 and the drain electrode DE101. When the overlapping region 102 is provided, even if the misalignment occurs in forming the source electrode SE101 and the drain electrode DE101, the source electrode SE101 or the drain electrode DE101 is not spaced apart from the gate electrode SE101, and the thin film transistor TR101 can operate as a transistor.

However, the overlapping region 102 causes the generation of electric capacitance that slows the operation speed of the thin film transistor TR101. More specifically, in the overlapping region 102, the gate electrode GE101 faces the source electrode SE101 and the drain electrode DE101 in proximity with interposing the gate insulating film GIF101 therebetween, so that parasitic capacitance is generated between the gate electrode GE101 and the source electrode SE101 and the drain electrode DE101, and the parasitic capacitance acts to slow the operation speed of the thin film transistor TR101. Thus, the overlapping region 102 is preferably as small as possible for higher performance.

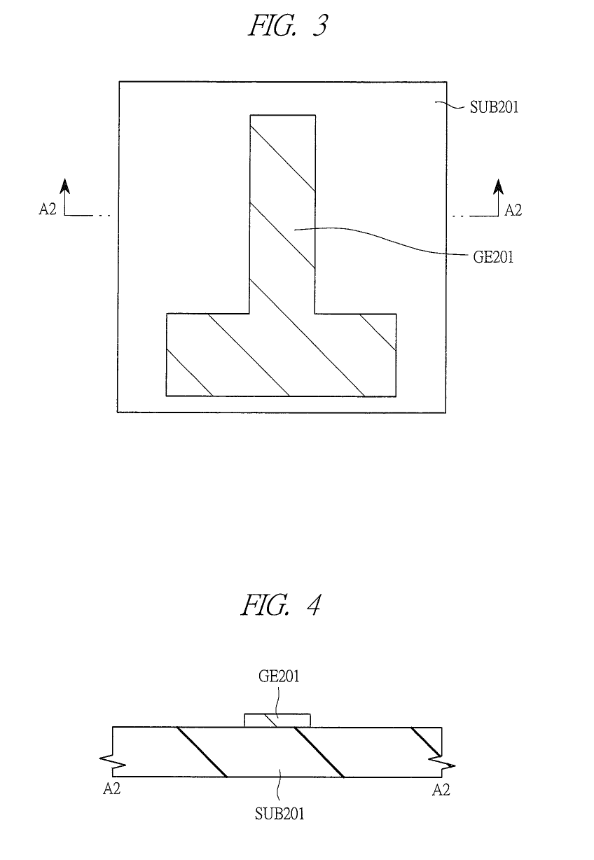

Next, a method of fabricating a thin film transistor TR201 reviewed by the inventors and having a structure in which the overlapping region 102 is scarcely formed will be described with reference to FIGS. 3 to 12.

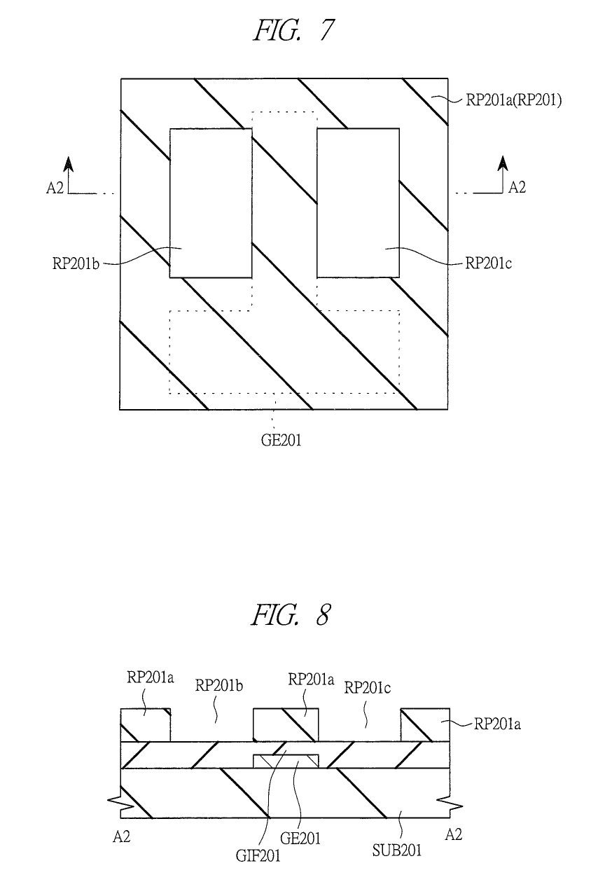

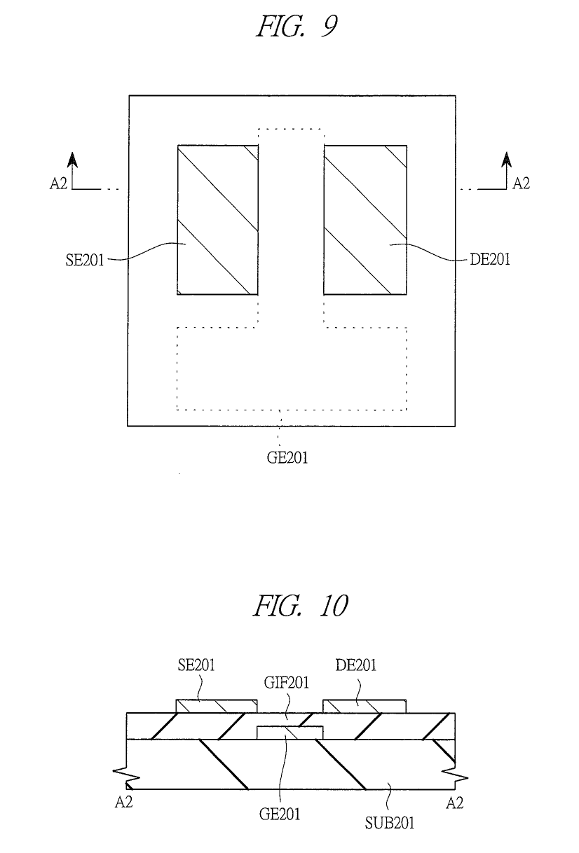

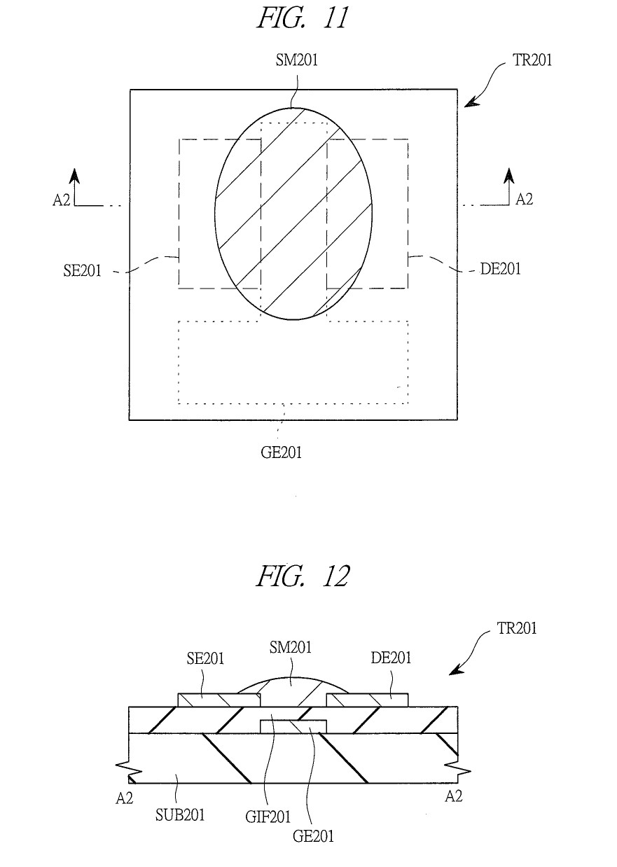

FIGS. 3 to 12 include plan views (plan view of principal part) and cross sectional views (cross sectional view of principal part) in the manufacturing process of the thin film transistor TR201 of the bottom gate structure of the second reviewed example reviewed by the inventors and a plan view of a mask MK201 used in the manufacturing process of the thin film transistor TR201. Of FIGS. 3 to 12, FIGS. 3, 7, 9 and 11 are plan views (plan view of principal part) in the manufacturing process of the thin film transistor TR201, FIGS. 4, 5, 8, 10 and 12 are cross sectional views (cross sectional views of principal part) in the manufacturing process of the thin film transistor TR201, and FIG. 6 is a plan view of the mask MK201. Further, FIGS. 3 and 4 correspond to the same processing step and the cross sectional view of the line A2-A2 of FIG. 3 corresponds to FIG. 4. FIGS. 7 and 8 correspond to the same processing step and the cross sectional view of the line A2-A2 of FIG. 7 corresponds to FIG. 8. FIGS. 9 and 10 correspond to the same processing step and the cross sectional view of the line A2-A2 of FIG. 9 corresponds to FIG. 10. FIGS. 11 and 12 correspond to the same processing step and the cross sectional view of the line A2-A2 of FIG. 11 corresponds to FIG. 12.

FIGS. 3, 6, 7, 9 and 11 are plan views, but in order to make the drawings easy to see, hatching is applied to the gate electrode GE201 in FIG. 3, to the light shielding region of the mask MK201 in FIG. 6, to the resist pattern RP201a in FIG. 7, to the source electrode SE201 and the drain electrode DE201 in FIG. 9, and to the semiconductor layer SM201 in FIG. 11.

As shown in FIGS. 3 and 4, a substrate SUB201 made of polyethylene telephtalate and the like is first prepared. After an aluminum film is formed on the substrate SUB201, the aluminum film is patterned by using the normal lithography technique and the etching technique to form the gate electrode GE201.

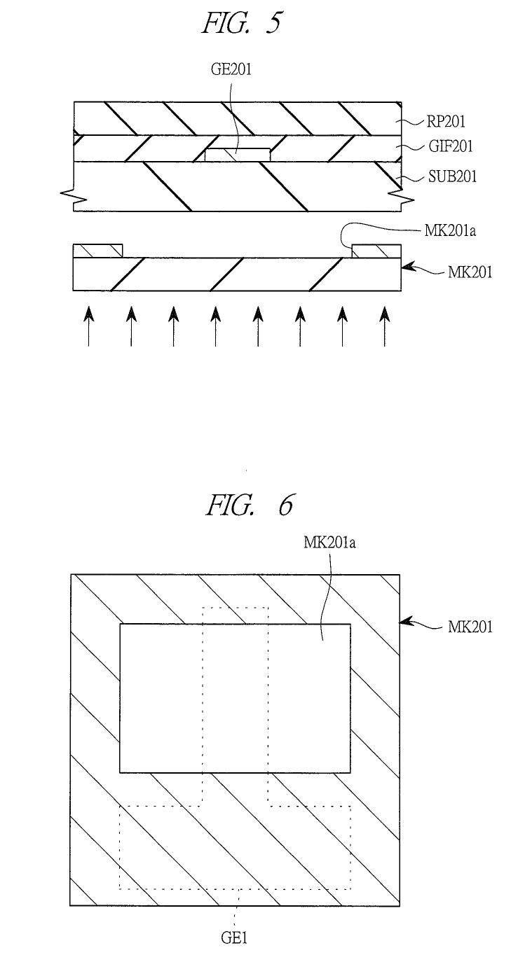

Next, as shown in FIG. 5, a gate insulating film GIF201 made of polyvinyl phenol and the like is formed on the entire surface of the substrate SUB201 so as to cover the gate electrode GE201. Then, a positive resist film RP201 is formed on the gate insulating film GIF201.

Next, the mask (photomask) MK201 for the source-drain electrode is disposed on the back surface side of the substrate SUB201, and the light is irradiated onto the substrate SUB201 from the back surface side of the substrate SUB201 to expose the resist film RP201. Hereinafter, the exposure performed by irradiating light from the back surface side of the substrate is also referred to as backside exposure. In FIG. 5, the light irradiated onto the substrate SUB201 from the back surface side of the substrate SUB201 in exposure is schematically shown with arrows.

As shown in FIG. 6, the mask MK201 has an opening MK201a, and has a function to pass the light through the opening MK201a and shielding the light at an area other than the opening MK201a. FIG. 6 is a plan view of the mask MK201, but hatching is applied to the light shielding portion of the mask MK201 to make the drawing easy to see, and the light passes through the portion (opening MK201a) to which no hatching is applied in the mask MK201 of FIG. 6. Further, the position of the gate electrode GE201 in exposure is shown with a dotted line in FIG. 6 so as to readily recognize the position of the opening MK201a of the mask MK201.

The substrate SUB201 and the gate insulating film GIF201 have translucency, and the light irradiated from the back surface side of the substrate SUB201 passes through the opening MK201a of the mask MK201 and is irradiated onto the resist film RP201 through the substrate SUB201 and the gate insulating film GIF201. In this case, the gate electrode GE201 formed of a metal film does not transmit light and functions as a mask. Therefore, the light passed through the opening MK201a of the mask MK201 and not shielded by the gate electrode GE201 is irradiated onto the resist film RP201.

Thereafter, the resist film RP201 is developed, so that the resist pattern RP201a is formed on the gate insulating film GIF201 as shown in FIG. 7.

The pattern shape of the opening MK201a of the mask MK201 is a shape in which the source electrode SE201 and the drain electrode DE201 formed later are connected (coupled) to one. By setting the shape of the opening MK201a of the mask MK201 to a desired arbitrary shape, the shape of the source electrode SE201 and the drain electrode DE201 formed later can be formed to the desired arbitrary shape. When performing the backside exposure through the mask MK201, not only the mask MK201 but also the gate electrode GE201 functions as the photomask, and the exposure region of the resist film RP201 is separated into the source electrode region RP201b and the drain electrode region RP201c by the gate electrode GE201. Thus, the overlapping region 102 is scarcely formed, and the position of the gate electrode GE201 is automatically aligned with the positions of the source electrode region RP201b and the drain electrode region RP201c. Since the resist film RP201 is a positive type, the resist pattern RP201a after development of FIG. 7 becomes the pattern in which the source electrode region RP201b and the drain electrode region RP201c corresponding to the region exposed in the step of FIG. 6 are opened.

Next, a metal film is formed on the entire surface of the substrate SUB201, that is, on the resist pattern RP201a and the gate insulating film GIF201 of the region not covered with the resist pattern RP201a, and then the resist pattern RP201a is dissolved and removed with organic solvent and the like. At this time, the metal film on the resist pattern RP201a is removed together. However, the metal film formed on the gate insulating film GIF201 exposed at the bottom of the opened region of the resist pattern RP201a remains without being removed, and becomes the source electrode SE201 and the drain electrode DE201 as shown in FIGS. 9 and 10.

By performing the so-called lift-off process as described above, the source electrode SE201 and the drain electrode DE201 are formed on the gate insulating film GIF201 of the region not covered with the resist pattern RP201a. Note that the source electrode SE201 is formed in the source electrode region RP201b, and the drain electrode DE201 is formed in the drain electrode region RP201c.

Thereafter, as shown in FIGS. 11 and 12, the semiconductor layer SM201 is formed on the gate insulating film GIF201 between the source electrode SE201 and the drain electrode DE201.

In this manner, as shown in FIG. 12, the thin film transistor TR201 in which the overlapping region (corresponding to overlapping region 102) of the gate electrode region GE201 and the source electrode SE201 and the drain electrode DE201 is scarcely formed and the position of the gate electrode GE201 is aligned with the positions of the source electrode SE201 and the drain electrode DE201 can be formed on the substrate SUB201.

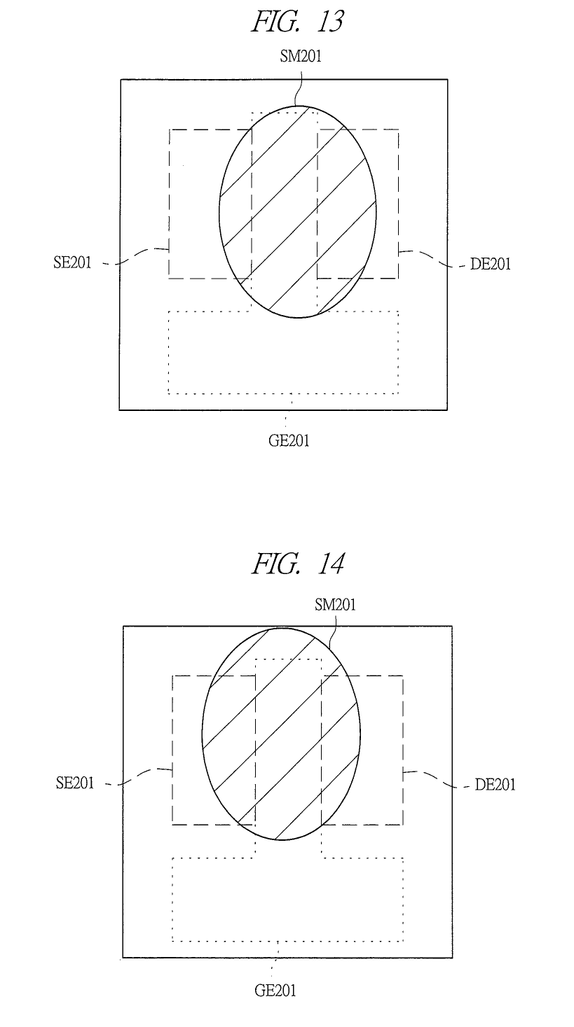

FIGS. 13 and 14 are plan views showing the case where the formed position of the semiconductor layer SM201 is shifted compared with FIG. 11, and the formed position of the semiconductor SM201 is shifted in different manners in the plan views of FIGS. 13 and 14.

In the thin film transistor TR201, the channel width is defined by the pattern shape of the source electrode SE201 and the drain electrode DE201, and the channel width is not changed even if the formed position of the semiconductor layer SM201 is shifted as shown in FIG. 13 and FIG. 14. Thus, even if the semiconductor layer SM201 is formed by using such means with poor placement accuracy (accuracy of application position) as the inkjet printing, the thin film transistor TR201 of uniform performance can be formed.

Next, a circuit using such a thin film transistor will be described.

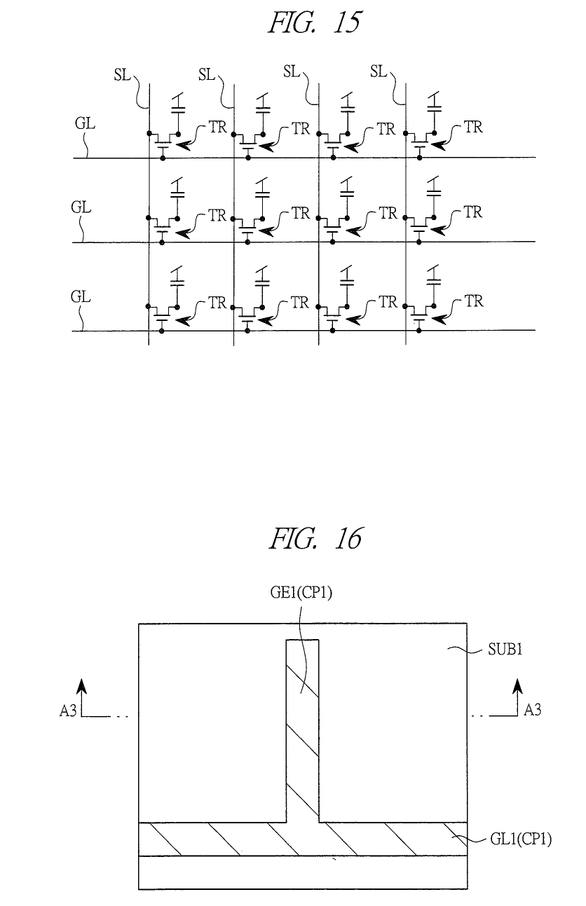

In general, in order to cause the liquid crystal display and electronic paper to display at high speed, a matrix transistor circuit referred to as active matrix is used. FIG. 15 shows a representative circuit diagram thereof. In the circuit of FIG. 15, the transistors TR are arranged in a matrix, and the gate electrodes of the transistors TR are connected to the scanning line GL for each row. The source electrodes of the transistors TR are connected to the signal line SL for each column, and the drain electrodes of the transistors TR are connected to the pixel electrodes connected to the pixels.

When forming the circuit shown in FIG. 15 on a substrate, a region where the scanning line GL and the signal line LS intersect in a plane is formed. Thus, the manufacturing method in the second reviewed example cannot be applied as it is. This is because, if the scanning line GL is positioned on the side close to the substrate compared with the signal line SL, the scanning line GL functions as a mask in the backside exposure, and thus the signal line SL cannot be formed at the position overlapping the scanning line GL.

The manufacturing method of the semiconductor device of the present embodiment, in which the active matrix circuit of FIG. 15 is formed with using the transistors in which the position of the gate electrode is aligned with the positions of the source electrode and the drain electrode as in the thin film transistor TR201, will be described with reference to FIGS. 16 to 29.

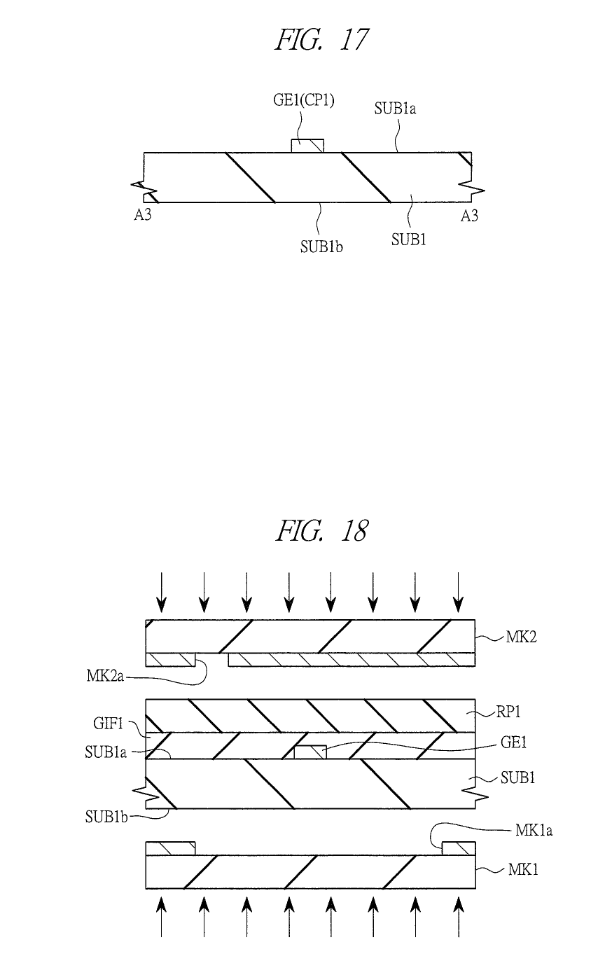

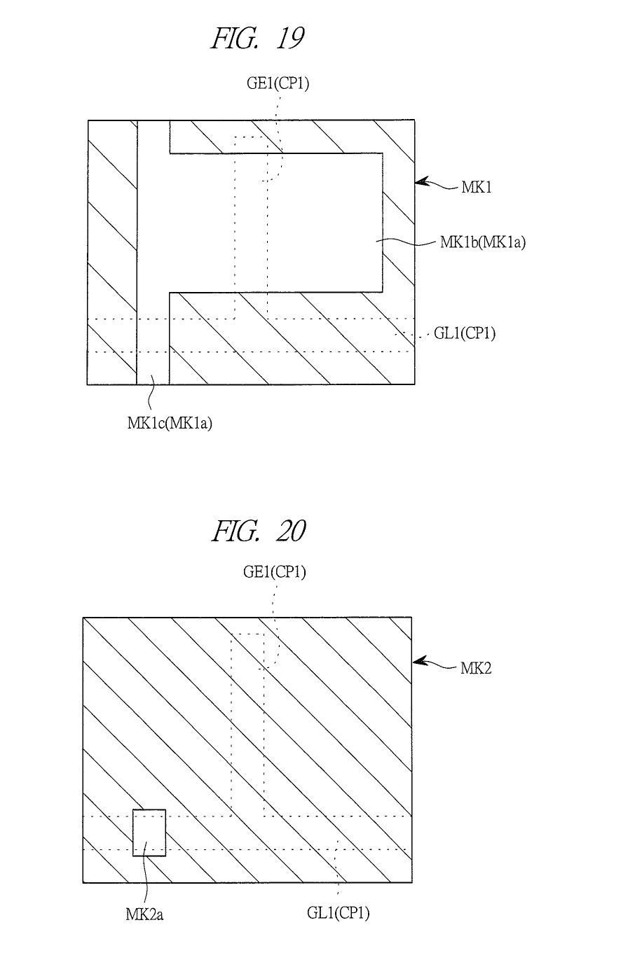

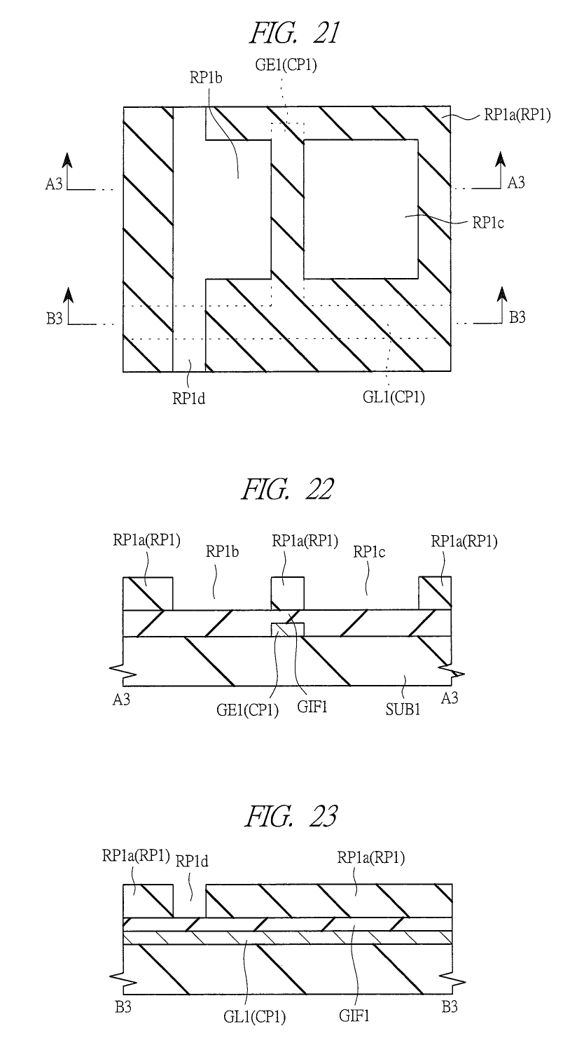

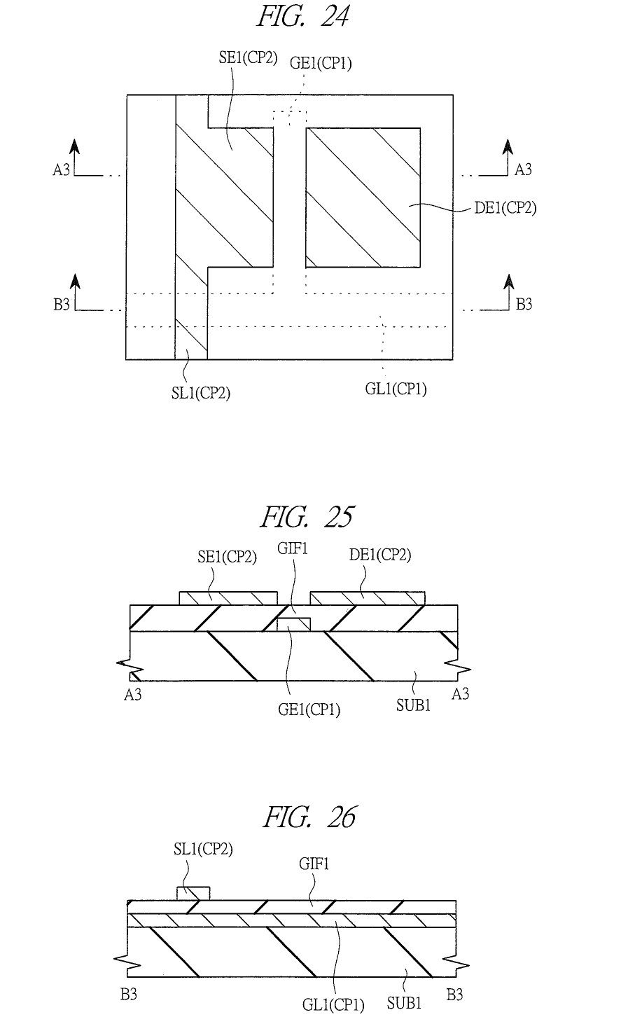

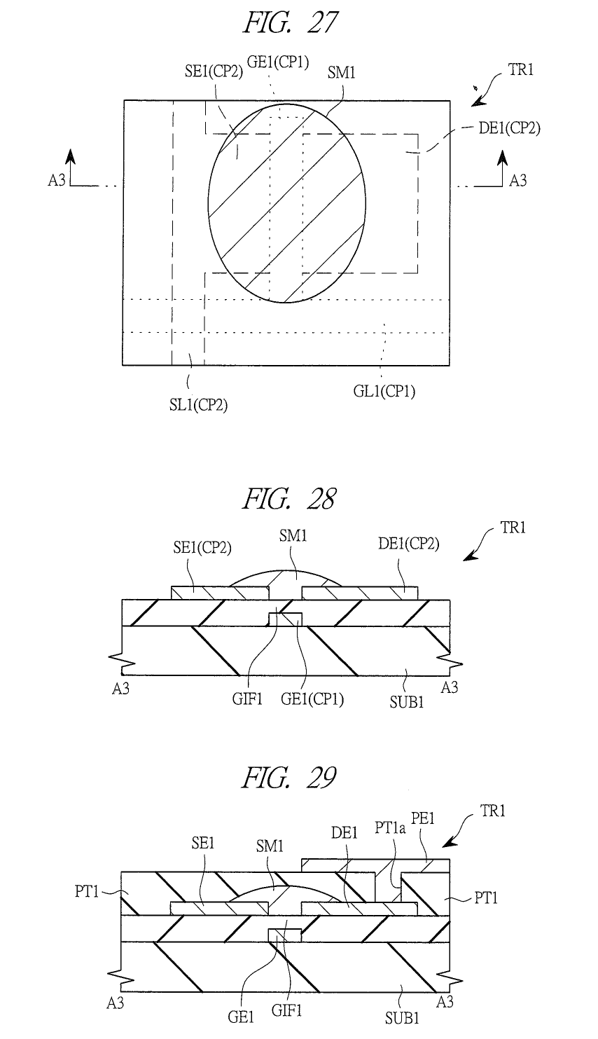

FIGS. 16 to 29 include plan views (plan view of principal part) and cross sectional views (cross sectional view of principal part) in the manufacturing process of the active matrix circuit using the thin film transistors TR1 of the bottom gate structure having a structure substantially similar to the thin film transistor TR201 as a single transistor, and plan views of the masks MK1 and MK2 used in the manufacturing process of the thin film transistor TR1. Of FIGS. 16 to 29, FIGS. 16, 21, 24 and 27 are plan views (plan view of principal part) in the manufacturing process of the thin film transistor TR1 and show different processing steps of the same region. Also, of FIGS. 16 to 29, FIGS. 17, 18, 22, 23, 25, 26, 28 and 29 are cross sectional views (cross sectional view of principal part) in the manufacturing process of the thin film transistor TR1. Also, FIG. 19 is a plan view of the mask MK1 and FIG. 20 is a plan view of the mask MK2. Further, FIGS. 16 and 17 correspond to the same processing step, and the cross sectional view of the line A3-A3 of FIG. 16 corresponds to FIG. 17. FIGS. 21 to 23 correspond to the same processing step, the cross sectional view of the line A3-A3 of FIG. 21 corresponds to FIG. 22, and the cross sectional view of the line B3-B3 of FIG. 21 corresponds to FIG. 23. Further, FIGS. 24 to 26 correspond to the same processing step, the cross sectional view of the line A3-A3 of FIG. 24 corresponds to FIG. 25, and the cross sectional view of the line B3-B3 of FIG. 24 corresponds to FIG. 26. Further, FIGS. 27 and 28 correspond to the same processing step, and the cross sectional view of the line A3-A3 of FIG. 27 corresponds to FIG. 28. Further, FIG. 29 is a cross sectional view in the manufacturing process continued from FIG. 28 and shows the same cross sectional region as FIG. 28.

Also, FIGS. 16, 19 to 21, 24 and 27 are plan views, but in order to make the drawings easy to see, hatching is applied to the conductor pattern CP1 in FIG. 16, to the light shielding region of the mask MK1 in FIG. 19, to the light shielding region of the mask MK2 in FIG. 20, to the resist pattern RP1a in FIG. 21, to the conductor pattern CP2 in FIG. 24, and to the semiconductor layer SM1 in FIG. 27.

First, as shown in FIG. 16 and FIG. 17, the substrate SUB1 is prepared. The substrate SUB1 has translucency and is preferably a resin substrate. For instance, the substrate SUB1 can be made of polyethylene terephtalate (PET). Further, a metal film such as an aluminum film is formed on the surface (upper surface) SUB1a of the substrate SUB1 to have a film thickness of about 200 nm, and thereafter, the metal film is patterned through the normal lithography technique and the etching technique to form the conductor pattern (metal pattern) CP1 including a gate electrode GE1 and a scanning line GL1. The scanning line GL1 corresponds to the scanning line GL of the circuit diagram of FIG. 15, and the gate electrode GE1 corresponds to the gate electrode of the transistor TR of the circuit diagram of FIG. 15. As is apparent from the circuit diagram of FIG. 15, the gate electrode GE1 and the scanning line GL1 need to be electrically connected, and thus the gate electrode GE1 and the scanning line GL1 are formed as an integrated pattern connected to each other on the substrate SUB1.

Next, as shown in FIG. 18, a translucent gate insulating film GIF1 is formed to have the film thickness of about 300 nm so as to cover the conductor pattern CP1 (gate electrode GE1 and scanning line GL1) on the entire surface of the substrate SUB1. As the material of the gate insulating film GIF1, an organic insulating film such as polyvinyl phenol (PVP) can be used.

Next, the positive resist film (photoresist film) RP1 is formed on the entire surface of the substrate SUB1, that is, on the gate insulating film GIF1. The process up to this point is substantially similar to that of the second reviewed example other than that the pattern of the gate electrode GE201 is changed to the pattern of the gate electrode GE1 and the scanning line GL1.

Next, as shown in FIG. 18, the source-drain electrode mask (photomask) MK1 is disposed on the back surface (lower surface) SUB1b side of the substrate SUB1, and the signal line intersecting portion mask (photomask) MK2 is disposed on the front surface (upper surface) SUB1a side of the substrate SUB1. Then, light is irradiated from both sides of the front surface SUB1a side and the back surface SUB1b side of the substrate SUB1, thereby exposing the resist film RP1. The mask MK1 has a planar shape as shown in FIG. 19, and the mask MK2 has a planar shape as shown in FIG. 20. In FIG. 18, the light irradiated onto the substrate SUB1 from the back surface SUB1b side and the front surface SUB1a side of the substrate SUB1 in exposure is schematically shown with arrows.

Note that, in the present embodiment and the following second to sixth embodiments, the main surface on the side where the structure of the conductor pattern CP1 (conductor patterns CP3, 5, 7, 9, 11 in second to sixth embodiments described later) and upper layers thereof are formed in the substrate SUB1 is referred to as the front surface SUB1a of the substrate SUB1, and the main surface on the opposite side of the front surface SUB1a is referred to as the back surface SUB1b of the substrate SUB1.

Thereafter, by developing the resist film RP1, the resist pattern (photoresist pattern) RP1a in which the source electrode region RP1b, the drain electrode region RP1c and the signal line region RP1d are opened is formed on the gate insulating film GIF1 as shown in FIGS. 21 to 23.

As shown in FIGS. 19 and 20, the masks MK1 and MK2 have openings (portion transmitting light) MK1a and MK2a, respectively, and have a function to pass light through the openings MK1a and MK2a and shielding light by the area other than the openings MK1a and MK2a. FIGS. 19 and 20 are plan views of the masks MK1 and MK2, but in order to make the drawings easy to see, hatching is applied to the light shielding portion (portion shielding light) of the masks MK1 and MK2, and the light passes through the portion not applied with hatching (openings MK1a and MK2a) in the masks MK1 and MK2 of FIG. 19 and FIG. 21. Also, FIG. 19 and FIG. 20 show the positions of the gate electrode GE1 and the scanning line GL1 in exposure with a dotted line so that the positions of the openings MK1a and MK2a of the masks MK1 and MK2 can be readily recognized.

The reason why the source-drain electrode mask MK1 is disposed on the back surface SUB1b side of the substrate SUB is similar to that described in relation to FIG. 5. In other words, since the substrate SUB1 and the gate insulating film GIF1 have translucency (light transmitting property), the light irradiated from the back surface SUB1b side of the substrate SUB1 passes through the opening MK1a of the mask MK1, and is irradiated onto the resist film RP1 through the substrate SUB1 and the gate insulating film GIF1. At this time, since the conductor pattern CP1 is formed of a metal film and has a light reflecting property instead of a light transmitting property, it functions as a mask in exposure. Therefore, the light passed through the opening MK1a of the mask MK1 and not shielded by the conductor pattern CP1 (gate electrode GE1 and scanning line GL1) is irradiated onto the resist film RP1 from the back surface SUB1b side of the substrate SUB1.

In the active matrix circuit shown in the circuit diagram of FIG. 15, the scanning line GL connected to the gate electrode and the signal line SL connected to the source electrode are provided in addition to the thin film transistor, in which the scanning line GL and the signal line SL intersect and the scanning line GL and the signal line SL are electrically insulated by the gate insulating film GIF1 at the intersecting position. The reason why the mask MK2 is used in addition to the mask MK1 is to form both the scanning line GL and the signal line SL at the intersecting position.

As shown in FIG. 19, the mask MK1 has a source-drain electrode opening pattern MK1b and a signal line opening pattern MK1c, and the source-drain electrode opening pattern MK1b and the signal line opening pattern MK1c are connected to form the opening MK1a.

The pattern shape of the opening MK1a of the mask MK1 is a shape in which the source electrode SE1, the drain electrode DE1, and the signal line SL1 to be formed are connected (coupled) to one. By setting the shape of the opening MK1a of the mask MK1 to the desired arbitrary shape, the shapes of the source electrode SE1, the drain electrode DE1 and the signal line SL1 to be formed later can be formed to the desired arbitrary shape. This is because, when the light is irradiated onto the positive resist film RP1 from the back surface SUB1b side of the substrate SUB1 through the mask MK1, the conductor pattern CP1 also acts as the photomask in addition to the mask MK1, and the exposure region of the resist film RP1 is separated into the source electrode region PR1b, the signal line region RP1d and the drain electrode region RP1c by the gate electrode GE1 of the conductor pattern CP1. At this time, the overlapping region 102 scarcely exists, and the position of the gate electrode GE1 is automatically aligned with the positions of the source electrode region RP1b and the drain electrode region RP1c. Since the resist film RP1 is a positive type, the resist pattern RP1a after development of FIGS. 21 to 23 has a pattern in which the source electrode region RP1b, the signal line region RP1d and the drain electrode region RP1c corresponding to the regions exposed in the exposure process of FIG. 18 are opened. Note that the source electrode region RP1b corresponds to the region in which the source electrode SE1 is to be formed, the drain electrode region RP1c corresponds to the region in which the drain electrode DE1 is to be formed, and the signal line region RP1d corresponds to the region in which the signal line SL1 is to be formed.

However, the opening MK1a of the mask MK1 also includes the signal line opening pattern MK1c, but in the region of the signal line opening pattern MK1c intersecting with the scanning line GL1, light cannot be irradiated onto the resist film RP1 from the back surface SUB1b side of the substrate SUB1 because the scanning line GL1 functions as the mask. Thus, if backside exposure with the mask MK1 is simply performed, the latent image pattern of the signal line formed on the positive resist film RP1 is cut because light cannot be irradiated to the intersecting portion with the scanning line GL1. Therefore, light needs to be irradiated onto the intersecting portion between the signal line SL (signal line SL1 described later) and the scanning line GL (GL1), and thus the signal line intersecting portion mask MK2 is disposed on the front surface SUB1a side of the substrate SUB1 and light is irradiated also from the front surface SUB1a side of the substrate SUB1 in the present embodiment.

As shown in FIG. 20, the mask MK2 has an opening MK2a in the region corresponding to the intersecting portion between the signal line opening pattern MK1c (i.e., region where the signal line SL1 is to be formed) and the region where the scanning line GL1 is formed. More specifically, the opening MK2a of the mask MK2 is formed so as to include a region where the signal line opening pattern MK1c of the mask MK1 and the scanning line GL1 planarly overlap in exposure. Therefore, when the resist film RP1 is exposed also from the front surface SUB1a side of the substrate SUB1 through the mask MK2 as shown in FIG. 18, light is irradiated to the resist film RP1 through the opening MK2a of the mask MK2. The light irradiated from the front surface SUB1a side of the substrate SUB1 is irradiated only to the intersecting portion between the region where the signal line SL (SL1) is to be formed and the region where the scanning line GL1 is formed in the resist film RP1.

Therefore, of the region where the signal line SL1 is to be formed, the light can be irradiated through the mask MK2 from the front surface SUB1a side of the substrate SUB1 to the region intersecting the scanning line GL1, and the light can be irradiated through the mask MK1 from the back surface SUB1b side of the substrate SUB1 to the regions other than the intersecting region. In this manner, the resist pattern RP1a after development has an opening (i.e., signal line region RP1d) corresponding to the signal line SL1 to be formed, and the signal line region RP1d is not disconnected even at the region intersecting the scanning line GL1.

The wavelength of the light irradiated from the back surface SUB1b side of the substrate SUB1 in the exposure process of FIG. 18 has to be in a wavelength range where a latent image is formed in the positive resist film RP1 and has to be a wavelength that transmits through the substrate SUB1 and the gate insulating film GIF1. For instance, parallel light of mixed lines of g line, i line and h line of a mercury lamp can be used. Also, the wavelength of the light irradiated from the front surface SUB1a side of the substrate SUB1 in the exposure process of FIG. 18 merely needs to be in a wavelength range where a latent image is formed in the positive resist film RP1. In the exposure process of FIG. 18, however, it is more preferable that the wavelength of the light irradiated from the front surface SUB1a side of the substrate SUB1 is the same as the wavelength of the light irradiated from the back surface SUB1b side of the substrate SUB1 because the exposure process can be simplified and the exposure device can be simplified. The same goes for the exposure process of FIG. 34 below, but in the exposure process of FIG. 34 below, the wavelength of the light irradiated from the back surface SUB1b side of the substrate SUB1 has to be a wavelength that transmits through not only the substrate SUB1 and the gate insulating film GIF1a described later but also the semiconductor layer SM1a described later.

Further, in the exposure process of FIG. 18, the light (parallel light) can be irradiated from the back surface SUB1b side and the front surface SUB1a side of the substrate SUB1 with using the masks MK1 and MK2 closely attached to the substrate SUB1, and alternatively, light can be also irradiated by using a proximate exposure device with the masks MK1 and MK2 being brought into proximity with the substrate SUB1 (i.e., with interposing slight gap therebetween). Further, the light may also be irradiated by using a projection exposure device with separately disposing the masks MK1 and MK2 from the substrate SUB1. In any case, substantially similar effects can be obtained. The same goes for the exposure process of FIG. 34 described later.

The subsequent steps are substantially similar to those described with reference to FIGS. 9 to 12.

After forming the resist pattern RP1a, a metal film is formed on the entire surface of the substrate SUB1, that is, on the resist pattern RP1a and the gate insulating film GIF1 of the region not covered with the resist pattern RP1a, and then the resist pattern RP1a is dissolved and removed with organic solvent and the like. In this case, the metal film on the resist pattern RP1a is also removed together, but the metal film formed on the gate insulating film GIF1 exposed at the bottom of the opening region (source electrode region RP1b, drain electrode region RP1c, and signal line region RP1d) of the resist pattern RP1a remains without being removed and becomes the conductor pattern (metal pattern) CP2 including the source electrode SE1, the drain electrode DE1 and the signal line SL1 as shown in FIGS. 24 to 26. The signal line SL1 corresponds to the signal line SL of the circuit diagram of FIG. 15, and the source electrode SE1 and the drain electrode DE1 respectively correspond to the source electrode and the drain electrode of the transistor TR of the circuit diagram of FIG. 15.

As described above, by performing the so-called lift-off process, the source electrode SE1, the drain electrode DE1, and the signal line SL1 are formed on the gate insulating film GIF1 of the region (source electrode region RP1b, drain electrode region RP1c, and signal line region RP1d) not covered with the resist pattern RP1a. As the metal film for forming the conductor pattern CP2, for example, a laminated film of a chromium (Cr) film having a film thickness of about 5 nm and a gold (Au) film having a film thickness of about 100 nm formed on the chromium film may be used, and it can be formed by, for example, the evaporation method or the like.

Next, as shown in FIGS. 27 and 28, the semiconductor layer (semiconductor pattern) SM1 is formed on the gate insulating film GIF1 between the source electrode SE and the drain electrode DE. The forming method and the material of the semiconductor layer SM1 are similar to those of a semiconductor layer SM2 of the second embodiment described later.

In this manner, the thin film transistor TR1 in which the overlapping region (corresponding to the overlapping region 102) of the gate electrode GE1 and the source electrode SE1 and the drain electrode DE1 scarcely exists and the position of the gate electrode GE1 is accurately aligned with the positions of the source electrode SE1 and the drain electrode DE1 can be formed on the substrate SUB1. The thin film transistor TR1 corresponds to the transistor TR in the circuit diagram of FIG. 15.

Next, as shown in FIG. 29, a protective film (insulating film) PT1 made of insulator is formed on the substrate SUB1, that is, on the gate insulating film GIF1 so as to cover the conductor pattern CP2 (source electrode SE1, drain electrode DE1 and signal line SL1) and the semiconductor layer 7. The protective film PT1 can be formed by, for instance, applying polyvinyl alcohol by the screen printing method (at this time, applied to a pattern having a via at a predetermined position) and drying the same. The protective film PT1 has a via (hole, opening) PT1a positioned on the drain electrode DE1.

Thereafter, a pixel electrode PE1 is formed on the protective film PT1 by, for instance, the screen printing method using silver ink. The conductive material configuring the pixel electrode PE1 is filled also in the via PT1a of the protective film PT1, whereby the pixel electrode PE1 is electrically connected to the drain electrode DE1. The pixel electrode PE1 is connected to a display element such as electronic paper. Also, if the pixel electrode PE1 is formed by using transparent conductive ink such as poly(3,4-ethylenedioxythiophene)-polystyrene sulfonic acid (PEDOT-PSS) instead of silver ink, the thin film transistor TR1 formed here can be used in a transmissive display such as a liquid crystal display. The same goes for the following fourth and fifth embodiments.

In the foregoing, the thin film transistor 1 of bottom gate structure has been described, but a thin film transistor TR1a of top gate structure can be fabricated in the same manner. The thin film transistor TR1a of top gate structure will be described below.

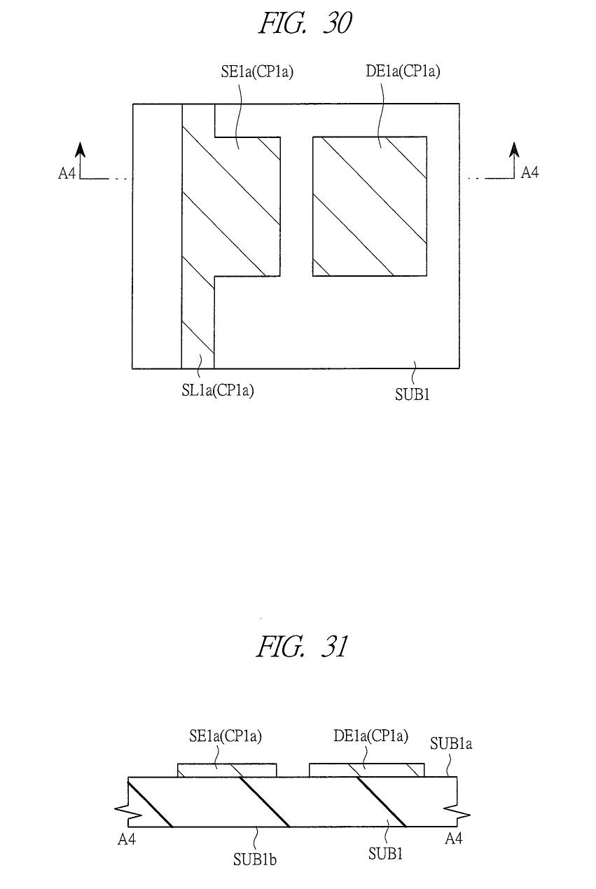

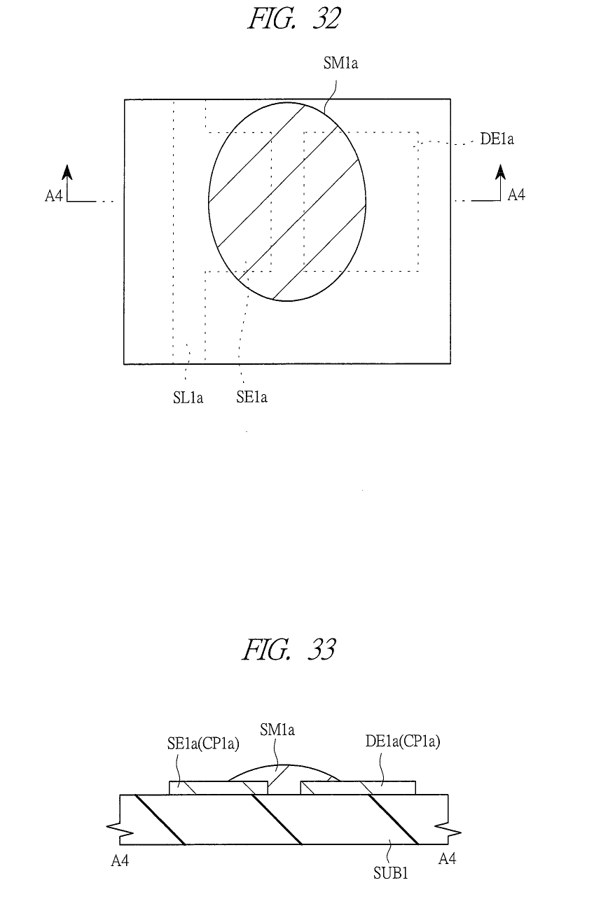

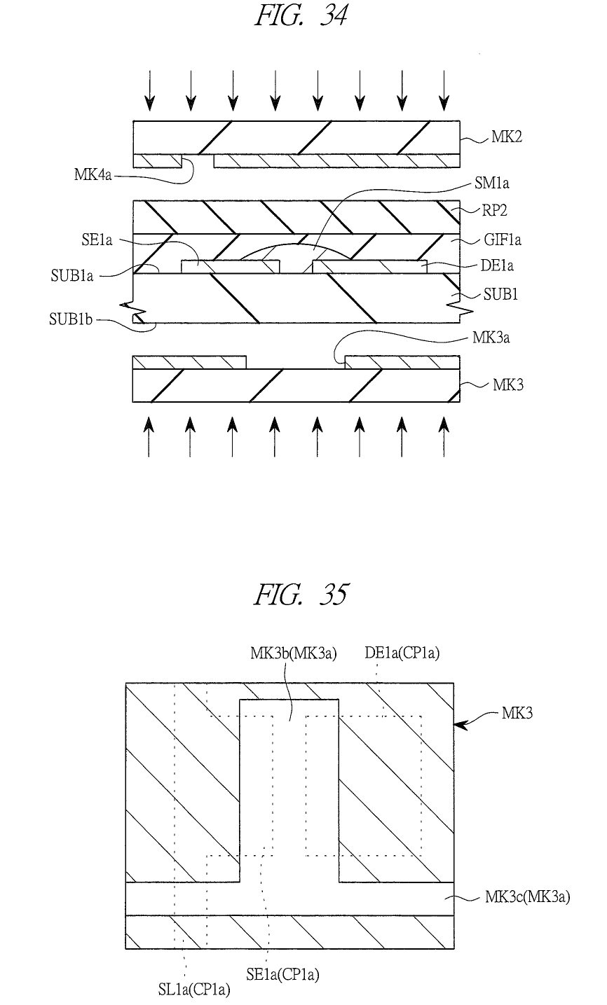

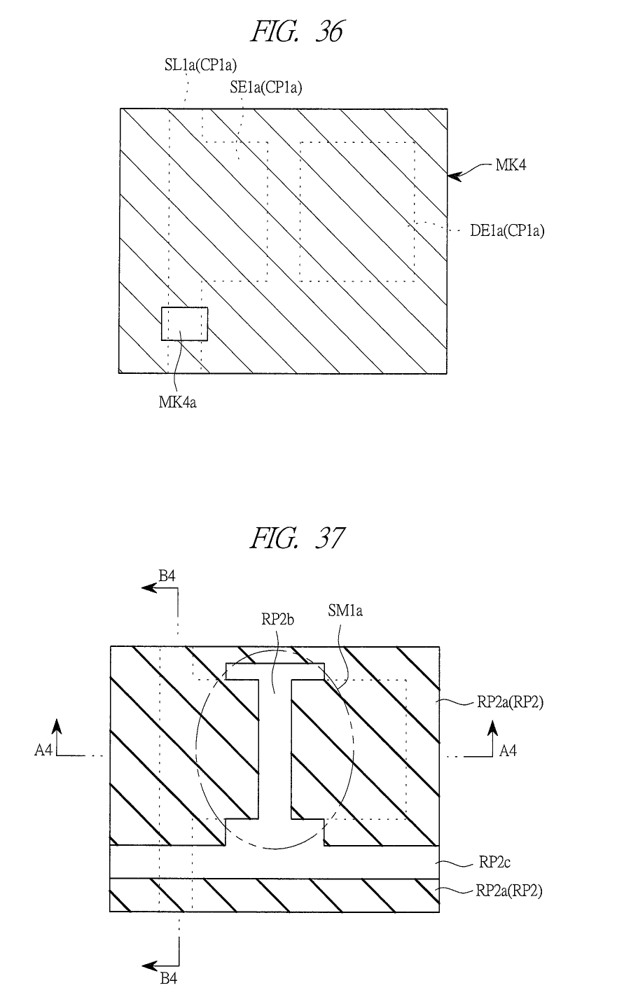

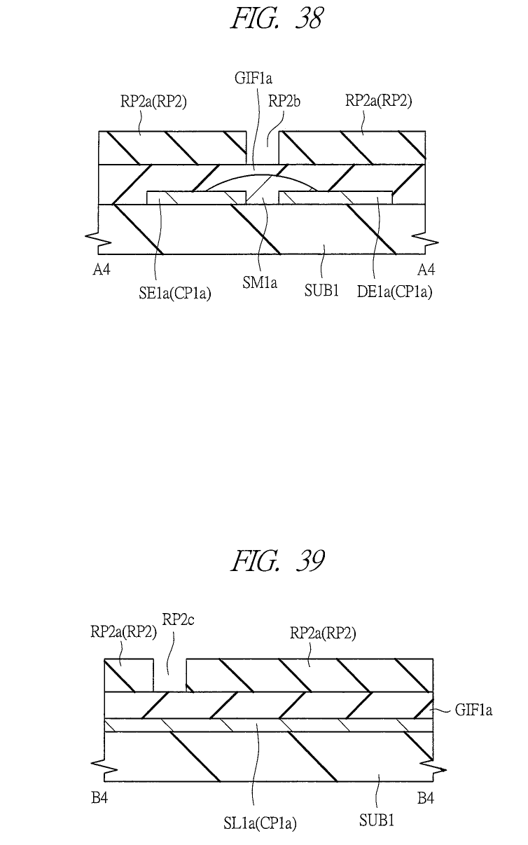

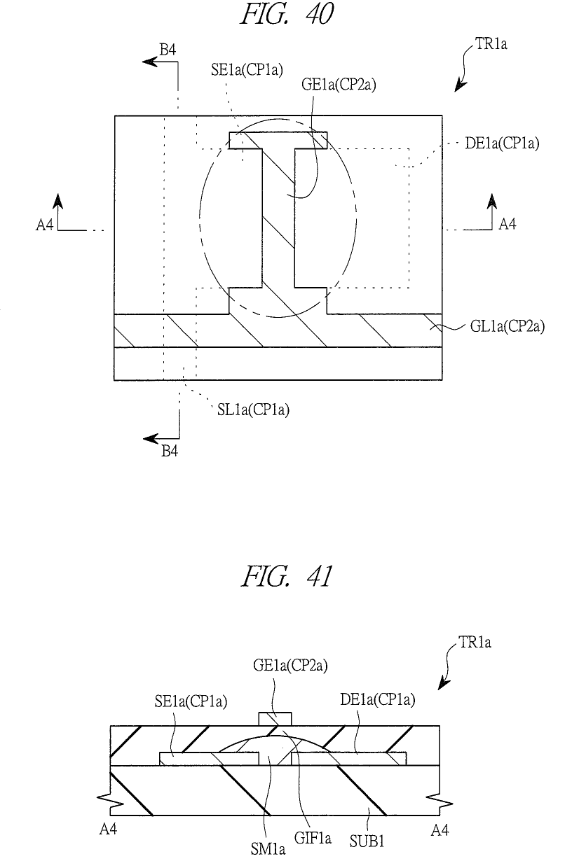

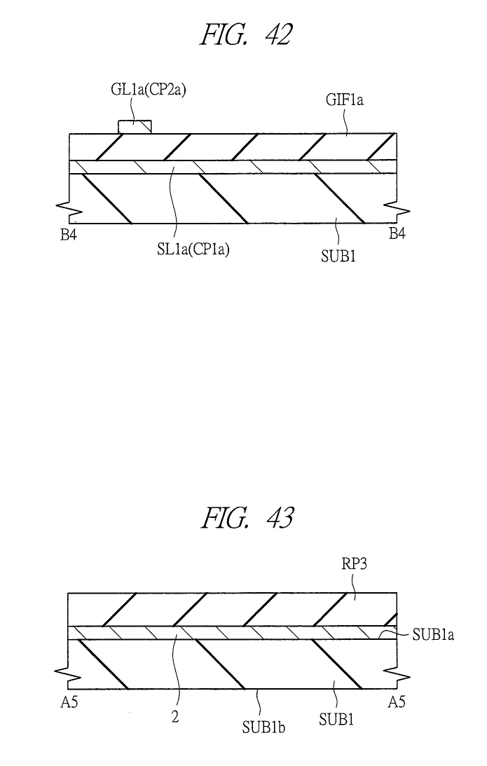

FIGS. 30 to 42 include plan views (plan view of principal part) and cross sectional views (cross sectional view of principal part) in the manufacturing process of the active matrix circuit (circuit of FIG. 15) using the thin film transistor TR1a of the top gate structure, and plan views of masks MK3 and MK4 used in the manufacturing process of the thin film transistor TR1a. Of FIGS. 30 to 42, FIGS. 30, 32, 37 and 40 are plan views (plan view of principal part) in the manufacturing process of the thin film transistor TR1a and show different processing steps of the same region. Also, of FIGS. 30 to 42, FIGS. 31, 33, 34, 38, 39, 41 and 42 are cross sectional views (cross sectional view of principal part) in the manufacturing process of the thin film transistor TR1a, FIG. 35 is a plan view of the mask MK3, and FIG. 36 is a plan view of the mask MK4. Further, FIGS. 30 and 31 correspond to the same processing step and the cross sectional view of the line A4-A4 of FIG. 30 corresponds to FIG. 31. FIGS. 32 and 33 correspond to the same processing step and the cross sectional view of the line A4-A4 of FIG. 32 corresponds to FIG. 33. Also, FIGS. 37 to 39 correspond to the same processing step, the cross sectional view of the line A4-A4 of FIG. 37 corresponds to FIG. 38, and the cross sectional view of the line B4-B4 of FIG. 37 corresponds to FIG. 39. Also, FIGS. 40 to 42 correspond to the same processing step, the cross sectional view of the line A4-A4 of FIG. 40 corresponds to FIG. 41, and the cross sectional view of the line B4-B4 of FIG. 40 corresponds to FIG. 42.

FIGS. 30, 32, 35 to 37, and 40 are plan views, but in order to make the drawings easy to see, hatching is applied to the conductor pattern CP1a in FIG. 30, to the semiconductor layer SM1a in FIG. 32, to the light shielding region of the mask MK3 in FIG. 35, to the light shielding region of the mask MK4 in FIG. 36, to the resist pattern RP2a in FIG. 37, and to the conductor pattern CP2a in FIG. 40.

First, as shown in FIG. 30 and FIG. 31, the substrate SUB1 is prepared. Then, after a metal film is formed to have a film thickness of about 200 nm on the substrate SUB1, the metal film is patterned through the normal lithography technique and the etching technique to form the conductor pattern (metal pattern) CP1a including the source electrode SE1a, the drain electrode DE1a and the signal line SL1a. The signal line SL1a corresponds to the signal line SL of the circuit diagram of FIG. 15, and the source electrode SE1a and the drain electrode DE1a respectively correspond to the source electrode and the drain electrode of the transistor TR of the circuit diagram of FIG. 15.

As is apparent from the circuit diagram of FIG. 15, since the source electrode SE1a and the signal line SL1a need to be electrically connected, the source electrode SE1a and the signal line SL1a are formed on the substrate SUB1 as an integrated pattern connected to each other. As the metal film for forming the conductor pattern CP1a, for instance, a laminated film of a chromium (Cr) film having a film thickness of about 5 nm and a gold (Au) film having a film thickness of about 100 nm formed on the chromium film can be used.

Next, as shown in FIGS. 32 and 33, a semiconductor layer (semiconductor pattern) SM1a is formed on the substrate SUB1 between the source electrode SE1a and the drain electrode DE1a. The forming method and the material of the semiconductor layer SM1a can be similar to those of the semiconductor layer SM2 of the second embodiment described later.

Next, as shown in FIG. 34, a translucent gate insulating film GIF1a is formed to have a film thickness of, for example, about 300 nm so as to cover the conductor pattern CP1a (source electrode SE1a, drain electrode DE1a and signal line SL1a) and the semiconductor layer SM1a on the entire surface of the substrate SUB1. For the material of the gate insulating film GIF1a, a material similar to that of the gate insulating film GIF1 can be used.

Next, the positive resist film RP2 is formed on the entire surface of the substrate SUB1, that is, on the gate insulating film GIF1a.

Next, as shown in FIG. 34, the gate electrode mask MK3 is disposed on the back surface SUB1b side of the substrate SUB1, and the scanning line intersecting portion mask MK4 is disposed on the front surface SUB1a side of the substrate SUB1. Then, light is irradiated from both the front surface SUB1a side and the back surface SUB1b side of the substrate SUB1, thereby exposing the resist film RP2. The mask MK3 has a planar shape as shown in FIG. 35, and the mask MK4 has a planar shape as shown in FIG. 36. In FIG. 34, the light irradiated onto the substrate SUB1 from the back surface SUB1b side and the front surface SUB1a side of the substrate SUB1 in exposure is schematically shown with arrows.

Thereafter, by developing the resist film RP2, as shown in FIGS. 37 to 39, the resist pattern (resist film) RP2a in which the gate electrode region RP2b and the scanning line region RP2c are opened is formed on the gate insulating film GIF1a.

As shown in FIG. 35 and FIG. 36, the masks MK3 and MK4 have openings MK3a and MK4a, and have a function to pass light through the openings MK3a and MK4a and shield light by the area other than the openings MK3a and MK4a. FIGS. 35 and 36 are plan views of the masks MK3 and MK4, respectively, but hatching is applied to the light shielding portion (portion shielding light) of the masks MK3 and MK4 so as to make the drawings easy to see, and the light passes through the portion not applied with hatching (openings MK3a and MK4a) in the masks MK3 and MK4 of FIGS. 35 and 36. Also, FIGS. 35 and 36 show the positions of the source electrode SE1a, the drain electrode DE1a and the signal line SL1a in exposure with a dotted line so that the positions of the openings MK3a and MK4a of the masks MK3 and MK4 can be readily recognized.

Since the substrate SUB1, the gate insulating film GIF1a and the semiconductor layer SM1a have translucency, the light irradiated from the back surface SUB1b side of the substrate SUB1 passes through the opening MK3a of the mask MK3 and is irradiated to the resist film RP2 through (passing through) the substrate SUB1, the semiconductor layer SM1a and the gate insulating film GIF1a. At this time, since the conductor pattern CP1a is formed of a metal film and has a light reflecting property instead of a light transmitting property, it functions as a mask in exposure. Therefore, the light passed through the opening MK3a of the mask MK3 and not shielded by the conductor pattern CP1a (source electrode SE1a, drain electrode DE1a and signal line SL1a) is irradiated onto the resist film RP2 from the back surface SUB1b side of the substrate SUB1.

As shown in FIG. 35, the mask MK3 has a gate electrode opening pattern MK3b and a scanning line opening pattern MK3c, and the gate electrode opening pattern MK3b and the scanning line opening pattern MK3c are connected to form the opening MK3a.

The pattern shape of the opening MK3a of the mask MK3 is a shape in which the gate electrode GE1a and the scanning line GL1a to be formed are connected (coupled) to one. By setting the shape of the opening MK3a to a desired arbitrary shape, the shapes of the gate electrode GE1a and the scanning line GL1a to be formed later can be formed to the desired arbitrary shape.

Also, when the back surface exposure through the mask MK3 is performed, the conductor pattern CP1a also acts as the photomask in addition to the mask MK3, and thus the portion corresponding to the overlapping region 102 scarcely exists, and the position of the gate electrode region RP2b is automatically aligned with the positions of the source electrode SE1a and the drain electrode DE1a. Since the resist film RP2 is a positive type, the resist pattern RP2a after development shown in FIGS. 37 to 39 has a pattern in which the gate electrode region RP2b and the scanning line region RP2c corresponding to the region exposed in the exposure process of FIG. 34 are opened. Note that the gate electrode region RP2b corresponds to the region where the gate electrode GE1a is to be formed, and the scanning line region RP2c corresponds to the region where the scanning line GL1a is to be formed.

However, if backside exposure with the mask MK3 is simply performed, the latent image pattern of the scanning line formed on the resist film PR2 is cut because light cannot be irradiated to the intersecting portion with the signal line SL1a. Thus, in order to irradiate light to the intersecting portion between the signal line SL1a and the scanning line GL, the scanning line intersecting portion mask MK4 is disposed and the light is irradiated also from the front surface SUB1a side of the substrate SUB.

As shown in FIG. 36, the mask MK4 has an opening MK4a in the region corresponding to the intersecting portion between the scanning line opening pattern MK3c (i.e., region where the scanning line GL1a is to be formed) and the region where the signal line SL1a is formed. More specifically, the opening MK4a of the mask MK4 is formed so as to include a region where the scanning line opening pattern MK3c of the mask MK3 and the signal line SL1a planarly overlap in exposure. Therefore, when the resist film RP1 is exposed from the front surface SUB1a side of the substrate SUB1 through the mask MK4 as in FIG. 34, light is irradiated to the resist film RP2 through the opening MK4a of the mask MK4. The light irradiated from the front surface SUB1a side of the substrate SUB1 is irradiated only to the intersecting portion between the region where the scanning line GL (GL1a) is to be formed and the region where the signal line SL1a is formed in the resist film RP2.

Therefore, of the region where the scanning line GL1a is to be formed, the light can be irradiated through the mask MK4 from the front surface SUB1a side of the substrate SUB1 to the region intersecting the signal line SL1a, and the light can be irradiated through the mask MK3 from the back surface SUB1b side of the substrate SUB1 to the regions other than the intersecting region. Thus, the resist pattern RP2a after development has an opening (i.e., scanning line region PR2c) corresponding to the scanning line GL1a to be formed, and the opening (scanning line region RP2c) corresponding to the scanning line GL1a is not disconnected even at the region intersecting the signal line SL1a.

After forming the resist pattern RP2a in this manner, a metal film made of an aluminum (Al) film and the like is formed on the entire surface of the substrate SUB1, that is, on the resist pattern RP2a and the gate insulating film GIF1a of the region not covered with the resist pattern RP2a, and then the resist pattern RP2a is dissolved and removed with organic solvent and the like. At this time, the metal film on the resist pattern RP2a is also removed together, but the metal film formed on the gate insulating film GIF1a exposed at the bottom of the opening region (gate electrode region RP2b and scanning line region RP2c) of the resist pattern RP2a remains without being removed and becomes the conductor pattern CP2a including the gate electrode GE1a and the scanning line GL1a as shown in FIG. 40 to FIG. 42. As described above, by performing the so-called lift-off process, the conductor pattern CP2a, namely, the gate electrode GE1a and the scanning line GL1a herein is formed on the gate insulating film GIF1a of the region (gate electrode region RP2b and scanning line region PR2c) not covered with the resist pattern RP2a. The scanning line GL1a corresponds to the scanning line GL of the circuit diagram of FIG. 15, and the gate electrode GE1a corresponds to the gate electrode of the transistor TR of the circuit diagram of FIG. 15.

In this manner, the thin film transistor TR1a in which the overlapping region (corresponding to overlapping region 102) of the gate electrode GE1a and the source electrode SE1a and the drain electrode DE1a scarcely exists, and the position of the gate electrode GE1a is accurately aligned with the positions of the source electrode SE1a and the drain electrode DE1a can be formed on the substrate SUB1.

Thereafter, a protective film such as the protective film PT1 is formed on the substrate SUB1, that is, on the gate insulating film GIF1a so as to cover the conductor pattern CP1a (gate electrode GE1a and scanning line GL1a), and a pixel electrode such as the pixel electrode PE1 is formed on the protective film, but the illustration and the description thereof will be omitted here.

### Second Embodiment

In the first embodiment, the thin film transistor in which the gate electrode is aligned with the source-drain electrodes is fabricated by forming the source-drain electrodes into the desired shape by using a separately prepared photomask. However, when forming the source-drain electrodes by using the photomask, the ends of the gate electrode can be aligned with the opposing ends of the source electrode and the drain electrode, but the outline position (position of the ends other than those aligned with the gate electrode) of the source-drain electrodes with respect to the gate electrode may shift (fluctuate) due to the shift in alignment of the photomask and the substrate in exposure. In order to reduce (miniaturize) the planar dimension of the transistor, it is desired to suppress the shift (fluctuation) of the outline position of the source-drain electrodes with respect to the gate electrode as much as possible in addition to aligning the gate electrode with the source-drain electrodes. Further, if an accurate alignment of the photomask and the substrate is necessary in exposure, an expensive exposure device having an alignment mechanism becomes necessary, which increases the manufacturing cost of the semiconductor device.

Therefore, in the present embodiment and the following third to sixth embodiments, the first conductor pattern and the second conductor pattern for forming electrode and wiring are formed in different layers on the substrate SUB1 with interposing an insulating film between the layers, thereby manufacturing the semiconductor device. Further, the photomask pattern for forming the second conductor pattern on the upper layer side (corresponding to conductor patterns CP4, CP6, CP8, CP10 and CP12 described later) is laid within the first conductor pattern on the lower layer side (corresponding to conductor patterns CP3, CP5, CP7, CP9 and CP11 described later) In the present embodiment, by using the gate electrode and the conductor pattern (corresponding to correction pattern AP2 described later) formed in the same layer, the source-drain electrodes are formed to the desired shape on the upper layer thereof, thereby fabricating the thin film transistor in which the gate electrode is aligned with the source-drain electrodes.

The manufacturing precess of the semiconductor device of the present embodiment or the thin film transistor TR2 of bottom gate structure herein will be described with reference to the drawings.

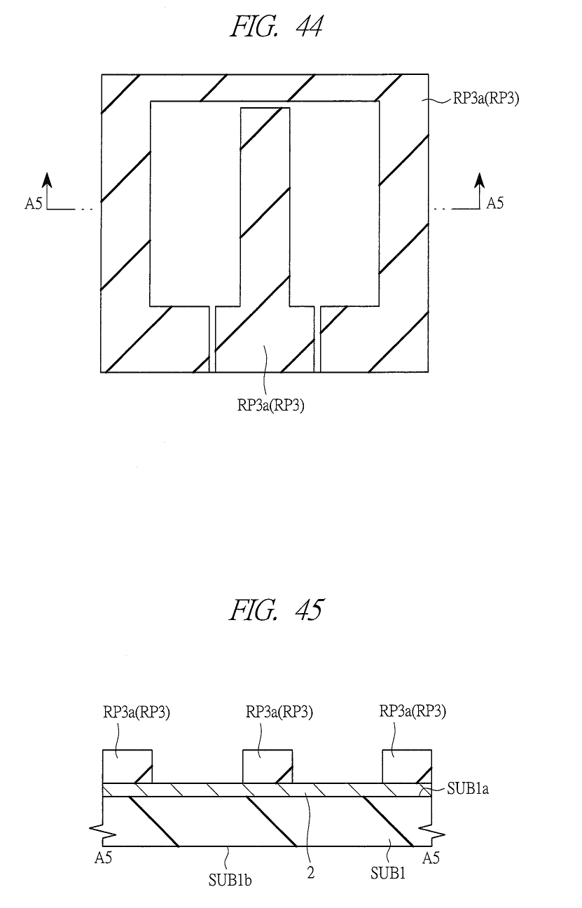

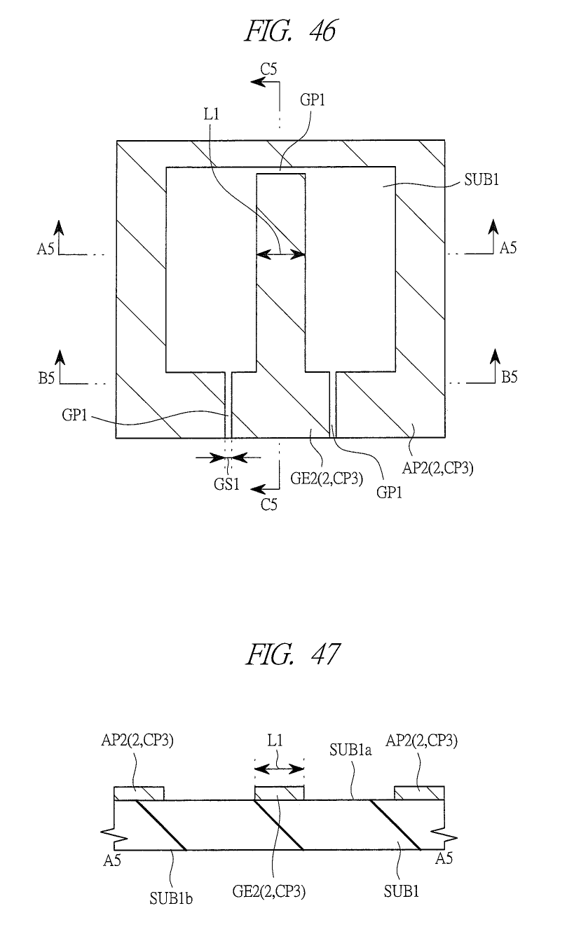

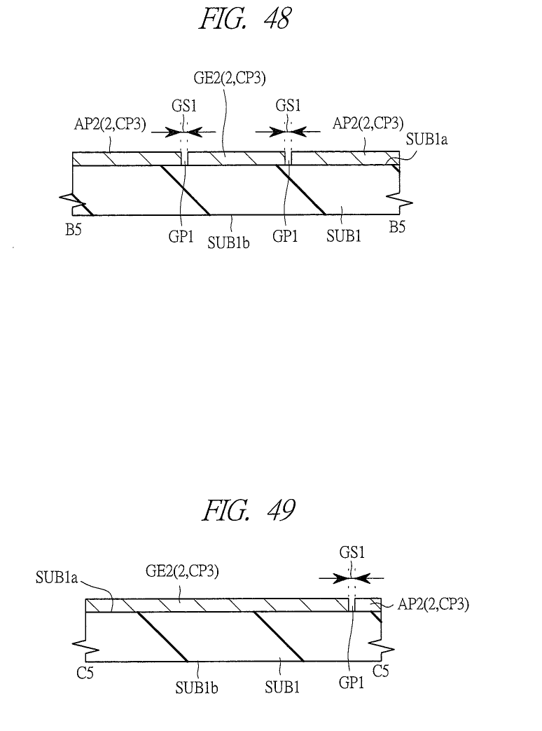

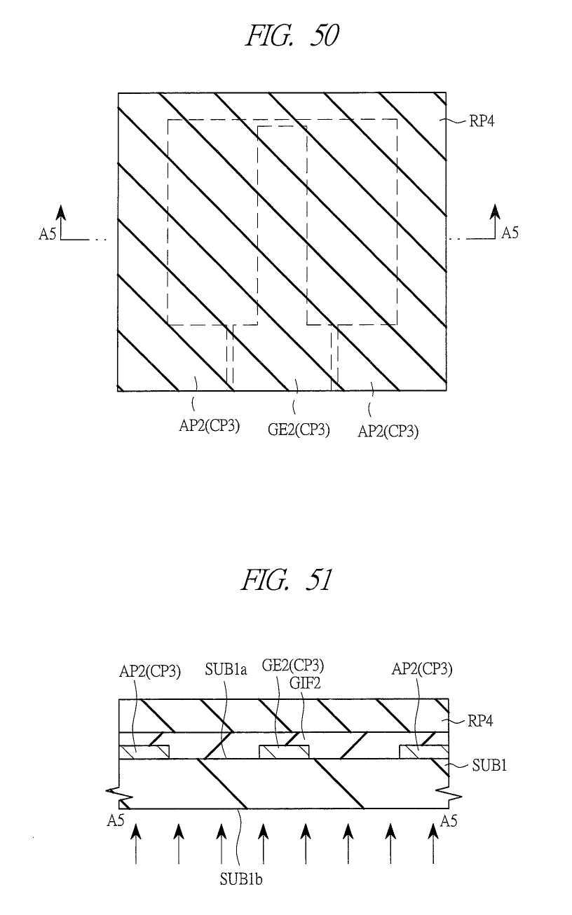

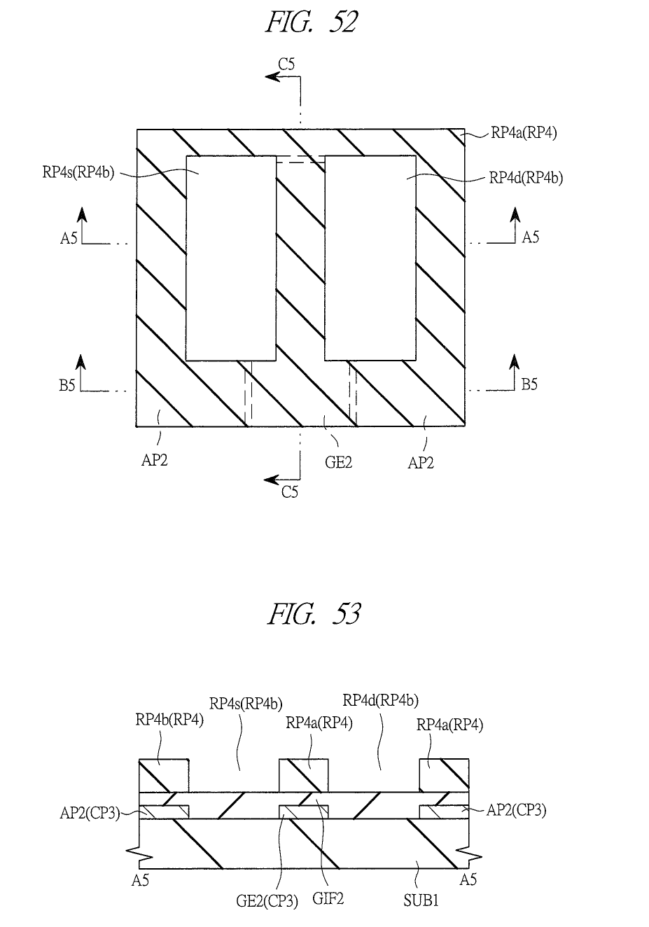

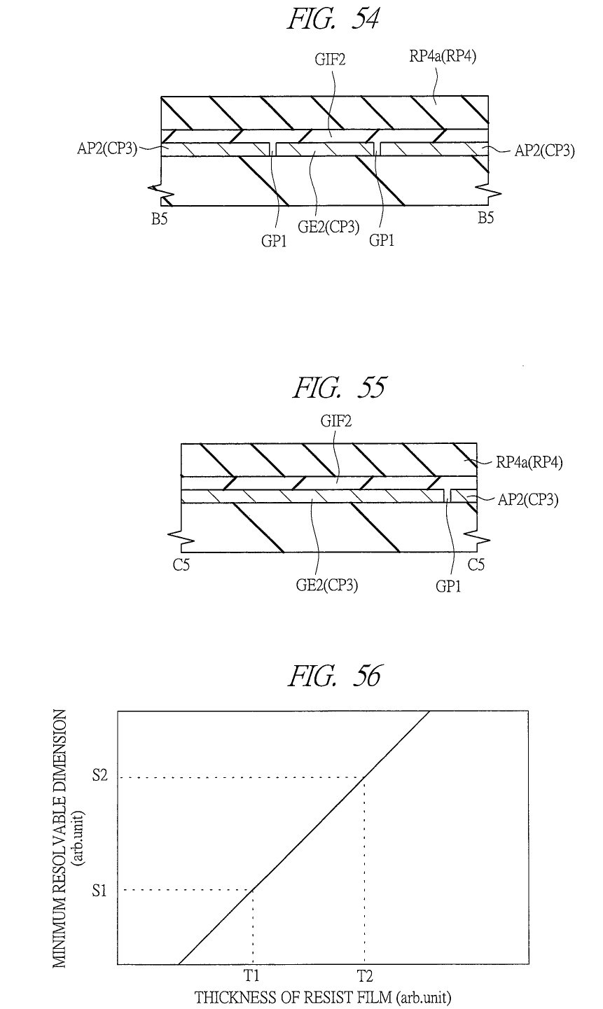

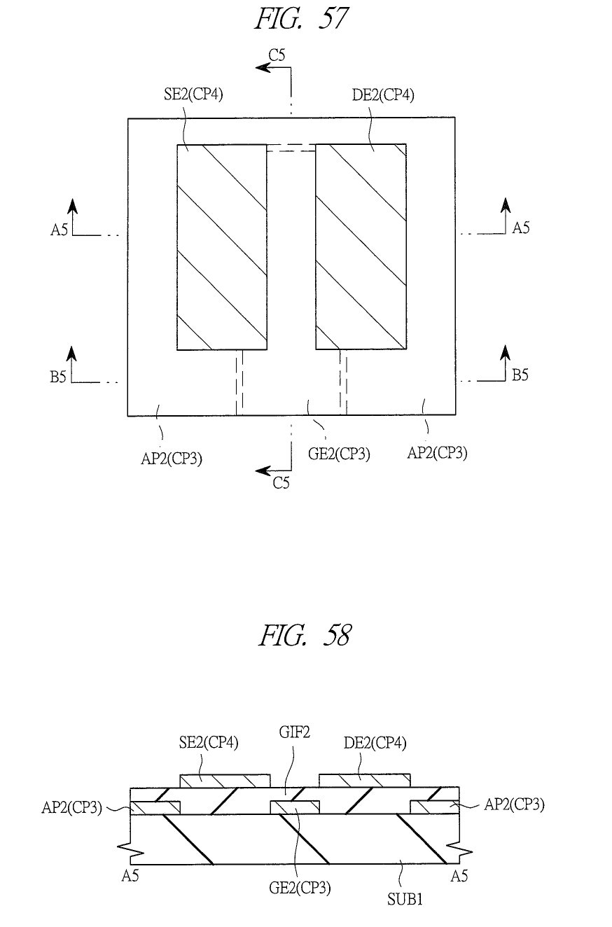

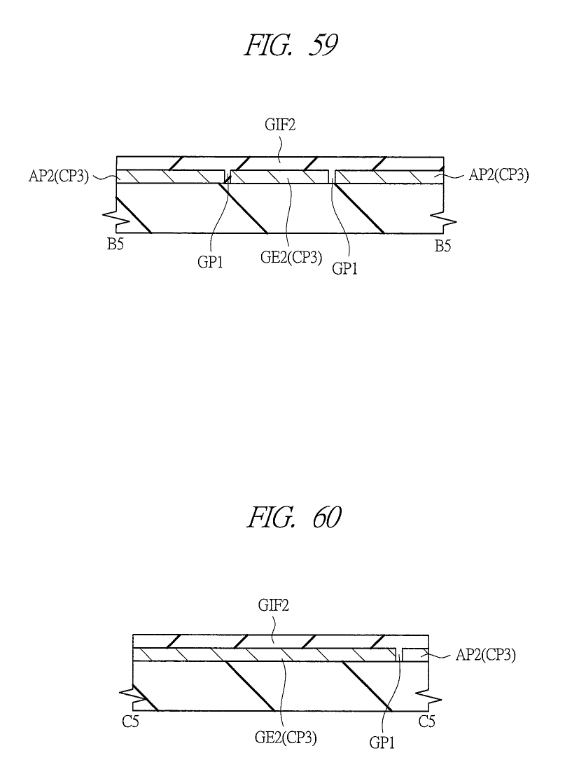

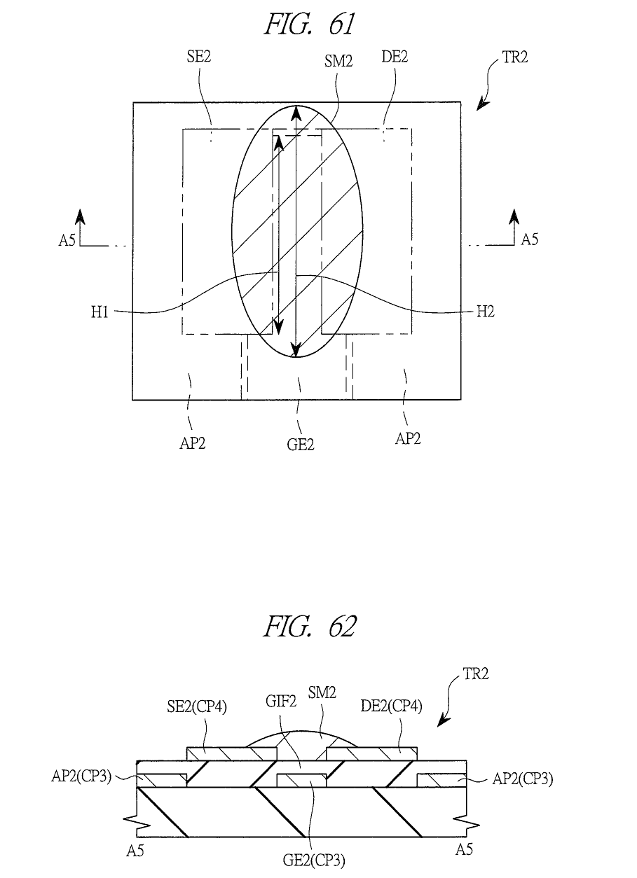

FIGS. 43 to 62 include plan views (plan view of principal part) and cross sectional views (cross sectional view of principal part) in the manufacturing process of the thin film transistor TR2 of the bottom gate structure and an explanatory view (graph). Of FIGS. 43 to 62, FIGS. 44, 46, 50, 52, 57 and 61 are plan views (plan view of principal part) in the manufacturing process of the thin film transistor TR2 and show different processing steps of the same region. Also, of FIGS. 43 to 62, FIGS. 43, 45, 47 to 49, 51, 53 to 55, 58 to 60 and 62 are cross sectional views (cross sectional view of principal part) in the manufacturing process of the thin film transistor TR2. Further, FIG. 56 is an explanatory view (graph) showing a relationship between a film thickness of the resist film and minimum resolvable dimension of the resist film. Also, FIGS. 44 and 45 correspond to the same processing step, and the cross sectional view of the line A5-A5 of FIG. 44 corresponds to FIG. 45. Further, FIGS. 46 to 49 correspond to the same processing step, the cross sectional view of the line A5-A5 of FIG. 46 corresponds to FIG. 47, the cross sectional view of the line B5-B5 of FIG. 46 corresponds to FIG. 48, and the cross sectional view of the line C5-C5 of FIG. 46 corresponds to FIG. 49. Further, FIGS. 50 and 51 correspond to the same processing step, and the cross sectional view of the line A5-A5 of FIG. 50 corresponds to FIG. 51. Further, FIGS. 52 to 55 correspond to the same processing step, the cross sectional view of the line A5-A5 of FIG. 52 corresponds to FIG. 53, the cross sectional view of the line B5-B5 of FIG. 52 corresponds to FIG. 54, and the cross sectional view of the line C5-C5 of FIG. 52 corresponds to FIG. 55. Further, FIGS. 57 to 60 correspond to the same processing step, the cross sectional view of the line A5-A5 of FIG. 57 corresponds to FIG. 58, the cross sectional view of the line B5-B5 of FIG. 57 corresponds to FIG. 59, and the cross sectional view of the line C5-C5 of FIG. 57 corresponds to FIG. 60. Further, FIGS. 61 and 62 correspond to the same processing step, and the cross sectional view of the line A5-A5 of FIG. 61 corresponds to FIG. 62.

Note that FIGS. 44, 46, 50, 52, 57, and 61 are plan views, but in order to make the drawings easy to see, hatching is applied to the resist pattern RP3a in FIG. 44, to the conductor pattern CP3 in FIG. 46, to the resist film RP4 in FIG. 50, to the resist pattern RP4a in FIG. 52, to the conductor pattern CP4 in FIG. 57, and to the semiconductor layer SM2 in FIG. 61.

For the manufacture of the thin film transistor TR2, the substrate SUB1 is first prepared as shown in FIG. 43. The substrate SUB1 has translucency and is preferably a resin substrate. For instance, the substrate SUB1 can be formed from polyethylenetelephtalate (PET). Then, a metal film 2 is formed on the front surface SUB1a of the substrate SUB1. An aluminum film or the like can be used for the metal film 2, and a film thickness thereof is, for instance, about 200 nm and can be formed by, for example, the evaporation method or the like. Thereafter, a resist film (photoresist film) RP3 is formed on the entire surface of the metal film 2.

Next, the resist film RP3 is exposed by using a photomask (not shown) and is then subjected to development, so that a resist pattern (photoresist pattern) RP3a is formed as shown in FIG. 44 and FIG. 45. In the formation of the resist pattern RP3a by exposing the resist film RP3, the photomask for exposure of the resist film RP3 does not need to be accurately aligned with respect to the substrate SUB1 because the pattern is not yet formed on the substrate SUB1. Also, since a conductor pattern CP3 including the gate electrode GE2 and an auxiliary pattern AP2 described later is to be formed by using the same photomask, the relative position of the gate electrode GE2 and the auxiliary pattern AP2 is hardly shifted.

Next, as shown in FIGS. 46 to 49, the metal film 2 is patterned by the etching using the resist pattern RP3a as an etching mask to form the conductor pattern (metal pattern, first conductor pattern) CP3 including the gate electrode (first pattern) GE2 and the auxiliary pattern (correction pattern, second pattern) AP2. Thereafter, the resist pattern RP3a is removed. FIGS. 46 to 49 correspond to the steps of removing the resist pattern RP3a. The conductor pattern CP3 and the resist pattern RP3a have the same pattern shape.

The conductor pattern CP3 is a conductor pattern for forming an electrode or a wiring and is formed from the patterned metal film 2, but it includes the gate electrode GE2 and the auxiliary pattern AP2, and the gate electrode GE2 and the auxiliary pattern AP2 are spaced apart by a narrow gap GP1 and electrically insulated from each other. The gap GP1 is a region where the conductor pattern CP3 is not formed. In other words, the conductor pattern CP3 is formed of the gate electrode GE2 and the auxiliary pattern AP2, and the gate electrode GE2 and the auxiliary pattern AP2 are made of a conductor layer (conductor pattern) of the same layer. Note that the conductor patterns CP4 to CP12 described later are also patterns for forming electrodes or wirings.

The dimension (interval, width) GS1 of the gap GP1 between the gate electrode GE2 and the auxiliary pattern AP2 is smaller (narrower) than the gate length L1 of the gate electrode GE2, that is, GS1<L1. In order to achieve the state where the resist film RP4 described later cannot resolve the portion corresponding to the gap GP1 and can accurately resolve the region corresponding to the gate electrode GE2, the dimension GS1 of the gap GP1 is preferably half the gate length L1 or smaller and is more preferably quarter the gate length L1 or smaller. Note that the dimension of the gap between a certain pattern and another pattern corresponds to an interval (distance) between the ends of the patterns facing each other via the gap, and the same goes for the present embodiment and the following third to sixth embodiments.

The gate electrode GE2 (first pattern) is the gate electrode pattern of the transistor TR2. Therefore, the gate electrode GE2 (first pattern) is assumed as a pattern functioning as the electrode or the wiring.

The auxiliary pattern AP2 (second pattern) is a pattern (pattern functioning as photomask in exposure) provided to define the outline shape of the source electrode SE2 and the drain electrode DE2 formed later, but is an electrically unnecessary conductor pattern. Therefore, by forming the narrow gap GP1 between the auxiliary pattern AP2 and the gate electrode GE2, the electrical connection of the auxiliary pattern AP2 to the gate electrode GE2 is prevented, and the generation of unnecessary parasitic component in the gate electrode GE2 can be prevented. Thus, the auxiliary pattern AP2 is an isolated pattern not connected to the electrode and the wiring, and is a pattern considered as a floating potential. Also in the case where the semiconductor device is used after the completion of the manufacture thereof, the auxiliary pattern AP2 and the auxiliary patterns AP3, AP4 and AP5 of the third to fifth embodiments described later are the floating potential.

After forming the conductor pattern CP3, the resist pattern RP3a is removed, and then the translucent insulating film (gate insulating film) GIF2 is formed to have the film thickness of about 300 nm by using an application method and the like on the entire front surface SUB1a of the substrate SUB1 so as to cover the conductor pattern CP3 (gate electrode GE2 and auxiliary pattern AP2) as shown in FIGS. 50 and 51. The insulating film GIF2 is the insulating film for the gate insulating film. Of the insulating film GIF2, the portion positioned on the gate electrode GE2 functions as the gate insulating film. For instance, an organic insulating film such as polyvinyl phenol (PVP) can be used for the insulating film GIF2. The interior of the gap GP1 is also filled with the insulating film GIF2.

Next, the positive resist film (photoresist film) RP4 is formed on the entire front surface SUB1a of the substrate SUB1, that is, on the insulating film GIF2.

Next, as shown in FIG. 51, light is irradiated from the back surface SUB1b side of the substrate SUB1, and the resist film RP4 is exposed, in other words, the so-called backside exposure is performed. In the backside exposure, only the conductor pattern CP3 formed on the substrate SUB1 functions as the mask, and the exposure photomask is not separately used unlike the exposure process of FIGS. 5, 18 and 34. Also, in the backside exposure, the exposure from the front surface SUB1a side of the substrate SUB1 is not performed. In FIG. 51, the light irradiated onto the substrate SUB1 from the back surface SUB1b side of the substrate SUB1 in the backside exposure is schematically shown with arrows (direction of arrow corresponds to direction of the light).

The substrate SUB1 and the insulating film GIF2 have translucency (light transmitting property), and the light irradiated from the back surface SUB1b side of the substrate SUB1 is irradiated onto the resist film RP4 through the substrate SUB1 and the insulating film GIF2 in the backside exposure process. At this time, since the conductor pattern CP3 is formed of a metal film and has a light reflecting property instead of a light transmitting property, the conductor pattern CP3 functions as a mask (photomask, exposure mask, and light shielding portion). Therefore, the light not shielded by the conductor pattern CP3 (gate electrode GE2 and auxiliary pattern AP2) is irradiated onto the resist film RP4 from the back surface SUB1b side of the substrate SUB1.

Note that, in the present embodiment and the following third to sixth embodiments, the wavelength of the light irradiated onto the resist film RP4 (the resist films RP6, RP7, RP8 and RP11 in the third to sixth embodiments described later) in the backside exposure process has to be in a wavelength range where a latent image is formed in the positive resist film RP4 (the resist films RP6, RP7, RP8 and RP11 in the third to sixth embodiments described later) and has to be a wavelength that transmits through the substrate SUB1 and the insulating film GIF2 (insulating films GIF3, GIF4, GIF5 and GIF 11 in the third to sixth embodiments described later). Further, in the third and the fifth embodiments described later, the wavelength also has to transmit through the semiconductor layers SM3 and SM5 described later. For instance, parallel light of mixed lines of g line, i line and h line of a mercury lamp can be used.

After the backside exposure process as described above, the resist pattern (photoresist pattern) RP4a is formed on the insulating film GIF2 as shown in FIGS. 52 to 55 by developing the resist film RP4. As is apparent from the reference of the comparison of FIG. 46 and FIG. 52, the formed resist pattern RP4a has a pattern shape corresponding to (same as) the conductor pattern CP3 obtained when the gate electrode GE2 (first pattern) and the auxiliary pattern AP2 (second pattern) are connected by removing the gap GP1 for the reasons described below. In other words, the resist pattern RP4a is formed to have a pattern shape substantially the same as that obtained when the conductor pattern is disposed in the gap GP1 in the conductor pattern CP3. Therefore, the resist pattern RP4a is formed on the conductor pattern CP3 and the gap GP1 and is not formed in other regions.

In the present embodiment, the resolutions of the resist film RP3 and the resist film RP4 are not the same. In other words, the resolution of the resist film RP3 for processing the conductor pattern CP3 is made high, thereby enabling the resist film RP3 to resolve the dimension GS1 of the gap GP1. By this means, the portion corresponding to the gap GP1 is formed in the resist pattern RP3a, whereby the narrow gap can be formed between the gate electrode GE2 and the auxiliary pattern AP2 in the conductor pattern CP3. On the other hand, the resist film RP4 of the backside exposure has lower resolution than the resist film RP3, so that the resist film RP4 cannot resolve the dimension GS1 of the gap GP1. By this means, the portion corresponding to the gap GP1 is not formed in the resist pattern RP4a, whereby the pattern shape of the resist pattern RP4a is substantially the same as the pattern shape of the conductor pattern CP3 obtained when the gate electrode GE2 and the auxiliary pattern AP2 are connected by removing the gap GP1.

In general, the resolution of the resist film depends on the resist material and the resist film thickness. The resist film has different resolution depending on the material thereof, but can change the resolution by changing the film thickness even when using the same material. Therefore, for the achievement of high resolution of the resist film RP3 and resolution of the resist film RP4 lower than the resist film RP3 in the present embodiment, a method of adjusting the resist material and a method of adjusting the resist film thickness can be adopted.

In the method of adjusting the resist material, the resolution of the resist film is adjusted by adjusting the material of the resist film. Specifically, the resist film RP3 is formed from a high resolution material, and the resist film RP4 is formed from a low resolution material different from the high resolution material, whereby the resolution of the resist film RP4 is made lower than the resolution of the resist film RP3.

On the other hand, in the method of adjusting the resist film thickness, the resolution of the resist film is adjusted by adjusting the resist film thickness. FIG. 56 shows a correlation between the film thickness of the resist film and the minimum resolvable dimension (resolution limit dimension) of the resist film, in which the horizontal axis of the graph corresponds to a film thickness (arbitrary unit) of the resist film and the vertical axis of the graph corresponds to a minimum resolvable dimension (arbitrary unit) of the resist film. Note that the minimum resolvable dimension of the resist film is referred to as the resolution limit dimension of the resist film.

As schematically shown in FIG. 56, the thicker the film thickness of the resist film, the larger the minimum resolvable dimension (resolution limit dimension) of the resist film becomes, and on the other hand, the thinner the film thickness of the resist film, the smaller the minimum resolvable dimension (resolution limit dimension) of the resist film becomes. Thus, in the method of adjusting the resist film thickness, the same resist material is used for the resist film RP3 and the resist film RP4, the film thickness of the resist film RP3 is made relatively thin to have high resolution, and the film thickness of the resist film RP4 is made larger than the resist film RP3 so that the resist film RP4 has lower resolution than the resist film RP3. Note that the film thickness of the resist films RP3 and RP4 can be controlled to the desired film thickness by adjusting the formed film thickness (applied film thickness) of the resist films RP3 and RP4 in the formation (application) process of the resist films RP3 and RP4.

In the present embodiment, in order to make the resolution of the resist film RP3 high and make the resolution of the resist film RP4 lower than that of the resist film RP3, any of the method of adjusting the resist material, the method of adjusting the resist film thickness, and the method of adjusting both the resist material and the resist film thickness in combination can be used. However, if the method of adjusting the resist film thickness is used, the same resist material can be used for the resist film RP3 and the resist film RP4, and thus an effect of simplifying the manufacturing process and the manufacturing device of the semiconductor device can be obtained. Therefore, the case of using the method of adjusting the resist film thickness will be mainly described below. Accordingly, the same material (resist material) is used for the resist film RP3 and the resist film RP4, and the thickness of the resist film RP4 is made larger than the thickness of the resist film RP3. The same goes for the following third to sixth embodiments, but the resist films RP6, RP7, RP8 and RP11 described later correspond to the resist film RP4 of the present embodiment, and the resist film RP5 described later and the resist films for processing conductor patters CP7, CP9 and CP11 described later correspond to the resist film RP3.

The reason why the resist film RP3 for processing the conductor pattern CP3 is made to have high resolution is to make it possible to resolve the dimension GS1 of the gap GP1 by the resist film RP3, and the resolution limit dimension of the resist film RP3 is made smaller than the dimension GS1 of the gap GP1. As opposed to the present embodiment, if the resist film RP3 cannot resolve the dimension GS1 of the gap GP1, the resist pattern RP3a becomes a resist pattern without an opening corresponding to the gap GP1. In this case, if the gate electrode GE2 and the auxiliary pattern AP2 are formed by etching with using the resist pattern as an etching mask, they are not separated and are electrically connected.

For its prevention, in the present embodiment, the film thickness of the resist film RP3 for processing the conductor pattern CP3 is adjusted to be equal to or smaller than a thickness T1 of the graph of FIG. 56. Here, as is apparent from the graph of FIG. 56, the film thickness of the resist film when the minimum resolvable dimension of the resist film is S1 corresponds to T1, and the film thickness of the resist film when the minimum resolvable dimension of the resist film is S2 corresponds to T2. In the case of the present embodiment, the S1 of the vertical axis of the graph of FIG. 56 corresponds to the dimension GS1 of the gap GP1 (i.e., S1=GS1), and the S2 of the vertical axis of the graph corresponds to the gate length L1 of the gate electrode GE2 (i.e., S2=L1).

In this manner, since the resolution limit dimension of the resist film RP3 becomes smaller than the dimension GS1 of the gap GP1, the resist pattern RP3a formed by exposing and developing the resist film RP3 has a pattern corresponding to the gate electrode GE2 and a pattern corresponding to the auxiliary pattern AP2 as is apparent from FIG. 44, and both patterns are not connected and are separated by a gap corresponding to the gap GP1. Since the metal film 2 is patterned by using the resist pattern RP3a, the conductor pattern CP3 including the gate electrode GE2 and the auxiliary pattern PA2 not connected but separated by the gap GP1 can be formed.

Meanwhile, the reason why the resist film RP4 for backside exposure is made to have low resolution is to achieve the state where the resist film RP4 can resolve the gate length GL1 of the gate electrode GE2 but cannot resolve the dimension GS1 of the gap GP1. As opposed to the present embodiment, if the resist film RP4 can resolve the dimension GS1 of the gap GP1, the formed resist pattern RP4a has the same pattern as the resist pattern RP3a, and the conductor pattern CP4 described later is formed also on the gap GP1.

Also, as opposed to the present embodiment, if the resist film RP4 cannot resolve not only the dimension GS1 of the gap GP1 but also the gate length GL1 of the gate electrode GE2 when the resolution of the resist film RP4 is excessively reduced, the opening pattern separated by the gate electrode GE2 is not formed in the formed resist pattern RP4a, and the pattern in which the source electrode region RP4s and the drain electrode region RP4d are not separated and connected to each other is obtained. In this case, the source electrode SE2 and the drain electrode DE2 formed later are connected unlike the present embodiment.

For its prevention, in the present embodiment, the resist film RP4 is adjusted so that it can resolve the gate length GL1 of the gate electrode GE2 but cannot resolve the dimension GS1 of the gap GP1. More specifically, the resolution limit dimension of the resist film RP4 is made larger than the dimension GS1 of the gap GP1 and equal to or smaller than the gate length GL1 of the gate electrode GE2. Therefore, the film thickness of the resist film RP4 is adjusted to be larger than the thickness T1 and equal to or smaller than the thickness T2 of the graph of FIG. 56.

By this means, the resist film RP4 cannot resolve the portion corresponding to the gap GP1, and the resist pattern RP4a after development has a pattern shape corresponding to (substantially the same as) the conductor pattern CP3 obtained when the portion corresponding to the gap GP1 is not formed and the gate electrode GE2 and the auxiliary pattern AP2 are connected by removing the gap GP1.

Further, since the resist film RP4 can resolve the gate length GL1 of the gate electrode GE2, the gate electrode GE2 acts as a mask in backside exposure, and the exposure region of the resist film RP4 is separated into the source electrode region RP4s and the drain electrode region RP4d by the gate electrode GE2, and the source electrode region RP4s and the drain electrode region RP4d become openings in the resist pattern RP4a after development as shown in FIG. 52. Therefore, the opening RP4b of the resist pattern RP4a has a pattern divided into the source electrode region (source electrode forming opening) RP4s and the drain electrode region (drain electrode forming opening) RP4d by the gate electrode GE2.

As an example of specific numerical values, the gate length GL1 of the gate electrode GE2 is 10 μm, the dimension (width) of the gap GP1 is 1 μm, and a novolac resin resist having a film thickness of 10 μm is used for the resist film RP4.

In this manner, in the present embodiment, even if the backside exposure is performed with using the gate electrode GE2 and the auxiliary pattern AP2 separated via the gap GP1 functioning as the mask (photomask, light shielding portion), the resist pattern RP4a without the portion corresponding to the gap GP1 can be obtained. More specifically, it is possible to obtain the resist pattern RP4a having a pattern similar to that obtained when back surface exposure of the resist film RP4 is performed with using the conductor pattern CP3, in which the gate electrode GE2 and the auxiliary pattern AP2 are connected by removing the gap GP1, as the mask.

Therefore, in the present embodiment, the resist pattern RP4a has a pattern in which the gap corresponding to the gap GP1 is not formed, and the source electrode region RP4s corresponding to the source electrode SE2 to be formed later and the drain electrode region RP4d corresponding to the drain electrode DE2 to be formed later are opened. In other words, the resist pattern RP4a has a pattern in which the resist film does not exist in the source electrode region RP4s and the drain electrode region RP4d separated from each other and the resist film exists in the region other than the source electrode region RP4s and the drain electrode region RP4d, and the resist pattern RP4a exists also on the gap GP1.

Since the gate electrode GE2 functions as a mask in backside exposure, so that the opening of the source electrode region RP4s and the opening of the drain electrode region RP4d are formed, the position of the gate electrode GE2 is automatically and accurately aligned with the positions of the source electrode region RP4s and the drain electrode region RP4d, and the overlapping like the overlapping region 102 is scarcely formed. Thus, the source electrode SE2 and the drain electrode DE2 formed in the source electrode region RP4s and the drain electrode region PR4d later are accurately aligned with the gate electrode GE2. Further, the auxiliary pattern AP2 functions as a mask in backside exposure together with the gate electrode GE2. Therefore, the opening shapes of the source electrode region RP4s and the drain electrode region RP4d (i.e., planar shape of the source electrode SE2 and the drain electrode DE2 formed later) can be adjusted to the desired arbitrary shapes by adjusting the pattern shape of the auxiliary pattern AP2 to the desired arbitrary shape even without using a separately prepared photomask such as the mask MK201. Also, since the auxiliary pattern AP2 is insulated from the gate electrode GE2 by the gap GP1, the pattern shape of the auxiliary pattern AP2 can be adjusted without adversely affecting the gate electrode GE2.

After forming the resist pattern RP4a in this manner, a metal film is formed on the entire front surface SUB1a of the substrate SUB1, that is, on the resist pattern RP4a and the insulating film GIF2 (i.e., insulating film GIF2 exposed at the bottom of the opening region RP4b of the resist pattern RP4a) of the region not covered with the resist pattern RP4a, and then the resist pattern RP4a is dissolved and removed with organic solvent and the like. At this time, the metal film on the resist pattern RP4a is also removed together with the resist pattern RP4a, but the metal film formed on the insulating film FIG2 exposed at the bottom of the opening region RP4b (source electrode region RP4s and drain electrode region RP4d) of the resist pattern RP4a remains without being removed. The remaining metal film becomes the conductor pattern (metal pattern, second conductor pattern) CP4 including the source electrode (source electrode pattern) SE2 and the drain electrode (drain electrode pattern) DE2 as shown in FIGS. 57 to 60. As the metal film for forming the conductor pattern CP4, for instance, a laminated film of a chromium (Cr) film having a film thickness of about 5 nm and a gold (Au) film having a film thickness of about 100 nm formed on the chromium film can be used, and it may be formed by the evaporation method and the like.

As described above, by performing the so-called lift-off process, the conductor pattern CP4 (source electrode SE2 and drain electrode DE2) can be formed on the insulating film GIF2 of a region (source electrode region RP4s and drain electrode region PR4d) not covered with the resist pattern RP4a. In the present embodiment, the conductor pattern CP4 is formed from the source electrode SE2 formed in the source electrode region RP4s and the drain electrode DE2 formed in the drain electrode region RP4d, and the source electrode SE2 and the drain electrode DE2 are made of the conductor layer (conductor pattern) of the same layer. The source electrode SE2 and the drain electrode DE2 are a source electrode pattern and a drain electrode pattern of the transistor TR2, respectively. Therefore, the source electrode SE2 and the drain electrode DE2 can be considered as patterns functioning as electrodes or wirings.

As described above, the resist pattern RP4a is formed on (immediately above) the conductor pattern CP3 and on (immediately above) the gap GP1, and the conductor pattern CP4 is formed in the region not covered with the resist pattern RP4a. Accordingly, the conductor pattern CP4 is formed in alignment with the conductor pattern CP3 on the region where the conductor pattern CP3 is not formed in a plane, but the conductor pattern CP4 is not formed on (immediately above) the gap GP1. Further, the conductor pattern CP4 is not formed on (immediately above) the conductor pattern CP3. In the present embodiment, in the region where the conductor pattern CP3 is not formed in a plane, the conductor pattern CP4 is formed in the entire region other than the gap GP1. Note that “viewed in a plane” in the present embodiment and the following embodiments means that an object is viewed in a plane parallel to the front surface SUB1a of the substrate SUB1.

As shown in FIGS. 61 and 62, after forming the conductor pattern CP4, the semiconductor layer (semiconductor pattern) SM2 is formed on the insulating film GIF2 (i.e., on the insulating film GIF2 on the upper side of the gate electrode GE2) between the source electrode SE2 and the drain electrode DE2.

The semiconductor layer SM2 can be formed by, for instance, applying a semiconductor material (application semiconductor) by the inkjet printing method and the like and drying the same, and the semiconductor layers SM1, SM1a, SM3, SM4, SM5, SM6 and SM11 of the first embodiment and the following third to sixth embodiments can be formed by the similar method. Also, poly(3-hexylthiophen) can be used for the material for forming the semiconductor layer SM2, and poly(3-hexylthiophen) can be used for the material of the semiconductor layers SM1, SM1a, SM3, SM4, SM5, SM6 and SM11 of the first embodiment and the following third to sixth embodiments. The poly(3-hexylthiophen) is called as P3HT, and hereinafter referred to as P3HT.

In this manner, the thin film transistor TR2 in which an overlapping region (corresponding to overlapping region 102) of the gate electrode GE2 and the source electrode SE2 and the drain electrode DE2 is scarcely formed and the position of the gate electrode GE2 is accurately aligned with the positions of the source electrode SE2 and the drain electrode DE2 can be formed on the substrate SUB1.

For instance, the conductor pattern CP3 can be designed by determining the position and the shape of the gate electrode GE2 to be formed, determining the position and the shape of the source electrode SE2 and the drain electrode DE2 to be formed, and then disposing the auxiliary pattern AP2 in the remaining region where they are not formed on the front surface SUB1a of the substrate SUB1. At this time, the narrow gap GP1 is formed between the auxiliary pattern AP2 and the gate electrode GE2 so as to prevent the auxiliary pattern AP2 from being electrically connected to the gate electrode GE2. In this manner, the gate electrode GE2 can be formed to a desired (optimum) shape, and the source electrode SE2 and the drain electrode DE2 of desired (optimum) shape can be formed with using the gate electrode GE2 and the auxiliary pattern AP2 functioning as photomasks in backside exposure.

As described with reference to FIGS. 13 and 14, the formed position of the semiconductor layer (corresponds to semiconductor layer SM201 in FIGS. 13 and 14 and semiconductor layer SM2 in the present embodiment) shifts frequently. However, in the present embodiment, the channel width is defined by the pattern shapes of the gate electrode GE2, the source electrode SE2 and the drain electrode DE2, and the channel width does not change even if the formed position of the semiconductor layer shifts as in FIGS. 13 and 14. Therefore, even if the semiconductor layer SM2 is formed by using such means with poor placement accuracy (accuracy of application position) as the inkjet printing, the thin film transistor TR2 of uniform performance can be formed.

Note that, for defining the channel width by the pattern shapes of the source electrode SE2 and the drain electrode DE2, the dimension H2 in the channel width direction of the semiconductor layer SM2 needs to be set larger than the dimension H1 in the channel width direction of the portion of the gate electrode GE2 positioned between the source electrode SE2 and the drain electrode DE2 as shown in FIG. 61 (i.e., H1<H2). The channel width direction mentioned here is the direction along the channel width and is the same as the direction along the gate width. By this means, of the gate electrode GE2, the portion positioned between the source electrode SE2 and the drain electrode DE2 is entirely covered with the semiconductor layer SM2, and the channel width is defined by the dimension H1 instead of the dimension H2 of the semiconductor layer SM2. Since the dimension H1 can be formed sufficiently accurately compared with the dimension H2, the thin film transistor TR2 having uniform channel width can be formed.

The effect that the thin film transistor of uniform performance can be formed even if the method in which the accuracy is bad is used to form the semiconductor layer SM2 is obtained not only in the present embodiment but also in the third to sixth embodiments described later. In the case of the third to sixth embodiments described later, however, the semiconductor layer SM2 described in relation is replaced with the semiconductor layers SM3, SM4, SM5 and SM11 described later, the source electrode SE2 is replaced with the source electrodes SE3, SE4, SE5, SE14, SE15 and SE16 described later, the drain electrode DE2 is replaced with the drain electrodes DE3, DE4, DE5, DE14, DE15 and DE16 described later, and the gate electrode GE2 is replaced with the gate electrodes GE3, GE4, GE5, GE14, GE15 and GE16 described later.

Further, in the present embodiment, the conductor pattern CP3 functions as the mask in backside exposure, and thus the gate electrode GE2 as well as the auxiliary pattern AP2 functions to define the opening shape of the source electrode region RP4s and the drain electrode region RP4d of the resist pattern RP4a, whereby the shape of the source electrode SE2 and the drain electrode DE2 can be defined. Therefore, the photomask for defining the opening shape of the source electrode region RP4s and the drain electrode region RP4d like the mask MK201 does not need to be separately used in the backside exposure process. Accordingly, since an accurate alignment of a photomask such as the mask MK201 and the substrate SUB1 is not necessary, an expensive exposure device having alignment mechanism is not required. Therefore, the manufacturing cost of the semiconductor device can be reduced.

Also, in the second reviewed example described with reference to FIG. 3 to FIG. 12, the gate electrode GE201 functions as the mask in the backside exposure, so that the mutually facing ends of the source electrode SE201 and the drain electrode DE201 are aligned with the ends of the gate electrode GE201. However, due to the shift in alignment between the mask MK201 and the substrate SUB201, the outline positions of the source electrode SE201 and the drain electrode DE201 (position of the ends other than those aligned with the gate electrode GE201) may shift with respect to the gate electrode GE201.

For its prevention, in the present embodiment, the conductor pattern CP3 functions as a mask in the backside exposure of the resist film RP4. The conductor pattern CP3 is formed by the resist pattern RP3a formed by using the same photomask, and the relative positions of the gate electrode GE2 and the auxiliary pattern AP2 are scarcely shifted even if misalignment between the substrate SUB1 and the conductor pattern CP3 occurs. Therefore, the source electrode SE2 and the drain electrode DE2 are formed by using the resist pattern RP4a formed by using the gate electrode GE2 and the auxiliary pattern AP2, in which shift (fluctuation) in the relative positions does not occur, as masks in exposure.

Accordingly, in the present embodiment, not only the mutually facing ends of the source electrode SE2 and the drain electrode DE2 are aligned with the ends of the gate electrode GE2, but also the outline position (position of the ends other than those aligned with the gate electrode GE2) of the source electrode SE2 and the drain electrode DE2 does not shift with respect to the gate electrode GE2 by the misalignment. By this means, the formed position and the shape (dimension) of the source electrode SE2 and the drain electrode DE2 with respect to the gate electrode GE2 can be accurately formed to the desired position and shape. Thus, the performance of the semiconductor device can be enhanced. Furthermore, the planar dimension of the transistor can be reduced (miniaturized), and the semiconductor device can be miniaturized (area reduction).

Further, in the semiconductor devices of the present embodiment and the following third to sixth embodiments, the first conductor pattern and the second conductor pattern for forming the electrode or the wiring are formed in different layers on the substrate SUB1 with interposing an insulating film between the layers. The second conductor pattern on the upper layer side thereof is formed so as to be aligned with the first conductor pattern in the region where the first conductor pattern on the lower layer side is not formed. Therefore, the first conductor pattern on the lower layer side and the second conductor pattern on the upper layer side are not overlapped in a plane (excluding connection patterns 13, 23 and 31 described later), thereby suppressing or preventing unnecessary parasitic component (parasitic capacitance) from generating between the first conductor pattern and the second conductor pattern. Therefore, since the parasitic component between the electrode and the wiring formed from the first conductor pattern on the lower layer side and the electrode and the wiring formed from the second conductor pattern on the upper layer side can be suppressed or prevented, the performance of the semiconductor device can be enhanced. Note that the first conductor pattern mentioned here corresponds to the conductor pattern CP3 in the present embodiment and corresponds to the conductor patterns CP5, CP7, CP9 and CP11 in the third to sixth embodiments described later, respectively. Also, the second conductor pattern mentioned here corresponds to the conductor pattern CP4 in the present embodiment and corresponds to the conductor patterns CP6, CP8, CP10 and CP12 in the third to sixth embodiments described later, respectively. Note that the state where the pattern (first conductor pattern) and another pattern (second conductor pattern) formed in different layers on the substrate SUB1 are aligned means that the positions of the ends of both the patterns substantially match in the vertical direction (direction perpendicular to the front surface SUB1a of the substrate SUB1).

Further, the resin substrate has an advantage of light weight and strong impact resistance compared with the glass substrate, but misalignment tends to occur when exposed by using the photomask because heat resisting property is low and heat distortion is large. However, in the present embodiment, the conductor pattern CP4 is formed by making the conductor pattern CP3 formed on the substrate SUB1 function as the photomask without using a photomask that requires alignment. Therefore, even if heat distortion occurs in the substrate SUB1, the relative position of the gate electrode GE2 contained in the conductor pattern CP3 scarcely shifts (fluctuates) with respect to those of the source electrode SE2 and the drain electrode DE2 contained in the conductor pattern CP4. Thus, the effect is large if the present embodiment is applied when the resin substrate (plastic substrate) made of resin (plastic) is used for the substrate SUB1. The same goes for the following third to sixth embodiments. That is, the second to sixth embodiments are particularly effective when a resin substrate (plastic substrate) is used for the substrate SUB1.

Further, in the description of the present embodiment above, the conductor pattern CP3 is formed by patterning the metal film formed on the substrate SUB1 by the lithography method and the etching method, but the conductor pattern CP3 can be formed by printing methods such as the inkjet printing, gravure printing, offset printing and pad printing using conductive ink such as silver ink. The same goes for the forming methods of the conductor patterns CP1, CP1a, CP5, CP7, CP9 and CP11 of the first embodiment and the following third to sixth embodiments.

Also, in the description of the present embodiment above, the conductor pattern CP4 is formed by evaporating a metal film such as the laminated film of a chromium film and a gold film and then performing the lift-off process. Alternatively, the conductor pattern CP4 made of silver ink can be formed by performing the lift-off process after applying the silver ink on the entire front surface SUB1a of the substrate SUB1 instead of the metal film. The same goes for the forming method of the conductor patterns CP2, CP2a, CP6, CP8, CP10 and CP12 of the first embodiment and the following third to sixth embodiments.

Further, in the description of the present embodiment above, polyvinyl phenol is used for the insulating film GIF2, but polyimide or silicon oxide and the like may be used instead of the polyvinyl phenol. The same goes for the materials of the insulating films GIF1, GIF1a, GIF3, GIF4, GIF5 and GIF11 of the first embodiment and the following third to sixth embodiments.

Further, in the description of the present embodiment above, P3HT is used for the semiconductor layer SM2, but polyfluolen-thiophen copolymer (F8T2), pentacene derivative, or polytoriarilamine (PTAA) and the like may be used instead of P3HT. The same goes for the materials of the semiconductor layers SM1a, SM1b, SM3, SM4, SM5 and SM11 of the first embodiment and the following third to sixth embodiments.

Further, in the description of the present embodiment above, the semiconductor layer SM2 is formed by the inkjet printing method, but printing methods such as gravure printing, offset printing and pad printing may be used instead of the inkjet printing method. The same goes for the forming method of the semiconductor layers SM1a, SM1b, SM3, SM4, SM5 and SM11 of the first embodiment and the following third to sixth embodiments.

Also, the thin film transistor described in the present embodiment uses the application semiconductor for the semiconductor layer SM2, but a silicon thin film transistor may be fabricated by using amorphous silicon semiconductor instead of the application semiconductor. However, in this case, the material of high heat resistance needs to be used for the substrate SUB1 in accordance with the process temperature of the film forming process of the amorphous silicon semiconductor. The same goes for the first embodiment and the following third to sixth embodiments, but the semiconductor layer SM2 of the present embodiment corresponds to the semiconductor layers SM1a, SM1b, SM3, SM4, SM5 and SM11 in the first embodiment and the following third to sixth embodiments.

### Third Embodiment

In the second embodiment, the thin film transistor TR2 of bottom gate structure has been described, and the thin film transistor TR3 of top gate structure will be described in the present embodiment.

The manufacturing process of the semiconductor device of the present embodiment, that is, the thin film transistor TR3 of top gate structure will be described with reference to the drawings.

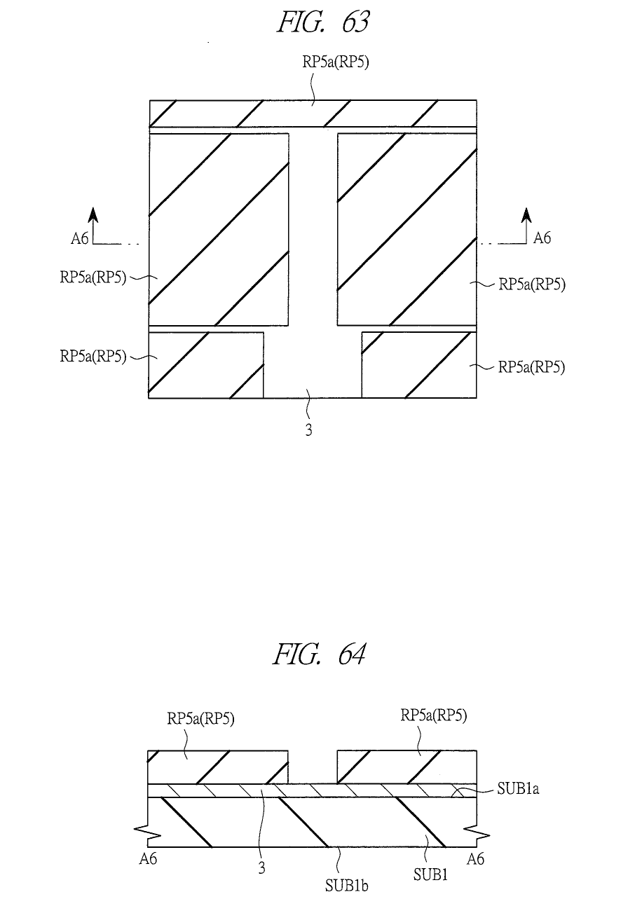

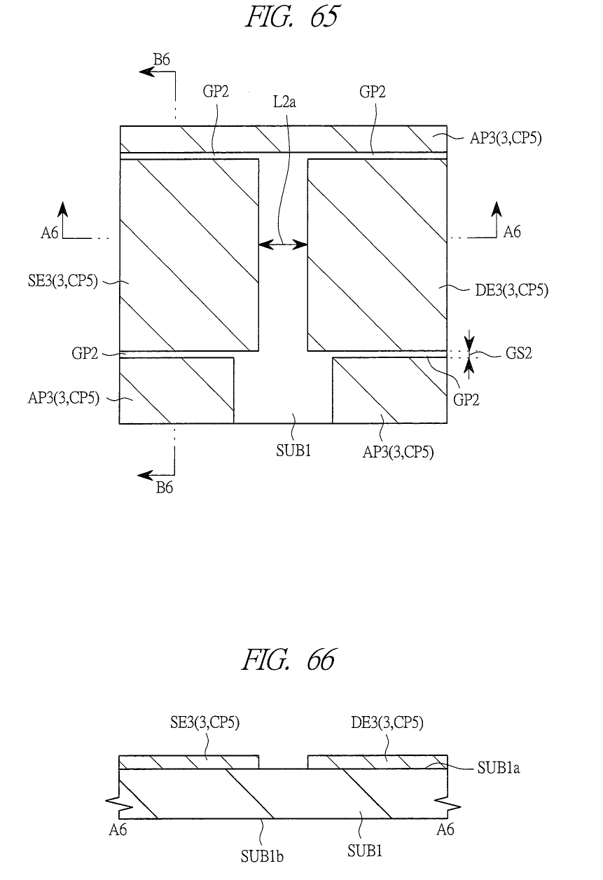

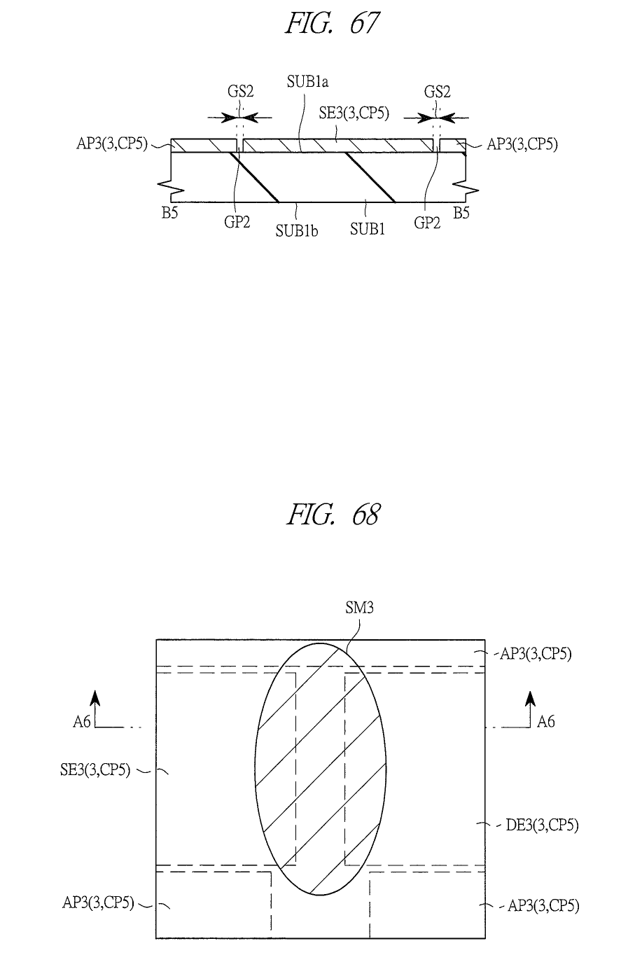

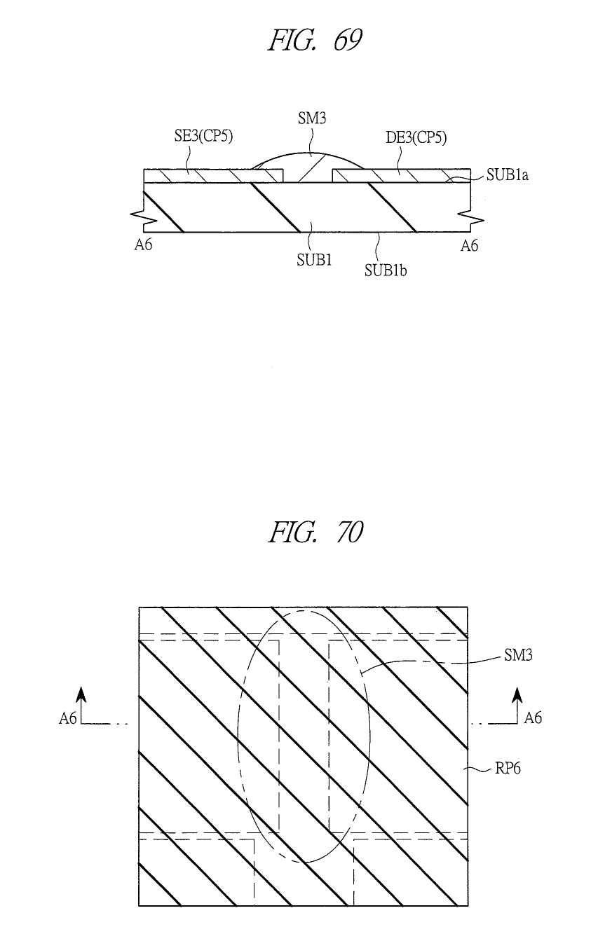

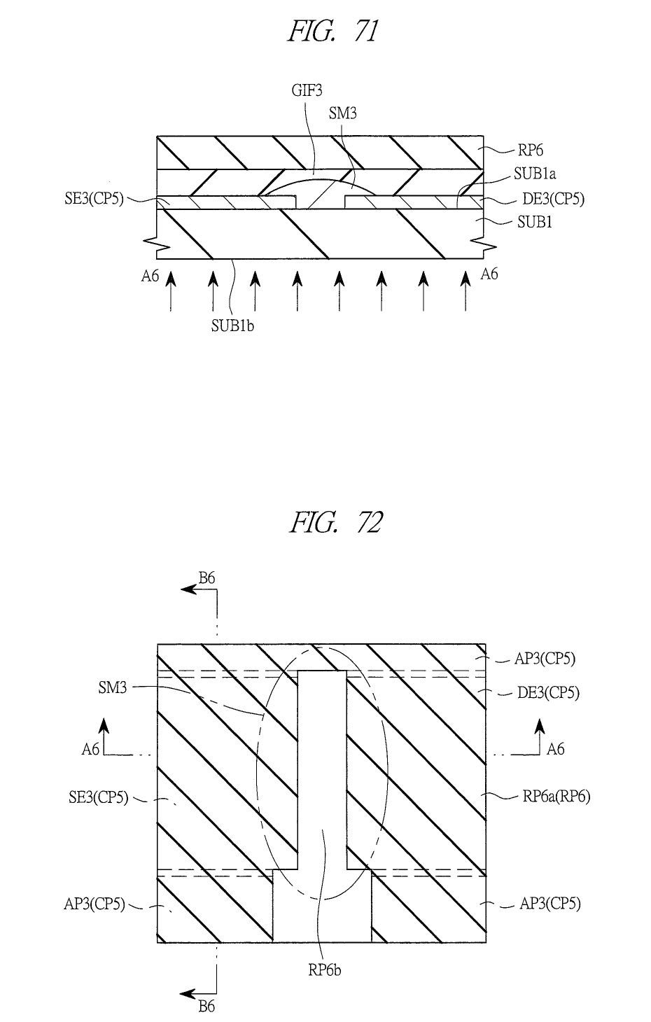

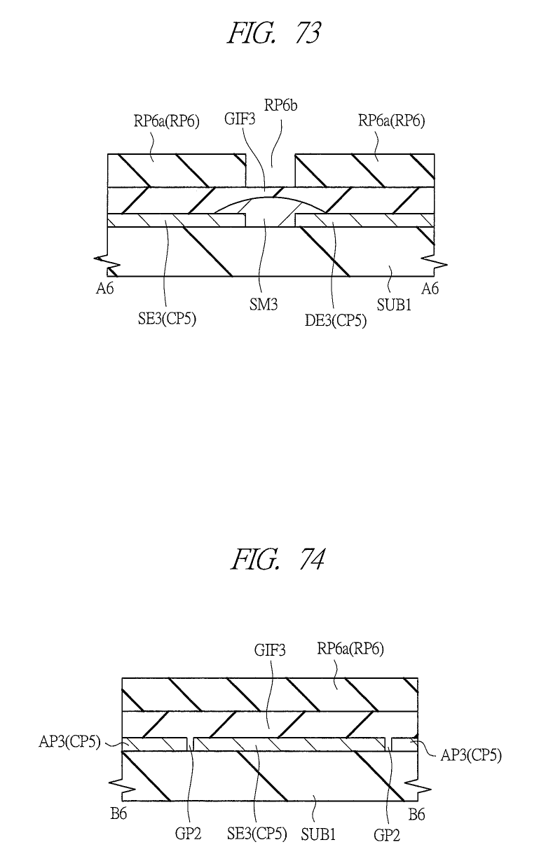

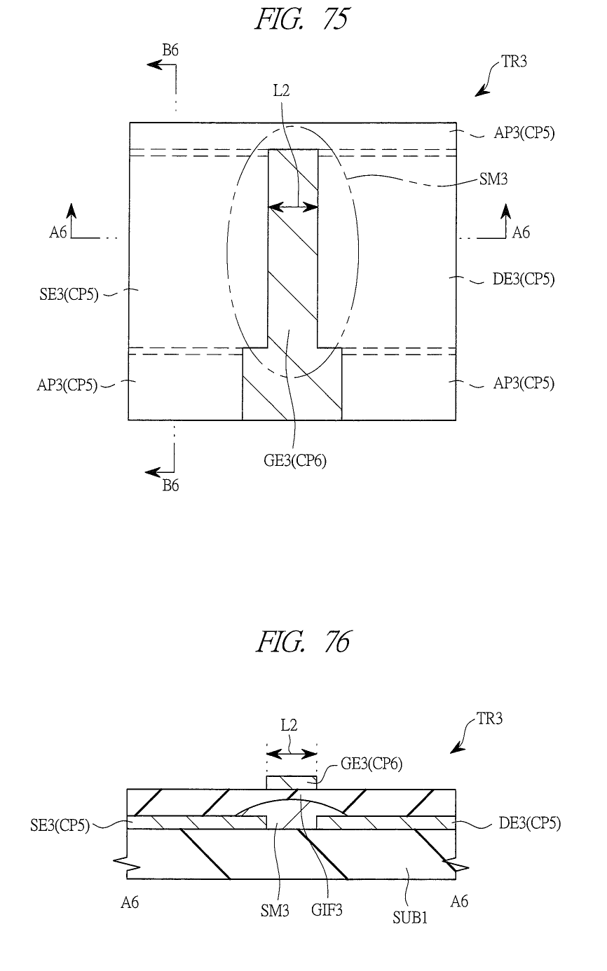

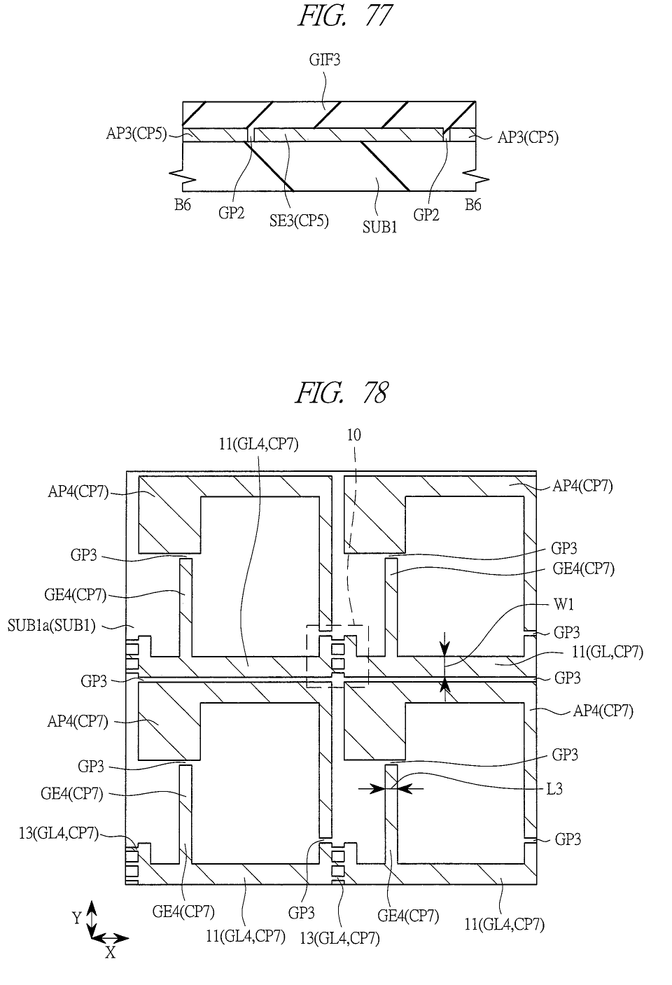

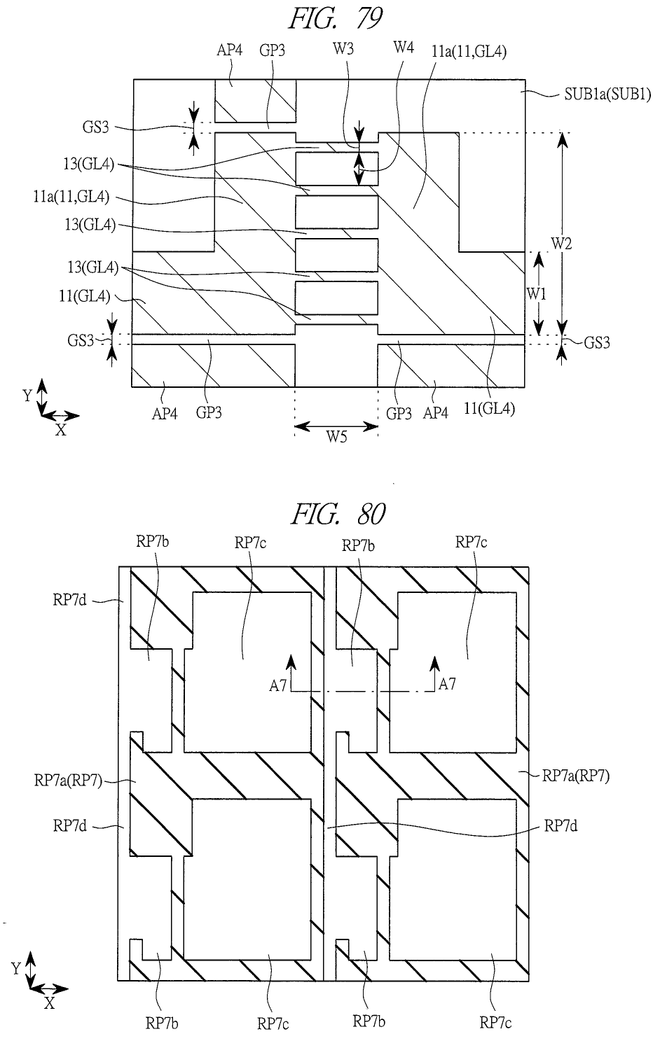

FIGS. 63 to 77 include plan views (plan view of principal part) and cross sectional views (cross sectional view of principal part) in the manufacturing process of the thin film transistor TR3 of the top gate structure. Of FIGS. 63 to 77, FIGS. 63, 65, 68, 70, 72 and 75 are plan views (plan view of principal part) in the manufacturing process of the thin film transistor TR3 and show different processing steps of the same region. Also, of FIGS. 63 to 77, FIGS. 64, 66, 67, 69, 71, 73, 74, 76 and 77 are cross sectional views (cross sectional view of principal part) in the manufacturing process of the thin film transistor TR3. Further, FIGS. 63 and 64 correspond to the same processing step and the cross sectional view of the line A6-A6 of FIG. 63 corresponds to FIG. 64. Also, FIGS. 65 to 67 correspond to the same processing step, the cross sectional view of the line A6-A6 of FIG. 65 corresponds to FIG. 66, and the cross sectional view of the line B6-B6 of FIG. 65 corresponds to FIG. 67. Also, FIGS. 68 and 69 correspond to the same processing step and the cross sectional view of the line A6-A6 of FIG. 68 corresponds to FIG. 69. Also, FIGS. 70 and 71 correspond to the same processing step and the cross sectional view of the line A6-A6 of FIG. 70 corresponds to FIG. 71. Also, FIGS. 72 to 74 correspond to the same processing step, the cross sectional view of the line A6-A6 of FIG. 72 corresponds to FIG. 73, and the cross sectional view of the line B6-B6 of FIG. 73 corresponds to FIG. 74. Also, FIGS. 75 to 77 correspond to the same processing step, the cross sectional view of the line A6-A6 of FIG. 75 corresponds to FIG. 76, and the cross sectional view of the line B6-B6 of FIG. 75 corresponds to FIG. 77.

FIGS. 63, 65, 68, 70, 72 and 75 are plan views, but in order to make the drawings easy to see, hatching is applied to the resist pattern RP5a in FIG. 63, to the conductor pattern CP5 in FIG. 65, to the semiconductor layer SM3 in FIG. 68, to the resist film RP6 in FIG. 70, to the resist pattern RP6a in FIG. 72 is, and to the conductor pattern CP6 in FIG. 75.

For the manufacture of the thin film transistor TR3, the substrate SUB1 similar to that of the second embodiment is first prepared as shown in FIGS. 63 and 64. Then, a metal film 3 is formed on the front surface SUB1a of the substrate SUB1. For the metal film 3, a laminated film of a chromium (Cr) film having a film thickness of about 5 nm and a gold (Au) film having a film thickness of about 100 nm formed on the chromium film can be used, and the metal film 3 can be formed by the evaporation method. Thereafter, a resist film (photoresist film) RP5 is formed on the entire surface of the metal film 3.

Next, the resist film RP5 is exposed by using a photomask (not shown) and then developed, thereby forming a resist pattern (photoresist pattern) RP5a as shown in FIG. 63 and FIG. 64. When forming the resist pattern RP5a by exposing the resist film RP5, the photomask for exposure of the resist film RP5 does not need to be accurately aligned with respect to the substrate SUB1 because the pattern is not yet formed on the substrate SUB1. Also, since a conductor pattern CP5 including the source electrode SE3, the drain electrode DE3 and the auxiliary pattern AP3 described later is formed by using the same photomask, the relative position of the source electrode SE3 and the drain electrode DE3 and the auxiliary pattern AP3 is scarcely shifted.

Next, as shown in FIGS. 65 to 67, the metal film 3 is patterned by etching using the resist pattern RP5a as the etching mask, and the conductor pattern (metal pattern, first conductor pattern) CP5 including the source electrode (source electrode pattern, first pattern) SE3, the drain electrode (drain electrode pattern, first pattern) DE3 and the auxiliary pattern (second pattern, correction pattern) AP3 is formed. Thereafter, the resist pattern RP5a is removed. Note that FIGS. 65 to 67 correspond to the steps of removing the resist pattern RP5a. The conductor pattern CP5 and the resist pattern RP5a have the same pattern shape.

The conductor pattern CP5 is formed of the patterned metal film 3, but it includes the source electrode SE3, the drain electrode DE3 and the auxiliary pattern AP3, and the auxiliary pattern AP3 is spaced apart and electrically insulated from the source electrode SE3 and the drain electrode DE3 by a narrow gap GP2. The gap GP2 is a region where the conductor pattern CP5 is not formed. In other words, the conductor pattern CP5 is formed from the source electrode SE3, the drain electrode DE3 and the auxiliary pattern AP3, and the source electrode SE3, the drain electrode DE3 and the auxiliary pattern AP3 are formed of a conductor layer (conductor pattern) of the same layer.

Also, the source electrode SE2 and the drain electrode DE2 are spaced apart by a distance larger than the gap GP2. That is, the dimension (interval, width) GS2 of the gap GP2 between the auxiliary pattern AP3 and the source electrode SE3 and the drain electrode DE3 is smaller (narrower) than the interval L2a between the source electrode SE3 and the drain electrode DE3, that is, GS2<L2a. Note that the interval L2a between the source electrode SE3 and the drain electrode DE3 is the same as the gate length L2 of the gate electrode GE3 to be formed later (i.e., L2a=L2) and is almost the same as the gate length L1 of the gate electrode GE2 of the second embodiment. Further, the dimension GS2 of the gap GP2 between the auxiliary pattern AP3 and the source electrode SE3 and the drain electrode DE3 is almost the same as the dimension GS1 of the gap GP1 of the second embodiment. Also, in order to achieve the state where the resist film RP6 described later cannot resolve the portion corresponding to the gap GP2 and can accurately resolve the interval L2a between the source electrode SE3 and the drain electrode DE3, the dimension GS2 of the gap GP2 is preferably half the interval L2a or smaller and is more preferably quarter the interval L2a or smaller.

The source electrode SE3 and the drain electrode DE3 (first pattern) are the source electrode pattern and the drain electrode pattern of the transistor TR3, respectively. Therefore, the source electrode SE3 and the drain electrode DE3 (first pattern) are assumed as a pattern functioning as the electrode or the wiring.

The auxiliary pattern AP3 (second pattern) is a pattern (pattern functioning as photomask in exposure) provided to define the outer shape of the gate electrode GE3 formed later, but is an electrically unnecessary conductor pattern. Thus, by forming the narrow gap GP2 between the auxiliary pattern AP3 and the source electrode SE3 and the drain electrode DE3, the auxiliary pattern AP3 is prevented from being electrically connected to the source electrode SE3 and the drain electrode DE3, and the generation of unnecessary parasitic component in the source electrode SE3 and the drain electrode DE3 can be prevented. Thus, the auxiliary pattern AP3 is an isolated pattern not connected to the electrode and the wiring and is a pattern considered as a floating potential.

After forming the conductor pattern CP5, the resist pattern RP5a is removed, and then as shown in FIGS. 68 and 69, the translucent semiconductor layer (semiconductor pattern) SM3 is formed by a method similar to the semiconductor layer SM2 on the substrate SUB1 between the source electrode SE3 and the drain electrode DE3 (i.e., on the substrate SUB1 on the lower side of the gate electrode GE3 to be formed later). As the material for forming the semiconductor layer SM3, the same material as that of the semiconductor layer SM2 of the second embodiment can be used. Translucency is not essential for the semiconductor layer SM2 of the second embodiment and the semiconductor layer SM4 of the fourth embodiment described later because they are formed after the backside exposure, but translucency is required for the semiconductor layer SM3 of the present embodiment and the semiconductor layer SM5 of the fifth embodiment described later because they are formed before the backside exposure.

After forming the semiconductor layer SM3, as shown in FIG. 70 and FIG. 71, a translucent insulating film (gate insulating film) GIF3 is formed to have a film thickness of about 300 nm on the entire front surface SUB1a of the substrate SUB1 so as to cover the conductor pattern CP5 (source electrode SE3, drain electrode DE3 and auxiliary pattern AP3) and the semiconductor layer SM3. The insulating film GIF3 is the insulating film for the gate insulating film. Of the insulating film GIF3, the portion positioned below the gate electrode GE3 formed later functions as the gate insulating film. As the material of the insulating film GIF3, the same material as that of the insulating film GIF2 of the second embodiment can be used. The interior of the gap GP2 is also filled with the insulating film GIF3.

Next, the positive resist film (photoresist film) RP6 is formed on the entire front surface SUB1a of the substrate SUB1, that is, on the insulating film GIF3.

Next, as shown in FIG. 71, light is irradiated from the back surface SUB1b side of the substrate SUB1, and the resist film RP6 is exposed, in other words, the so-called backside exposure is performed. In the backside exposure, only the conductor pattern CP5 formed on the substrate SUB1 functions as the mask, and the exposure photomask is not separately used unlike the exposure process of FIGS. 5, 18 and 34. Also, in the backside exposure, the exposure from the front surface SUB1a side of the substrate SUB1 is not performed. In FIG. 71, the light irradiated onto the substrate SUB1 from the back surface SUB1b side of the substrate SUB1 in the backside exposure is schematically shown with arrows (direction of arrow corresponds to direction of the light).

The substrate SUB1, the semiconductor layer SM3 and the insulating film GIF3 have translucency (light transmitting property), and the light irradiated from the back surface SUB1b side of the substrate SUB1 is irradiated onto the resist film RP6 through the substrate SUB1, the semiconductor layer SM3 and the insulating film GIF3 in the backside exposure process. At this time, since the conductor pattern CP5 is made of a metal film and has a light reflecting property instead of a light transmitting property, the conductor pattern CP5 functions as a mask (photomask, exposure mask, light shielding portion). Therefore, the light not shielded by the conductor pattern CP5 (source electrode SE3, drain electrode DE3, and auxiliary pattern AP3) is irradiated onto the resist film RP6 from the back surface SUB1b side of the substrate SUB1.

After the backside exposure process as described above, the resist pattern (photoresist pattern) RP6a as shown in FIGS. 72 to 74 is formed on the insulating film GIF2 by developing the resist film RP6. As is apparent from the reference of the comparison of FIG. 65 and FIG. 72, for the reasons similar to the resist pattern RP4a of the second embodiment, the formed resist pattern RP6a has a pattern shape corresponding to (same as) the conductor pattern CP5 obtained when the auxiliary pattern AP3 (second pattern) is connected to the source electrode SE3 and the drain electrode DE3 (first pattern) by removing the gap GP2. In other words, the resist pattern RP6a is formed to a pattern shape substantially the same as that obtained when the conductor pattern is disposed also in the gap GP2 in the conductor pattern CP5. Therefore, the resist pattern RP6a is formed on the conductor pattern CP5 and on the gap GP2 and is not formed in the other regions.

More specifically, similar to the resist film RP3 of the second embodiment, also in the present embodiment, the resolution of the resist film RP5 for processing the conductor pattern CP5 is made high and the resolution limit dimension of the resist film RP5 is made smaller than the dimension GS2 of the gap GP2, thereby enabling the resist film RP5 to resolve the dimension GS2 of the gap GP2. Therefore, the film thickness of the resist film RP5 for processing the conductor pattern CP5 is adjusted to be equal to or smaller than the thickness T1 of the graph of FIG. 56. Note that, in the present embodiment, S1 of the vertical axis of the graph of FIG. 56 corresponds to the dimension GS2 of the gap GP2 (i.e., S1=GS2), and S2 of the vertical axis of the graph corresponds to the interval L2a between the source electrode SE3 and the drain electrode DE3 (i.e., S2=L2a).

In this manner, since the resolution limit dimension of the resist film RP5 becomes smaller than the dimension GS2 of the gap GP2, the resist pattern RP5a in which the portion corresponding to the gap GP2 is formed can be formed. By patterning the metal film 3 by using the resist pattern RP5a, the conductor pattern CP5 including the auxiliary pattern AP3, the source electrode SE3 and the drain electrode DE3 separated by the gap GP2 without being connected can be formed.

On the other hand, similar to the resist film RP4 of the second embodiment, the resolution of the resist film RP6 of the present embodiment is made lower than that of the resist film RP5, whereby the state where the resist film RP6 can resolve the interval L2a between the source electrode SE3 and the drain electrode DE3 but cannot resolve the dimension GS2 of the gap GP2 is achieved. More specifically, the resolution limit dimension of the resist film RP6 in the backside exposure process is made larger than the dimension GS2 of the gap GP2 and equal to or smaller than the interval L2a between the source electrode SE3 and the drain electrode DE3. Therefore, the film thickness of the resist film RP6 is adjusted to be larger than the thickness T1 of the graph of FIG. 56 and equal to or smaller than the thickness T2 of the graph of FIG. 56.

By this means, since the resolution limit dimension of the resist film RP6 becomes larger than the dimension GS2 of the gap GP2, the portion corresponding to the gap GP2 cannot be resolved, and the resist pattern RP6a after development has a pattern shape corresponding to (substantially the same as) the conductor pattern CP5 obtained when the portion corresponding to the gap GP2 is not formed and the auxiliary pattern AP3 and the source electrode SE3 and the drain electrode DE3 are connected by removing the gap GP2.

Also, since the resist film RP6 can resolve the interval L2a between the source electrode SE3 and the drain electrode DE3, the source electrode SE3 and the drain electrode DE3 act as masks in the backside exposure, and the exposure region (gate electrode region PR6b) of the resist film RP6 is formed in a region between the source electrode SE3 and the drain electrode DE3 when viewed in a plane. After development, the gate electrode region RP6b of the exposure region becomes the opening of the resist pattern RP6a as in FIG. 72. Thus, the gate electrode region RP6b which is the opening of the formed resist pattern RP6a is formed between the source electrode SE3 and the drain electrode DE3 when viewed in a plane, and has a pattern aligned with the source electrode SE3 and the drain electrode DE3.

As an example of specific numerical values, the dimension GS2 of the gap GP2 is 1 μm, the interval L2a between the source electrode SE3 and the drain electrode DE3 is 10 μm, and a novolac resin resist having a film thickness of 10 μm is used for the resist film RP6.

In this manner, in the present embodiment, even if the backside exposure is performed with using the auxiliary pattern AP3, the source electrode SE3 and the drain electrode DE3 separated via the gap GP2 functioning as the masks, the resist pattern RP6a without the portion corresponding to the gap GP2 can be obtained. More specifically, it is possible to obtain the resist pattern RP6a having a pattern similar to that obtained when back surface exposure of the resist film RP6 is performed with using the conductor pattern CP5, in which the auxiliary pattern AP3, the source electrode SE3 and the drain electrode DE3 are connected by removing the gap GP2, as the mask.

Therefore, in the present embodiment, the resist pattern RP6a has a pattern in which the gap corresponding to the gap GP2 is not formed and the gate electrode region RP6b corresponding to the gate electrode GE3 to be formed later is opened. In other words, the resist pattern RP6a has a pattern in which the resist film does not exist in the gate electrode region RP6b and the resist film is present in the region other than the gate electrode region RP6b, and the resist pattern RP6a is present also on the gap GP2.

Since the opening of the gate electrode region RP6b is formed with using the source electrode SE3 and the drain electrode DE3 functioning as a mask in backside exposure, the position of the gate electrode region RP6b is automatically and accurately aligned with the positions of the source electrode SE3 and the drain electrode DE3, and the overlapping as in the overlapping region 102 scarcely occurs. Thus, the gate electrode GE3 formed later in the gate electrode region RP6 is accurately aligned with the source electrode SE2 and the drain electrode DE2. Also, the auxiliary pattern AP3 functions as a mask in backside exposure together with the source electrode SE3 and the drain electrode DE3. Therefore, by adjusting the pattern shape of the auxiliary pattern AP3 to the desired arbitrary shape, the opening shape of the gate electrode region RP6 of the resist pattern RP6a (i.e., planar shape of the gate electrode GE2 formed later) can be adjusted to the desired arbitrary shape even if the separately prepared photomask like the mask MK201 is not used. Further, since the auxiliary pattern AP3 is insulated from the source electrode SE3 and the drain electrode DE3 by the gap GP2, the pattern shape of the auxiliary pattern AP2 can be adjusted without adversely affecting the source electrode SE3 and the drain electrode DE3.

After forming the resist pattern RP6a in this manner, a metal film made of an aluminum film is formed on the entire front surface SUB1a of the substrate SUB1, that is, on the resist pattern RP6a and the insulating film GIF3 of the region not covered with the resist pattern RP6a (i.e., insulating film GIF3 exposed at the bottom of the opening region of the resist pattern RP6a) by an evaporation method and the like, and then, the resist pattern RP6a is dissolved and removed with organic solvent and the like. At this time, the metal film on the resist pattern RP6a is also removed together with the resist pattern RP6a, but the metal film formed on the insulating film GIF3 exposed at the bottom of the opening region of the resist pattern RP6a (gate electrode region RP6b) remains without being removed and becomes the conductor pattern (metal pattern, second conductor pattern) CP6 including the gate electrode (gate electrode pattern) GE3 as shown in FIGS. 75 to 77. The conductor pattern CP6 formed in the gate electrode region RP6 becomes the gate electrode GE3.

As described above, by performing the so-called lift-off process, the conductor pattern CP6 or the gate electrode GE3 herein can be formed on the insulating film GIF3 of a region (gate electrode region RP6b) not covered with the resist pattern RP6a. In the present embodiment, the gate electrode GE3 is the gate electrode pattern of the transistor TR3. Therefore, the gate electrode GE3 can be considered as a pattern functioning as an electrode or a wiring.

As described above, the resist pattern RP6a is formed on (immediately above) the conductor pattern CP5 and on (immediately above) the gap GP2, and the conductor pattern CP6 is formed in the region not covered with the resist pattern RP6a. Therefore, the conductor pattern CP6 is formed in alignment with the conductor pattern CP5 on the region in which the conductor pattern CP5 is not formed when viewed in a plane, but the conductor pattern CP6 is not formed on (immediately above) the gap GP2. Further, the conductor pattern CP6 is not formed on (immediately above) the conductor pattern CP5. In the present embodiment, the conductor pattern CP6 is formed on the region in which the conductor pattern CP5 is not formed when viewed in a plane in the entire region other than the gap GP2.

In this manner, the thin film transistor TR3 in which an overlapping region (corresponding to overlapping region 102) of the gate electrode GE3 and the source electrode SE3 and the drain electrode DE3 is scarcely formed and the position of the gate electrode GE3 is accurately aligned with the positions of the source electrode SE3 and the drain electrode DE3 can be formed on the substrate SUB1.

For instance, the conductor pattern CP5 can be designed by determining the position and the shape of the source electrode SE3 and the drain electrode DE3 to be formed, determining the position and the shape of the gate electrode GE3 to be formed, and then disposing the auxiliary pattern AP3 in the remaining region where they are not disposed on the front surface SUB1a of the substrate SUB1. At this time, the narrow gap GP2 is formed between the auxiliary pattern AP3 and the gate electrode GE3 and the drain electrode DE3 so as to prevent the auxiliary pattern AP3 from being electrically connected to the gate electrode GE3 and the drain electrode DE3.

In the present embodiment, the conductor pattern CP5 functions as the mask in backside exposure, and thus the source electrode SE3 and the drain electrode DE3 as well as the auxiliary pattern AP3 function to define the opening shape of the gate electrode region RP6b of the resist pattern RP6a, whereby the shape of the gate electrode GE2 can be defined. Therefore, the photomask does not need to be separately used in the backside exposure process. Accordingly, an accurate alignment between the photomask and the substrate SUB1 is not necessary, and thus an expensive exposure device having alignment mechanism is not required. Therefore, the manufacturing cost of the semiconductor device can be reduced.

Further, similar to the conductor pattern CP3 of the second embodiment, the relative position of the source electrode SE3 and the drain electrode DE3 and the auxiliary pattern AP3 scarcely shifts even if misalignment occurs between the conductor pattern CP5 and the substrate SUB1. Thus, the gate electrode GE3 is formed by using the resist pattern RP6a formed by using the source electrode SE3, the drain electrode DE3 and the auxiliary pattern AP3 having no shift (fluctuation) in the relative positions as masks in exposure. Therefore, in the present embodiment, not only the mutually facing ends of the source electrode SE3 and the drain electrode DE3 are aligned with the ends of the gate electrode GE3, but also the outline position (position of the ends other than those aligned with the source electrode SE3 and the drain electrode DE3) of the gate electrode GE3 with respect to the source electrode SE3 and the drain electrode DE3 does not shift by misalignment. Accordingly, the formed position and the shape (dimension) of the gate electrode GE3 with respect to the source electrode SE3 and the drain electrode DE3 can be accurately formed to the desired position and shape. Therefore, the performance of the semiconductor device can be enhanced. Furthermore, the planar dimension of the transistor can be reduced (miniaturized), and the semiconductor device can be miniaturized (area reduction).

### Fourth Embodiment

The case of forming an active matrix circuit as shown in FIG. 15 by using the thin film transistors TR2 of bottom gate structure of the second embodiment will be described in the present embodiment.

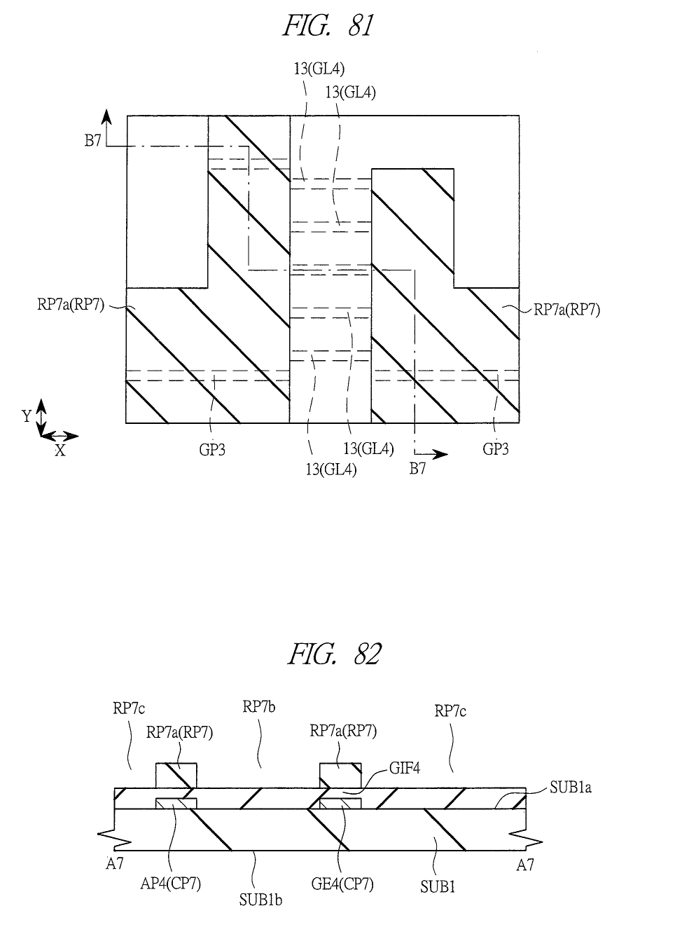

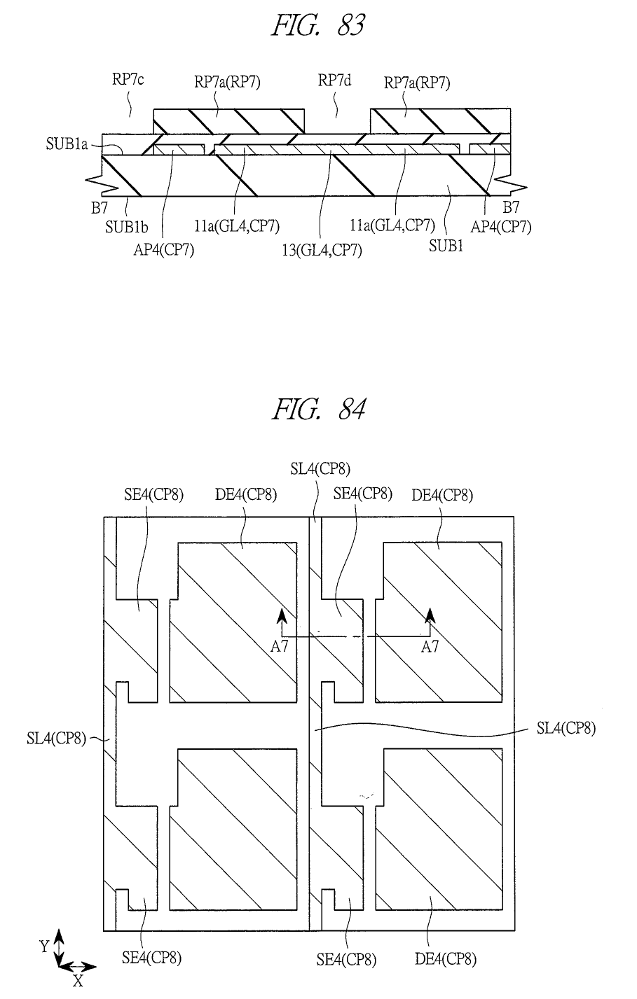

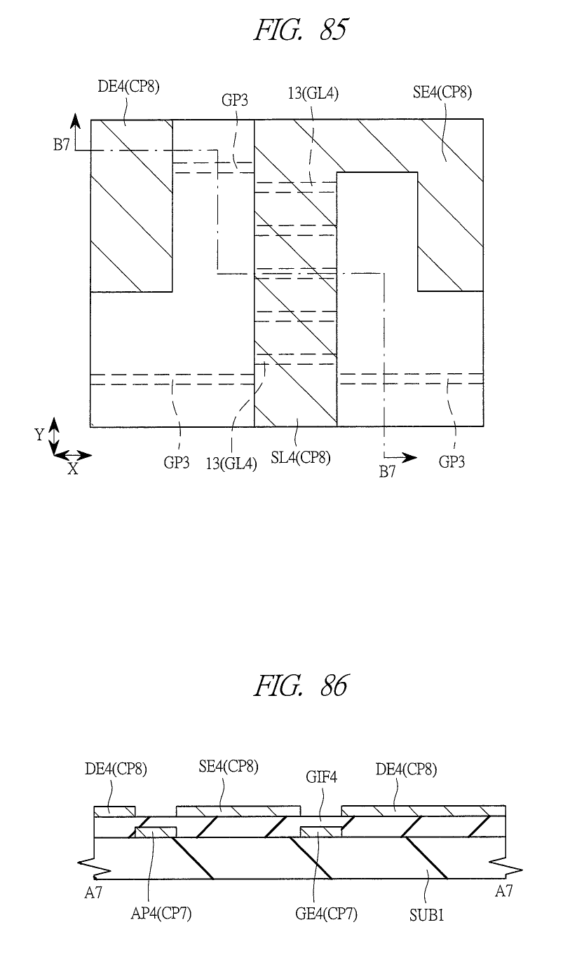

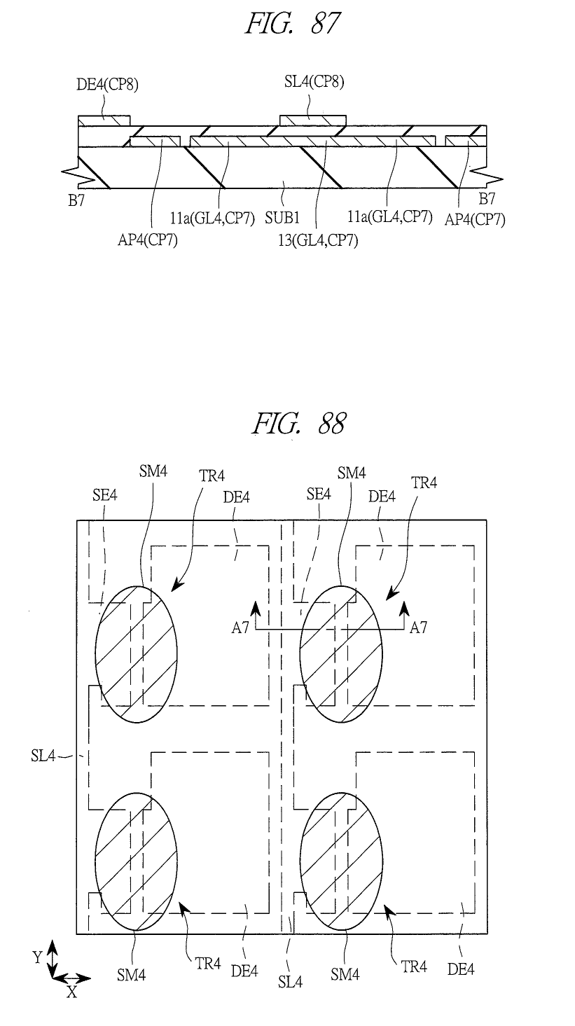

FIGS. 78 to 89 include plan views (plan view of principal part) and cross sectional views (cross sectional view of principal part) in the manufacturing process of the semiconductor device of the present embodiment, that is, the active matrix circuit using the thin film transistors TR4 of bottom gate structure having a structure substantially similar to the thin film transistor TR2 of the second embodiment as a single transistor. Of FIGS. 78 to 89, FIGS. 78, 80, 84 and 88 are plan views (plan view of principal part) in the manufacturing process of the active matrix circuit using the thin film transistor TR4 and show different processing steps of the same region. Note that FIGS. 78, 80, 84 and 88 show a region where a total of four transistors in 2 rows and 2 columns are formed in the active matrix circuit in which transistors are disposed in plural rows and plural columns on the substrate SUB1. Of FIGS. 78 to 89, FIGS. 79, 81 and 85 show partially enlarged plan views (plan view of principal part) of the region corresponding to a region 10 surrounded by a dotted line in FIG. 78 and show different processing steps of the same region. Also, FIGS. 78 and 79 correspond to the same processing step, and the drawing in which the region 10 of FIG. 78 is enlarged corresponds to FIG. 79. Also, FIGS. 80 to 83 correspond to the same processing step, the drawing in which a part (region corresponding to the region 10 of FIG. 79) of FIG. 80 is enlarged corresponds to FIG. 79, the cross sectional view of the line A7-A7 of FIG. 80 corresponds to FIG. 82, and the cross sectional view of the line B7-B7 of FIG. 81 corresponds to FIG. 83. Also, FIGS. 84 to 87 correspond to the same processing step, the drawing in which a part (region corresponding to the region 10 of FIG. 79) of FIG. 84 is enlarged corresponds to FIG. 85, the cross sectional view of the line A7-A7 of FIG. 84 corresponds to FIG. 86, and the cross sectional view of the line B7-B7 of FIG. 84 corresponds to FIG. 87. Also, FIGS. 88 and 89 correspond to the same processing step, and the cross sectional view of the line A7-A7 of FIG. 88 corresponds to FIG. 89.

FIGS. 78 to 81, 84, 85 and 88 are plan views, but in order to make the drawings easy to see, hatching is applied to those corresponding to the conductor pattern CP7 in FIGS. 78 and 79, to the resist pattern RP7a in FIGS. 80 and 81, to those corresponding to the conductor pattern CP8 in FIGS. 84 and 85, and to the semiconductor layer SM4 in FIG. 88.

First, as shown in FIGS. 78 and 79, the substrate SUB1 is prepared. Thereafter, a metal film similar to the metal film 2 of the second embodiment is formed on the front surface SUB1a of the substrate SUB1, the resist film (not shown) similar to the resist films RP3 and RP5 is formed on the metal film, and the resist pattern (not shown) is formed by exposing and developing the resist film with using a photomask. Then, the metal film is patterned by etching using the resist pattern as the etching mask to form the conductor pattern (metal pattern, first conductor pattern) CP7 as shown by the hatching in FIGS. 78 and 79. Note that the resist pattern for forming the conductor pattern CP7 has the same pattern as the conductor pattern CP7. Thereafter, the resist pattern is removed. In the following, the resist film used to form the conductor pattern CP7 by patterning the metal film is called as the resist film for processing the conductor pattern CP7.

The conductor pattern CP7 includes a gate electrode (gate electrode pattern, first pattern) GE4, a scanning line (scanning line pattern, first pattern) GL4 and an auxiliary pattern (correction pattern, second pattern) AP4, and the auxiliary pattern AP4 is spaced apart and electrically insulated from the gate electrode GE4 and the scanning line GL4 by a narrow gap GP3. The gap GP3 is a region where the conductor pattern CP7 is not formed. In other words, the conductor pattern CP7 is formed from the gate electrode GE4, the scanning line GL4 and the auxiliary pattern AP4, and the gate electrode GE4, the scanning line GL4 and the auxiliary pattern AP4 are formed of a conductor layer (conductor pattern) of the same layer. The dimension (interval, width) GS3 of the gap GP3 between the auxiliary pattern AP4 and the gate electrode GE4 and the scanning line GL4 is smaller (narrower) than the gate length L3 of the gate electrode GE4, that is, GS3<L3.

The gate electrode GE4 (first pattern) is the gate electrode pattern of the transistor TR4, and the scanning line GL4 (first pattern) is the wiring (scanning line) pattern for connecting the gate electrodes of the plurality of transistors TR4. Therefore, the gate electrode GE4 and the scanning line GL4 (first pattern) can be considered as patterns functioning as electrodes or wirings.

The auxiliary pattern AP4 (second pattern) is a pattern (pattern functioning as photomask in exposure) provided to define the outer shape of the source electrode SE4, the drain electrode DE4 and the signal line SL4 to be formed later, but is an electrically unnecessary conductor pattern. Thus, by providing the narrow gap GP3 between the auxiliary pattern AP4 and the gate electrode GE4 and the scanning line GL4, the auxiliary pattern AP4 can be prevented from being electrically connected to the gate electrode GE4 and the scanning line GL4. Thus, the auxiliary pattern AP4 is an isolated pattern not connected to the electrode and the wiring and is a pattern considered as a floating potential.

The scanning line GL4 corresponds to the scanning line GL of the circuit diagram of FIG. 15, and the gate electrode GE4 corresponds to the gate electrode of the transistor TR of the circuit diagram of FIG. 15. As is apparent from the circuit diagram of FIG. 15, the gate electrode GE4 and the scanning line GL4 need to be electrically connected, and thus the gate electrode GE4 and the scanning line GL4 are formed on the substrate SUB1 as a coupled integrated pattern. More specifically, on the front surface SUB1a of the substrate SUB1, a plurality of scanning lines GL4 extending in the X direction are disposed in parallel to each other, and the ends of the plurality of gate electrodes 3d extending in the Y direction are coupled to the scanning lines GL4. The X direction and the Y direction mentioned here are directions intersecting each other and are preferably orthogonal to each other. The same goes for the following fifth embodiment.

However, in the present embodiment, in order to form the pattern of the signal line SL4 even in the region where the scanning line GL4 and the signal line SL4 to be formed later intersect without using the masks MK1 and MK2 used in the first embodiment, the following techniques are used for the pattern shape (planar shape) of the scanning line GL4.

As shown in FIGS. 78 and 79, each scanning line GL4 is configured of a main pattern (main portion, third pattern, fourth pattern) 11 formed as a relatively wide width pattern extending in the X direction and a connection pattern (connection pattern, connecting part) 13 formed as a line pattern (linear pattern) with a narrow width for coupling (connecting) the main patterns 11 adjacent in the X direction. The main pattern 11 and the connection pattern 13 are integrally formed. Therefore, each scanning line GL4 of the conductor pattern CP7 includes the main pattern 11 (third pattern), another main pattern 11 (fourth pattern) adjacent thereto in the X direction and the connection pattern 13 for coupling (connecting) the adjacent main patterns 11, and these are repeatedly formed so as to extend in the X direction.

In each scanning line GL4, the connection pattern 13 is disposed in a region where the scanning line GL4 and the signal line SL4 formed later planarly intersect, and the main pattern 11 is disposed in a region other than the region planarly intersecting with the signal line SL4 formed later. Each scanning line GL4 has the plurality of main patterns 11 connected by the connection pattern 13 and entirely extends in the X direction, and one gate electrode GE4 is connected to one main pattern 11. In each scanning line GL4 extending in the X direction, the main patterns 11 adjacent in the X direction are electrically connected via the connection pattern 13, and each scanning line GL4 including the main pattern 11 and the connection pattern 13 becomes the conductor pattern extending in the X direction, whereby the plurality of gate electrodes GE4 can be electrically connected by the scanning line GL4.

The main pattern 11 of the scanning line GL4 extends in the X direction with substantially the same width (dimension in Y direction) W1, but the end (end in X direction) 11a of the main pattern 11 has a wider width (dimension in Y direction) than other portions of the main pattern 11. In other words, the width (dimension in Y direction) W2 of the end 11a of the main pattern 11 of the scanning line GL4 is larger than the width (dimension in Y direction) W1 of other portions (i.e., W2>W1).

In the scanning line GL4, the connection pattern 13 is the portion of coupling and electrically connecting (the ends 11a of) the main patterns 11 adjacent in the X direction, but it is not formed from the pattern with the same width as the main pattern 11 and is a linear pattern with a narrower width than the main pattern 11. More specifically, the width (dimension in Y direction) W3 of the connection pattern 13 is smaller than the width (dimension in Y direction) W1 of the main pattern 11 and the width (dimension in Y direction) W2 of the end 11a of the main pattern 11 (i.e., W3<W1, W2).

More specifically, as shown in FIG. 79, the connection pattern 13 extends in the X direction between the ends 11a of the two main patterns 11 adjacent in the X direction, a plurality of connection patterns 13 are disposed in line at a predetermined interval (preferably, equal interval) in the Y direction, and both ends of each connection pattern 13 are disposed in continuation to the ends 11a of the main patterns 11 and coupled (connected) thereto. Also, the interval (dimension in Y direction) W4 of the connection patterns 13 adjacent in the Y direction needs to be larger than the width (dimension in Y direction) W3 of the connection pattern 13 (i.e., W4>W3), and it is preferably sufficiently larger than the width W3 of the connection pattern 13 and is preferably equal to or larger than the gate length L3 of the gate electrode GL4 (i.e., W4≧L3). The dimension of the connection pattern 13 in the X direction corresponds to the interval (dimension in X direction) W5 between (the ends 11a of) the main patterns 11 adjacent in the X direction and is larger than the width W3 of the connection pattern 13 (i.e., W5>W3). Also, the width (dimension in X direction) of the signal line SL4 to be formed later is substantially equal to the interval W5. Further, the width W3 of the connection pattern 13 is smaller than the gate length L3 of the gate electrode GE4 (i.e., W3<L3). Also, the dimension GS3 of the gap GP3 and the width W3 of the connection pattern 13 are approximately the same dimensions (i.e., GS3=W3) and almost equal to the dimensions GS1 and GS2 of the gaps GP1 and GP2 of the second and third embodiments. As is apparent from FIG. 79, the width W3 of the connection pattern 13 corresponds to the dimension in the direction (Y direction in this case) intersecting (preferably orthogonal to) the extending direction (X direction in this case) of the connection pattern 13 extending to couple the adjacent main patterns 11 therebetween.

Therefore, the dimension GS3 of the gap GP3 and the width W3 of the connection pattern 13 are smaller than the gate length L3, the widths W1 and W2, and the intervals W4 and W5 (i.e., GS3, W3<L3, W1, W2, W4, W5). This is to achieve the state where the resist film RP7 described later cannot resolve the portion corresponding to the gap GP3 and the connection pattern 13 and can resolve the other regions. Also, in order to achieve the state where the resist film RP7 described later cannot resolve the portion corresponding to the gap GP3 and the connection pattern 13 and can accurately resolve the other regions, the dimension GS3 of the gap GP3 and the width W3 of the connection pattern 13 are preferably half the gate length GL3, the widths W1 and W2, and the intervals W4 and W5 or smaller and more preferably quarter the gate length GL3, the widths W1 and W2, and the intervals W4 and W5 or smaller.

As an example of specific numerical values, the dimension GS3 of the gap GP3 is 1 μm, the gate length GL3 of the gate electrode GE4 is 4 μm, the width W1 of the main pattern 11 of the scanning line GL4 is 10 μm, the width W2 of the end 11a of the main pattern 11 of the scanning line GL4 is 40 μm, the width W3 of the connection pattern 13 of the scanning line GL4 is 1 μm, and the interval W4 of the connection patterns 13 of the scanning line GL4 is 5 μm. Also, the novolac resin resist having a film thickness of, for instance, 10 μm can be used for the resist film RP7.

The reason why the scanning line GL4 is formed from the connection patterns 13 with a narrower width than the main pattern 11 in the region intersecting with the signal line SL4 to be formed later is to prevent the signal line SL4 to be formed later from being divided by the shadow of the scanning line GL4. Also, the reason why a plurality of connection patterns 13 (e.g., several connection patterns 13) with a narrow width are arranged in parallel and the main patterns 11 are coupled by the plurality of connection patterns 13 is to suppress the heat generation due to extreme increase in electrical resistance of the scanning line GL4 by the connection patterns 13. Further, the width W2 of the end 11a of the main pattern 11 is made larger than the width W1 of the main pattern 11 other than the end 11a (W2>W1) and the connection patterns 13 are coupled to the ends 11a with a wide width, whereby the number of connection patterns 13 for connecting the pair of main patterns 11 can be increased and thus the heat generation at the connection patterns 13 can be more accurately prevented. The total of the width W3 of the plurality of connection patterns 13 for connecting the pair of main patterns 11 (obtained by multiplying the number of connection patterns 13 by the width W3) is more preferably equal to or larger than 80% of the width W1 of the main pattern 11 in terms of the suppression of the heat generation at the connection pattern 13.

After forming the conductor pattern CP7, the translucent insulating film (gate insulating film) GIF4 is formed to have a film thickness of about 300 nm on the entire front surface SUB1a of the substrate SUB1 so as to cover the conductor pattern CP7 (gate electrode GE4, scanning line GL4 and auxiliary pattern AP4) as shown in FIGS. 80 to 83. The insulating film GIF4 is the insulating film for the gate insulating film. Of the insulating film GIF4, the portion positioned on the gate electrode GE4 functions as the gate insulating film. The same material as that of the insulating film GIF2 of the second embodiment can be used for the material of the insulating film GIF4. The interior of the gap GP3 is also filled with the insulating film GIF4.

Next, the positive resist film (photoresist film) RP7 is formed on the entire front surface SUB1a of the substrate SUB1, that is, on the insulating film GIF4.

Then, light is irradiated from the back surface SUB1b side of the substrate SUB1 to expose the resist film RP7, in other words, the so-called backside exposure is performed. In the backside exposure, only the conductor pattern CP7 formed on the substrate SUB1 functions as the mask, and the exposure photomask is not separately used unlike the exposure process of FIGS. 5, 18 and 34. Also, in the backside exposure, the exposure from the front surface SUB1a side of the substrate SUB1 is not performed.

The substrate SUB1 and the insulating film GIF4 have translucency, and the light irradiated from the back surface SUB1b side of the substrate SUB1 is irradiated onto the resist film RP7 through the substrate SUB1 and the insulating film GIF4 in the backside exposure process. At this time, since the conductor pattern CP7 is made of a metal film and has a light reflecting property instead of a light transmitting property, the conductor pattern CP7 functions as a mask (photomask, exposure mask, light shielding portion). Therefore, the light not shielded by the conductor pattern CP7 (gate electrode GE4, scanning line GL4 and auxiliary pattern AP4) is irradiated onto the resist film RP7 from the back surface SUB1b side of the substrate SUB1.

After the backside exposure process described above, the resist pattern (photoresist pattern) RP7a as shown in FIGS. 80 to 83 is formed on the insulating film 4b by developing the resist film RP7.

With reference to the comparison of FIGS. 78 and 79 and FIGS. 80 and 81, it can be understood that the resist pattern RP7a has a pattern shape as follows for the reasons described later. More specifically, the formed resist pattern RP7a has a pattern shape corresponding to (same as) the conductor pattern CP7 obtained when the auxiliary pattern AP4 (second pattern) is coupled to the gate electrode GE4 and the scanning line GL4 (first pattern) by removing the gap GP3 and the main patterns 11 (third pattern and fourth pattern) of the scanning line GL4 adjacent in the X direction are separated by removing the connection pattern 13 (first connection pattern). In other words, the resist pattern RP7a is formed to have the pattern shape substantially the same as that obtained when the conductor pattern is disposed also in the gap GP3 in the conductor pattern CP7 and the connection pattern 13 is removed. Therefore, the resist pattern RP7a is formed on the conductor pattern CP7 and the gap GP3 and is not formed in other regions, and further, it is not formed on the connection pattern 13 (first connection pattern).

More specifically, similar to the resist films RP3 and RP5 of the second and third embodiments, the resolution of the resist film for processing the conductor pattern CP7 is increased also in the present embodiment so that the resist film can resolve the dimension GS3 of the gap GP3 and the width W3 of the connection pattern 13 of the scanning line GL4. Therefore, similar to the resist films RP3 and RP5 of the second and third embodiments, the film thickness of the resist film for processing the conductor pattern CP7 is adjusted to be equal to or smaller than the thickness T1 of the graph of FIG. 56. In the case of the present embodiment, S1 of the vertical axis of the graph of FIG. 56 corresponds to the dimension GS3 of the gap GP3 and the width W3 of the connection pattern 13 of the scanning line GL4 (i.e., S1=GS3, W3), and S2 of the vertical axis of the graph corresponds to the smallest one of the gate length L3 of the gate electrode GE4, the widths W1 and W2, and the intervals W4 and W5.

By this means, the resolution limit dimension of the resist film for processing the conductor pattern CP7 becomes smaller than the dimension GS3 of the gap GP3 and the width W3 of the connection pattern 13, and thus the resist pattern formed by exposing and developing the resist film for processing the conductor pattern CP7 is formed to have the portion corresponding to the gap GP3 and the portion corresponding to the connection pattern 13. Therefore, the gap GP3 and the connection pattern 13 can be formed in the conductor pattern CP7.

On the other hand, similar to the resist films RP4 and RP6 of the second and third embodiments, the resolution of the resist film RP7 of the present embodiment is made lower than that of the resist film for processing the conductor pattern CP7, thereby achieving the state where the resist film RP7 can resolve the gate length L3, the widths W1 and W2, and the intervals W4 and W5, but cannot resolve the dimension GS3 of the gap GP3 and the width W3 of the connection pattern 13. In other words, the resolution limit dimension of the resist film RP7 in the backside exposure process is made larger than the dimension GS3 of the gap GP3 and the width W3 of the connection pattern 13 and made equal to or smaller than the gate length L3, the widths W1 and W2, and the intervals W4 and W5. Therefore, the film thickness of the resist film RP7 is adjusted to be larger than the thickness T1 of the graph of FIG. 56 and equal to or smaller than the thickness T2 of the graph of FIG. 56.

In this manner, the resist film RP7 cannot resolve the portion corresponding to the gap GP3, and the resist pattern RP7a after development has a pattern shape corresponding to (substantially the same as) the conductor pattern CP7 obtained when the portion corresponding to the gap GP3 is not formed and the auxiliary pattern AP4 is coupled to the gate electrode GE4 and the scanning line GL4 by removing the gap GP3.

Further, the resist film RP7 cannot resolve the portion corresponding to the connection pattern 13 of the scanning line GL4, and the resist pattern RP7a after development has a pattern shape corresponding to (substantially the same as) the conductor pattern CP7 obtained when the portion corresponding to the connection pattern 13 of the scanning line GL4 is not formed and the main patterns 11 of the scanning line GL4 adjacent in the X direction are separated by removing the connection pattern 13.

In this manner, in the present embodiment, even if the backside exposure is performed with using the conductor pattern CP7 including the narrow gap GP3 and the linear connection pattern 13 with a narrow width functioning as a mask, the resist pattern RP7a without the portion corresponding to the gap GP3 and the connection pattern 13 can be obtained. More specifically, the resist pattern PR7a has a pattern similar to that obtained when the back surface exposure of the resist film RP7 is performed with using the conductor pattern CP7, in which the auxiliary pattern AP4, the gate electrode GE4 and the scanning line GL4 are coupled by removing the gap GP3 and the main patterns 11 of the scanning line GL4 are separated by removing the connection pattern 13, as the mask.

Therefore, the resist pattern RP7a has a pattern in which the gap corresponding to the gap GP3 and a narrow linear portion corresponding to the connection pattern 13 are not formed and a source electrode region RP7b corresponding to a region in which the source electrode SE4 is to be formed later, a drain electrode region RP7c corresponding to a region in which the drain electrode DE4 is to be formed later, and a signal line region RP7d corresponding to a region in which the signal line SL4 is to be formed later are opened. More specifically, the resist pattern RP7a has a pattern in which the resist film does not exist in the source electrode region RP7b, the drain electrode region RP7c and the signal line region PR7d, and the resist film exists in other regions, and the resist pattern RP7a exists on the gap GP3 and the resist pattern RP7a does not exist on the connection pattern 13.

Since the gate electrode GE4 functions as a mask in backside exposure and the openings of the source electrode region RP7c and the drain electrode region RP7c are formed, the position of the gate electrode GE4 is automatically and accurately aligned with the positions of the source electrode region RP7b and the drain electrode region RP7c, and overlapping like the overlapping region 102 is scarcely formed. Therefore, the source electrode SE4 and the drain electrode DE4 formed later in the source electrode region RP7c and the drain electrode region RP7c are accurately aligned with the gate electrode GE4.

Also, since the auxiliary pattern AP4 functions as a mask in backside exposure together with the gate electrode GE4 and the scanning line GL4, even if separately prepared photomasks such as the masks MK1 and MK2 are not used, the opening shape of the source electrode region RP7b, the drain electrode region RP7c and the signal line region RP7d can be formed to have a desired arbitrary shape by adjusting the pattern shape of the auxiliary pattern AP4 to the desired arbitrary shape. By this means, the planar shape of the source electrode SE4, the drain electrode DE4 and the signal line SL4 formed later in the source electrode region PR7b, the drain electrode region RP7c and the signal line region RP7d can be adjusted to a desired arbitrary shape. Also, since the auxiliary pattern AP4 is insulated from the gate electrode GE4 and the scanning line GL4 by the gap GP3, the pattern shape of the auxiliary pattern AP4 can be adjusted without adversely affecting the gate electrode GE4 and the scanning line GL4.

After forming the resist pattern RP7a in this manner, a metal film is formed on the entire front surface SUB1a of the substrate SUB1, that is, on the resist pattern RP7a and the insulating film GIF4 (i.e., insulating film GIF4 exposed at the bottom of the opening region of the resist pattern RP7a) in the region not covered with the resist pattern RP7a, and the resist pattern RP7a is then dissolved and removed with organic solvent and the like. At this time, the metal film on the resist pattern RP7a is removed together with the resist pattern RP7a, but the metal film formed on the insulating film GIF4 exposed at the bottom of the opening region (source electrode region RP7b, drain electrode region RP7c and signal line region RP7d) of the resist pattern RP7a remains without being removed. The remaining metal film becomes the conductor pattern (metal pattern, second conductor pattern) CP8 including the source electrode SE4, the drain electrode DE4 and the signal line SL4 as shown in FIGS. 84 to 87. As the metal film for forming the conductor pattern CP8, the same metal film as that for forming the conductor pattern CP4 of the second embodiment can be used.

By performing the so-called lift-off process as described above, the conductor pattern CP8 (source electrode SE4, drain electrode DE4 and signal line SL4) can be formed on the insulating film GIF4 in the region (source electrode region RP7b, drain electrode region RP7c and signal line region 7d) not covered with the resist pattern RP7a.

As described above, the resist pattern RP7a is formed on (immediately above) the conductor pattern CP7 and on (immediately above) the gap GP3, but is not formed on (immediately above) the connection pattern 13, and the conductor pattern CP8 is formed in the region not covered with the resist pattern RP7a. Thus, the conductor pattern CP8 is formed in alignment with the conductor pattern CP7 on the region where the conductor pattern CP7 is not formed when viewed in a plane, but the conductor pattern CP8 is not formed on (immediately above) the gap GP3. Further, the conductor pattern CP8 is not formed on (immediately above) the conductor pattern CP7 except the connection pattern 13, but is formed on (immediately above) the connection pattern 13. In the present embodiment, the region where the conductor pattern CP7 is not formed when viewed in a plane is the region in which the conductor pattern CP8 is formed in the entire region other than the gap GP3, and the region where the conductor pattern CP7 is formed and the conductor pattern CP8 is formed when viewed in a plane is only the region on (immediately above) the connection pattern 13.

In the present embodiment, the conductor pattern CP8 is formed from the source electrode SE4 formed in the source electrode region RP7b, the drain electrode DE4 formed in the drain electrode region RP7c, and the signal line SL4 formed in the signal line region RP7d, and the source electrode SE4, the drain electrode DE4 and the signal line SL4 are formed of the conductor layer (conductor pattern) of the same layer. The signal line SL4 corresponds to the signal line SL of the circuit diagram of FIG. 15, the source electrode SE4 corresponds to the source electrode of the transistor TR of the circuit diagram of FIG. 15, and the drain electrode DE4 corresponds to the drain electrode of the transistor TR of the circuit diagram of FIG. 15.

As opposed to the present embodiment, if the same pattern as the main pattern 11 is extended in place of the connection pattern 13 with a narrow width in the scanning line GL4 (i.e., when the width W3 of the connection pattern 13 is made almost equal to the width W1 of the main pattern 11), the opening of the signal line region RP7d is cut at the position planarly intersecting with the scanning line GL4 because the light is shielded by the scanning line GL4 in the backside exposure process of the resist film RP7. In this case, the formed signal line SL4 is disconnected at the intersecting portion with the scanning line GL4. The scanning line GL4 extending in the X direction and the signal line SL4 extending in the Y direction need to be formed so as not to be disconnected even at the intersecting portion thereof.

On the other hand, the connection pattern 13 having a narrow linear pattern is provided for the scanning line GL4 in the region where the scanning line GL4 and the signal line SL4 intersect in the present embodiment. Because of the presence of the connection pattern 13, the scanning line GL4 can extend in the X direction without being disconnected even at the region intersecting the signal line SL4. Further, the width W3 of the connection pattern 13 of the scanning line GL4 is made smaller than the resolution limit dimension of the resist film RP7 in the backside exposure process, whereby it is possible to prevent the pattern corresponding to the connection pattern 13 of the scanning line GL4 from being formed in the resist pattern RP7a and prevent the resist pattern RP7a from existing above (immediately above) the connection pattern 13. Thus, the opening of the signal line region RP7d of the resist pattern RP7a is continuously formed in the Y direction without being separated even at the region intersecting the scanning line GL4. Therefore, the signal line SL4 is formed also above the connection pattern 13 of the scanning line GL4 and is not disconnected even at the region intersecting the scanning line GL4. Thus, although the scanning line GL4 extends in the X direction and the signal line SL4 extends in the Y direction intersecting (preferably orthogonal to) the X direction, not only the scanning line GL4 but also the signal line SL4 is not disconnected at the region where the scanning line GL4 and the signal line SL4 intersect. In this manner, even if photomasks such as the masks MK1 and MK2 used in the first embodiment are not used, the scanning line GL4 and the signal line SL4 can be formed so as not to be disconnected even at the region where they intersect.

The source electrode SE4, the drain electrode DE4 and the signal line SL4 are formed on the insulating film GIF4 in this manner, and a pair of the source electrode SE4 and the drain electrode DE4 is disposed in alignment with the position of the gate electrode GE4. Further, a plurality of signal lines SL4 are disposed in parallel so as to extend in the Y direction without being disconnected even at the intersecting portion with the scanning line GL4, and the ends of the plurality of source electrodes SE4 are coupled to the signal lines SL4. Thus, the source electrodes SE4 can be electrically connected via the signal line SL4.

After forming the conductor pattern CP8, as shown in FIGS. 88 and 89, the semiconductor layer (semiconductor pattern) SM4 is formed on the insulating film GIF4 between the source electrode SE4 and the drain electrode DE4 (i.e., on the insulating film GIF4 on the upper side of the gate electrode GE4) by a method similar to that of the semiconductor layer SM2. As the material for forming the semiconductor layer SM4, the same material as that of the semiconductor layer SM2 of the second embodiment can be used.

In this manner, the thin film transistor TR4 in which an overlapping region (corresponding to overlapping region 102) of the gate electrode GE4 and the source electrode SE4 and the drain electrode DE4 scarcely exists and the position of the gate electrode GE4 is accurately aligned with the positions of the source electrode SE4 and the drain electrode DE4 can be formed on the substrate SUB1. The thin film transistor TR4 corresponds to the transistor TR of the circuit diagram of FIG. 15. The source electrode SE4 is the source electrode pattern of the transistor TR4, the drain electrode DE4 is the drain electrode pattern of the transistor TR4, and the signal line SL4 is the wiring (signal line) pattern for connecting the source electrodes of a plurality of transistors TR4. Therefore, the source electrode SE4, the drain electrode DE4 and the signal line SL4 can be considered as patterns functioning as electrodes or wirings.

Thereafter, a protective film such as the protective film PT1 of the first embodiment is formed on the insulating film GIF4 so as to cover the conductor pattern CP8 (source electrode SE4, drain electrode DE4 and signal line SL4) and the semiconductor layer SM4, and a pixel electrode such as the pixel electrode PE1 electrically connected to the drain electrode DE4 is formed on the protective film, but the illustration and the description thereof will be omitted here.

In the present embodiment, the case of fabricating the active matrix circuit by using the auxiliary pattern AP4 of the simplest shape has been described, but the auxiliary pattern AP4 can be formed to have an arbitrary shape according to need.

For instance, the conductor pattern CP7 can be designed by determining the position and the shape of the gate electrode GE4 and the scanning line GL4 to be formed, determining the position and the shape of the source electrode SE4, the drain electrode DE4 and the signal line SL4 to be formed, and then disposing the auxiliary pattern AP4 in the region (remaining region) where they are not disposed on the front surface SUB1a of the substrate SUB1. At this time, in order to prevent the auxiliary pattern AP4 from being electrically connected to the gate electrode GE4 and the scanning line GL4, the narrow gap GP3 is formed between the auxiliary pattern AP4 and the gate electrode GE4 and the scanning line GL4. Also, the scanning line GL4 is formed from the connection pattern 13 with a narrow width at the intersecting region of the scanning line GL4 and the signal line SL4.

In the present embodiment, since the conductor pattern CP7 functions as the mask in backside exposure, the auxiliary pattern AP4 as well as the gate electrode GE4 and the scanning line GL4 functions to define the opening shapes of the source electrode region RP7b, the drain electrode region RP7c and the signal line region RP7d of the resist pattern RP7a, whereby the shapes of the source electrode SE4, the drain electrode DE4 and the signal line SL4 can be defined. Therefore, it is unnecessary to use a photomask such as the masks MK1 and MK2 in the backside exposure process. Accordingly, an accurate alignment between the photomask and the substrate SUB1 is not necessary, and thus an expensive exposure device having alignment mechanism is not required. Therefore, the manufacturing cost of the semiconductor device can be reduced.

Further, similar to the conductor patterns CP3 and CP5 of the second and third embodiments, the relative position of the gate electrode GE4, the scanning line GL4 and the auxiliary pattern AP4 scarcely shifts even if misalignment occurs between the conductor pattern CP7 and the substrate SUB1. Thus, the source electrode SE4, the drain electrode DE4 and the signal line SL4 are formed by using the resist pattern RP7a formed by using the gate electrode GE4, the scanning line GL4 and the auxiliary pattern AP4 having no shift (fluctuation) in the relative positions as masks in exposure. Therefore, in the present embodiment, not only the mutually facing ends of the source electrode SE4 and the drain electrode DE4 are aligned with the ends of the gate electrode GE4, but also the outline position (position of the ends other than those to be aligned with the gate electrode GE4) of the source electrode SE4, the drain electrode DE4 and the signal line SL4 with respect to the gate electrode GE4 and the scanning line GL4 does not shift by misalignment. Accordingly, the formed position and the shape (dimension) of the source electrode SE4, the drain electrode DE4 and the signal line SL4 with respect to the gate electrode GE4 and the scanning line GL4 can be accurately formed to the desired position and shape. Therefore, the performance of the semiconductor device can be enhanced. Furthermore, the planar dimension of the transistor can be reduced (miniaturized), and the semiconductor device can be miniaturized (area reduction).

### Fifth Embodiment

The case of forming the active matrix circuit by using the thin film transistor of bottom gate structure has been described in the fourth embodiment, and the case of forming the active matrix circuit of FIG. 15 by using the thin film transistor TR3 of top gate structure of the third embodiment will be described in the present embodiment.

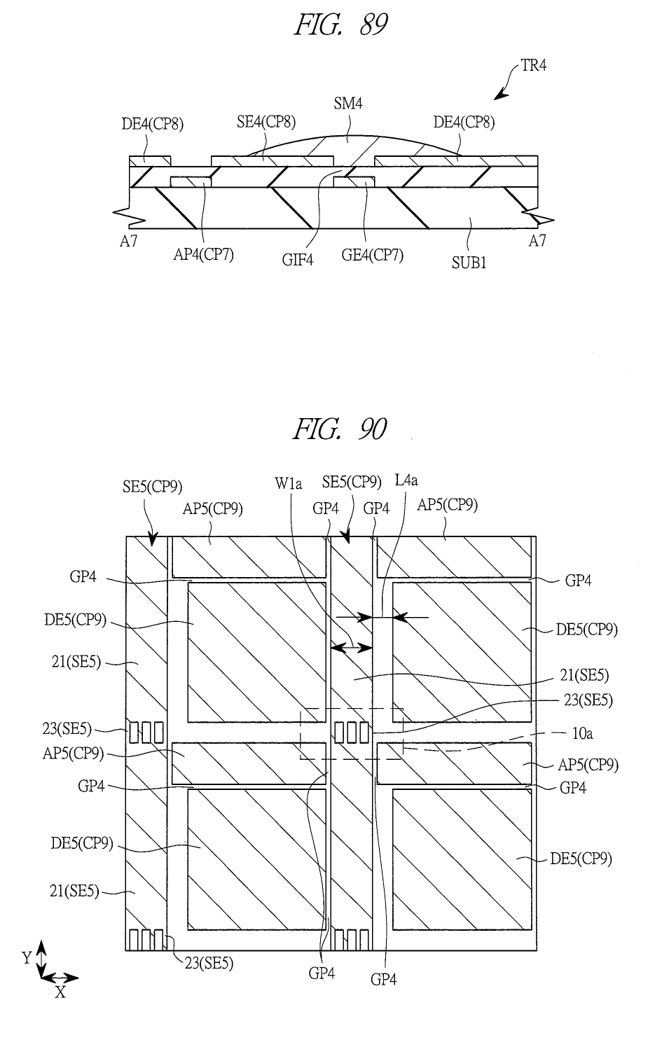

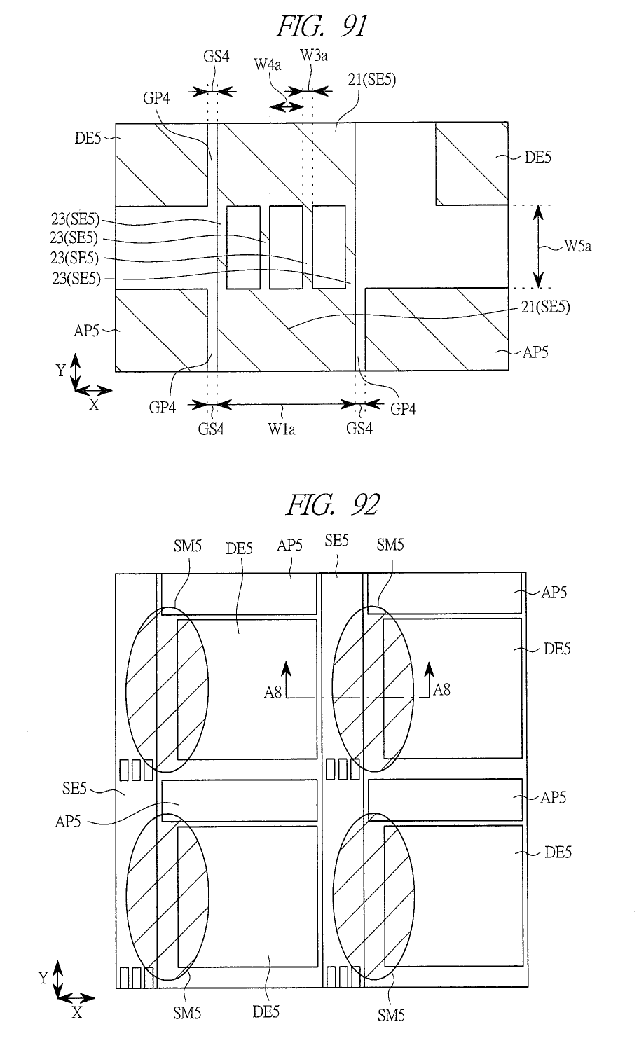

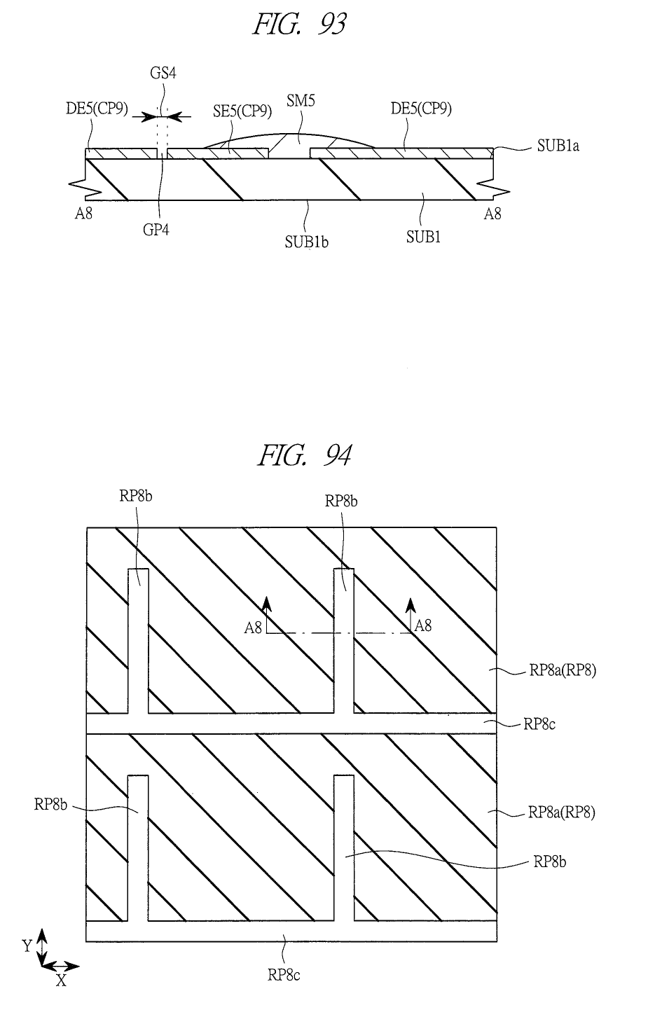

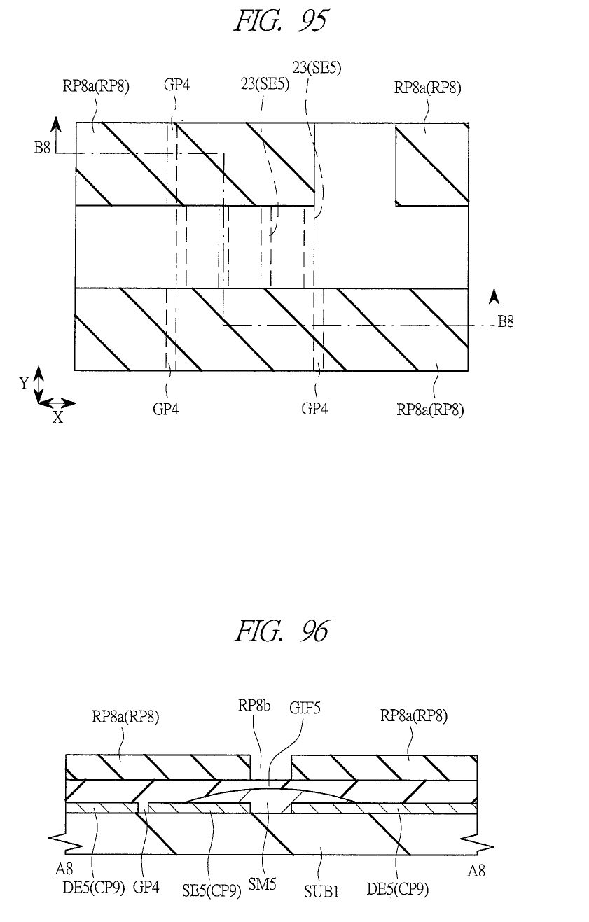

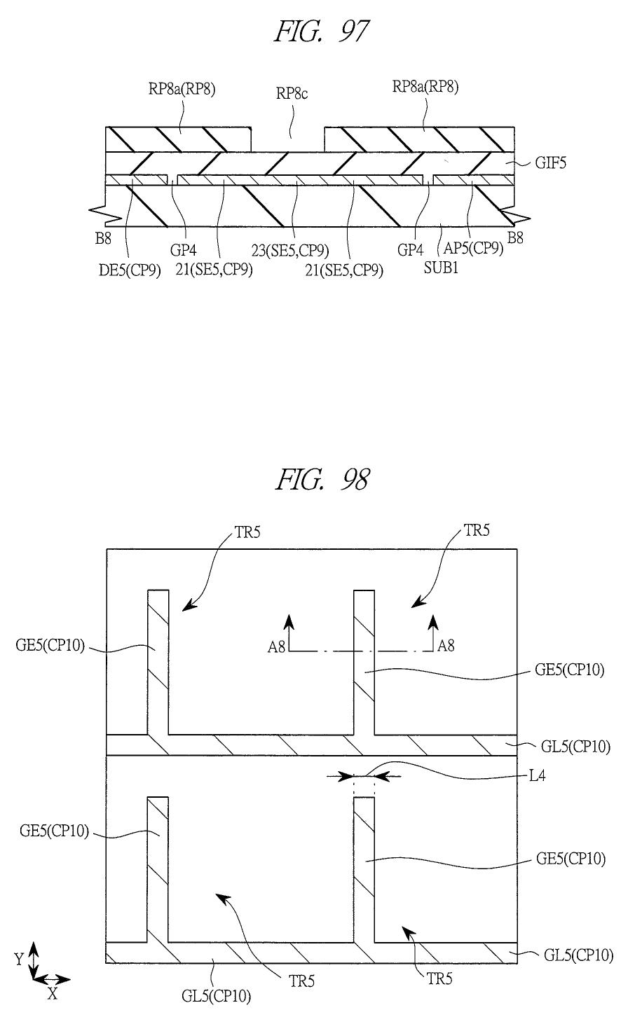

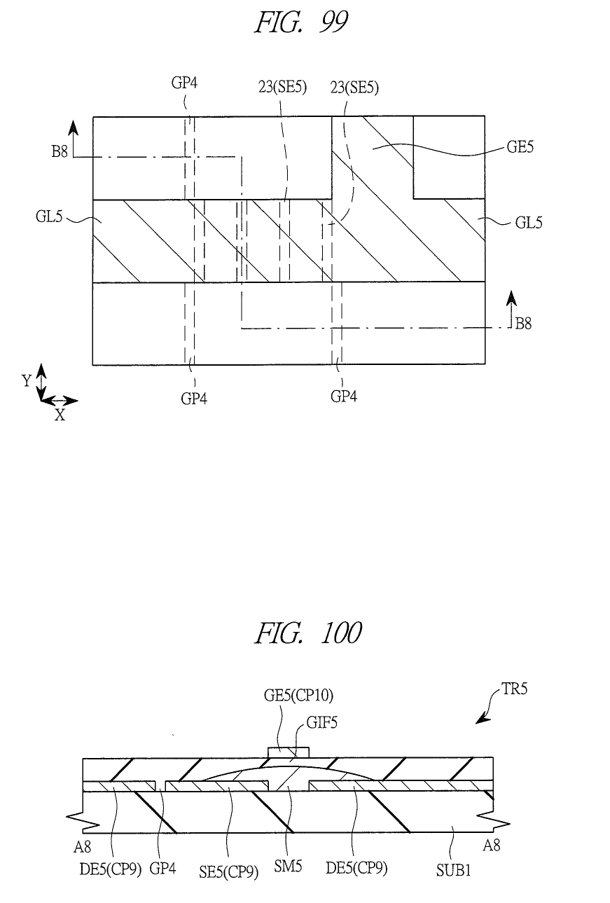

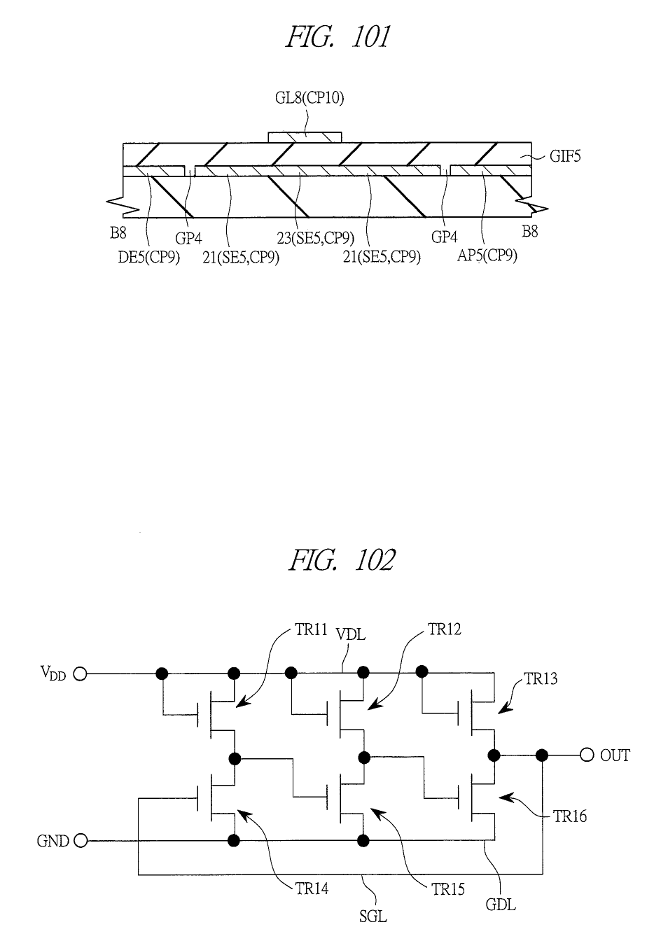

FIGS. 90 to 101 include plan views (plan view of principal part) and cross sectional views (cross sectional view of principal part) in the manufacturing process of the semiconductor device of the present embodiment, that is, the active matrix circuit using the thin film transistors TR5 of bottom gate structure having a structure substantially similar to the thin film transistor TR3 of the third embodiment as a single transistor. Of FIGS. 90 to 101, FIGS. 90, 92, 94 and 98 are plan views (plan view of principal part) in the manufacturing process of the active matrix circuit using the thin film transistor TR5 and show different processing steps of the same region. Note that FIGS. 90, 92, 94 and 98 show a region where a total of four transistors in 2 rows and 2 columns are formed in the active matrix circuit in which transistors are disposed in plural rows and plural columns on the substrate SUB1. Also, of FIGS. 90 to 101, FIGS. 91, 95 and 99 show partially enlarged plan views (plan view of principal part) of the region corresponding to a region 10a surrounded by a dotted line in FIG. 90 and show different processing steps of the same region. Also, FIGS. 90 and 91 correspond to the same processing step, and the drawing in which the region 10a of FIG. 90 is enlarged corresponds to FIG. 91. Also, FIGS. 92 and 93 correspond to the same processing step, and the cross sectional view of the line A8-A8 of FIG. 92 corresponds to FIG. 93. Also, FIGS. 94 to 97 correspond to the same processing step, the drawing in which a part (region corresponding to the region 10a of FIG. 90) of FIG. 94 is enlarged corresponds to FIG. 95, the cross sectional view of the line A8-A8 of FIG. 94 corresponds to FIG. 96, and the cross sectional view of the line B8-B8 of FIG. 95 corresponds to FIG. 97. Also, FIGS. 98 to 101 correspond to the same processing step, the drawing in which a part (region corresponding to the region 10a of FIG. 90) of FIG. 98 is enlarged corresponds to FIG. 99, the cross sectional view of the line A8-A8 of FIG. 98 corresponds to FIG. 100, and the cross sectional view of the line B8-B8 of FIG. 99 corresponds to FIG. 101.

Note that FIGS. 90 to 92, 94, 95, 98 and 99 are plan views, but in order to make the drawings easy to see, hatching is applied to those corresponding to the conductor pattern CP9 in FIGS. 90 and 91, to the semiconductor layer SM5 in FIG. 92, to the resist pattern RP8a in FIGS. 94 and 95, and to those corresponding to the conductor pattern CP10 in FIGS. 98 and 99.

First, as shown in FIGS. 90 and 91, the substrate SUB1 is prepared. Thereafter, a metal film similar to the metal film 3 of the third embodiment is formed on the front surface SUB1a of the substrate SUB1, the resist film (not shown) similar to the resist films RP3 and RP5 is formed on the metal film, and the resist pattern (not shown) is formed by exposing and developing the resist film by using a photomask. Then, the metal film is patterned by etching using the resist pattern as the etching mask to form the conductor pattern (metal pattern, first conductor pattern) CP9 as shown by the hatching in FIGS. 90 and 91. Note that the resist pattern for forming the conductor pattern CP9 has the same pattern as the conductor pattern CP9. Thereafter, the resist pattern is removed. In the following, the resist film used to form the conductor pattern CP9 by patterning the metal film is called as the resist film for processing the conductor pattern CP9.

The conductor pattern CP9 includes a source electrode (source electrode pattern, first pattern) SE5, a drain electrode (drain electrode pattern, first pattern) DE5 and an auxiliary pattern (correction pattern, second pattern) AP5, and the auxiliary pattern AP5 is spaced apart and electrically insulated from the source electrode SE5 and the drain electrode DE5 by a narrow gap GP4. The gap GP4 is a region where the conductor pattern CP9 is not formed. In other words, the conductor pattern CP9 is formed from the source electrode SE5, the drain electrode DE5 and the auxiliary pattern AP5, and the source electrode SE5, the drain electrode DE5 and the auxiliary pattern AP5 are formed of a conductor layer (conductor pattern) of the same layer.

The drain electrode DE5 (first pattern) is the drain electrode pattern of the transistor TR5, and the source electrode SE5 (first pattern) is the pattern functioning as both the source electrode of the transistor TR5 and the wiring (signal line) for connecting a plurality of source electrodes. Therefore, the source electrode SE5 and the drain electrode DE5 (first pattern) can be considered as patterns functioning as electrodes or wirings.

The auxiliary pattern AP5 (second pattern) is a pattern (pattern functioning as photomask in exposure) disposed to define the outer shape of the gate electrode GE5 and the scanning line GL5 to be formed later, but is an electrically unnecessary conductor pattern. Thus, by forming the narrow gap GP4 between the auxiliary pattern AP5 and the source electrode SE5 and the drain electrode DE5, it is possible to prevent the auxiliary pattern AP5 from being electrically connected to the source electrode SE5 and the drain electrode DE5. Therefore, the auxiliary pattern AP5 is an isolated pattern not connected to the electrode and the wiring, and is a pattern considered as a floating potential.

The drain electrode DE5 and the source electrode SE5 respectively correspond to the drain electrodes of the transistor TR of the circuit diagram of FIG. 15. As is apparent from the circuit diagram of FIG. 15, the source electrode of the transistor TR needs to be electrically connected to the signal line SL. Therefore, the source electrode SE5 extends in the Y direction to function also as the signal line SL, the portion facing the drain electrode DE5 functions as the source electrode of each thin film transistor, and the source electrodes (portion of the source electrode SE5 facing the drain electrode DE5) of the plurality of thin film transistors are connected by the source electrode SE5 extending in the Y direction. Therefore, the entire source electrode SE5 extending in the Y direction can be considered as the source electrode wiring (source wiring) or the signal line SL, and the portion facing each drain electrode DE5 therein can be considered as the source electrode. A plurality of source electrodes SE5 extending in the Y direction are disposed in parallel to each other on the substrate SUB1. Also, the source electrode SE5 and the drain electrode DE5 configuring the same transistor are spaced apart with an interval L4a wider than the dimension GS4 of the gap GP4 (i.e., L4a>GS4) in the region where the gate electrode is to be formed. The interval L4a between the source electrode SE5 and the drain electrode DE5 is the same as the gate length L4 of the gate electrode GE5 to be formed later (i.e., L4a=L4).

Similar to the fourth embodiment, in order to form the pattern of the scanning line GL5 even in the region where the source electrode SE5 and the scanning line GL5 to be formed later intersect, the following techniques are used for the pattern shape (planar shape) of the source electrode SE5.

More specifically, as shown in FIGS. 90 and 91, each source electrode SE5 is configured of a main pattern (main portion, third pattern, fourth pattern) 21 formed as a relatively wide width pattern extending in the Y direction and a connection pattern (connection pattern, connecting part) 23 formed as a line pattern (linear pattern) with a narrow width for coupling (connecting) the main patterns 21 adjacent in the Y direction. The main pattern 21 and the connection pattern 23 are integrally formed. Therefore, each source electrode SE5 of the conductor pattern CP9 includes the main pattern 21 (third pattern), another main pattern 21 (fourth pattern) adjacent thereto in the Y direction and the connection pattern 23 for coupling (connecting) the adjacent main patterns 21, and these are repeatedly formed so as to extend in the Y direction. In each source electrode SE5, the connection pattern 23 is disposed in a region where the source electrode SE5 and the scanning line GL5 formed later planarly intersect, and the main pattern 21 is disposed in a region other than the region of planarly intersecting with the scanning line GL5 to be formed later. The portion to be the source electrode of one transistor TR is formed of one main pattern 21, and the main patterns 21 adjacent in the Y direction are electrically connected via the connection pattern 23, whereby the source electrodes of the plurality of transistors TR can be electrically connected.

The main pattern 21 of the source electrode SE5 extends in the Y direction with substantially the same width (dimension in X direction) W1a. On the other hand, in the source electrode SE5, the connection pattern 23 is the portion for coupling and electrically connecting (the ends of) the main patterns 21 adjacent in the Y direction, and it is not formed to be the pattern with the same width as the main pattern 21 but is a linear pattern with a narrower width than the main pattern 21. More specifically, the width (dimension in X direction) W3a of the connection pattern 23 is smaller than the width (dimension in X direction) W1a of the main pattern 21 (i.e., W3a<W1a).

More specifically, as shown in FIG. 91, the connection pattern 23 extends in the Y direction between (the ends of) the two main patterns 21 adjacent in the Y direction, and a plurality of the connection patterns 23 are disposed in line at a predetermined interval (preferably, equal interval) in the X direction, and both ends of each connection pattern 23 are disposed in continuation to the ends of the main patterns 21 and coupled (connected) thereto. Also, the interval (dimension in X direction) W4a of the connection patterns 23 adjacent in the X direction is larger than the width (dimension in X direction) W3a of the connection pattern 23 (i.e., W4a>W3a). The dimension of the connection pattern 23 in the Y direction corresponds to the interval (dimension in Y direction) W5a of the main patterns 21 adjacent in the Y direction, but is larger than the width W3a of the connection pattern 23 (i.e., W5a>W3a) Further, the width (dimension in Y direction) of the scanning line GL5 to be formed later is substantially equal to the interval W5a. Also, the width W3a of the connection pattern 23 is smaller than the interval L4a between the source electrode SE5 and the drain electrode DE5, that is, the gate length L4 of the gate electrode GE5 formed later (i.e., W3a<L4a=L4). Also, the dimension GS4 of the gap GP4 and the width W3a of the connection pattern 23 are almost the same dimension (i.e., GS3=W3a) and are almost the same as the dimensions GS1, GS2 and GS3 of the gaps GP1, GP2 and GP3 of the second, third and fourth embodiments. As is apparent from FIG. 91, the width W3a of the connection pattern 23 corresponds to the dimension thereof in the direction (X direction) intersecting (preferably orthogonal to) the extending direction (Y direction) of the connection pattern 23 extending to couple the adjacent main patterns 21.

Therefore, the dimension GS4 of the gap GP4 and the width W3a of the connection pattern 23 are smaller than the interval L4a, the gate length L4, the width W1a and the intervals W4a and W5a (i.e., GS4, W3a<L4a, L4, W1a, W4a, W5a), but this is to achieve the state where the resist film RP8 described later cannot resolve the portion corresponding to the gap GP4 and the connection pattern 23 and can resolve the other regions. Also, in order to achieve the state where the resist film RP8 described later cannot resolve the portion corresponding to the gap GP4 and the connection pattern 23 and can accurately resolve the other regions, the dimension GS4 of the gap GP4 and the width W3a of the connection pattern 23 are preferably half the interval L4a, the gate length L4, the width W1a and the intervals W4a and W5a or smaller and more preferably quarter the interval L4a, the gate length L4, the width W1a and the intervals W4a and W5a or smaller.

As an example of specific numerical values, the dimension GS4 of the gap GP4 is 1 μm, the interval L4a between the source electrode SE5 and the drain electrode DE5 is 4 μm, the width W1a of the main pattern 21 of the source electrode SE5 is 19 μm, the width W3a of the connection pattern 23 of the source electrode SE5 is 1 μm, and the interval W4a of the connection patterns 23 is 5 μm. Also, the novolac resin resist having a film thickness of, for example, 10 μm can be used as the resist film RP8 described later.

In the present embodiment, the portion corresponding to the end 11a with a wider width than the main pattern 11 of the fourth embodiment is not disposed, but this is to prevent the width (dimension in X direction) of the gate electrode GE5 to be formed later from being partially narrow to cause the increase in connection resistance between the gate electrode GE5 and the scanning line GL5. On the other hand, since the dimension of the source electrode in the Y direction is larger than the dimension of the gate electrode in the X direction, the function of the source electrode SE4 is not influenced even if the end 11a with a large dimension in the Y direction is disposed in the main pattern 11 of the scanning line GL4 in the fourth embodiment.

After forming the conductor pattern CP9, the translucent semiconductor layer (semiconductor pattern) SM5 is formed on the semiconductor substrate SUB1 between the drain electrode DE5 and the source electrode SE5 facing thereto (i.e., on the substrate SUB1 on the lower side of the gate electrode GE5 formed later) by a method similar to that of the semiconductor layer SM2 as shown in FIGS. 92 and 93. As the material for forming the semiconductor layer SM5, the same material as that of the semiconductor layer SM2 of the second embodiment can be used.

Next, as shown in FIGS. 94 to 97, the translucent insulating film (gate insulating film) GIF5 is formed to have a film thickness of about 300 nm on the entire front surface SUB1a of the substrate SUB1 so as to cover the conductor pattern CP9 (source electrode SE5, drain electrode DE5 and auxiliary pattern AP5) and the semiconductor layer SM5. The insulating film GIF5 is the insulating film for the gate insulating film. Of the insulating film GIF5, the portion positioned under the gate electrode GE5 to be formed later functions as the gate insulating film. As the material for forming the insulating film GIF5, the same material as that of the gate insulating film GIF2 of the second embodiment can be used. The interior of the gap GP4 is also filled with the insulating film GIF5.

Next, the positive resist film (photoresist film) RP8 is formed on the entire front surface SUB1a of the substrate SUB1, that is, on the insulating film GIF5.

Next, the light is irradiated from the back surface SUB1b side of the substrate SUB1 to expose the resist film RP8, that is, the so-called backside exposure is performed. In the backside exposure, only the conductor pattern CP9 formed on the substrate SUB1 functions as the mask, and the exposure photomask is not separately used unlike the exposure process of FIGS. 5, 18 and 34. Also, in the backside exposure, the exposure from the front surface SUB1a side of the substrate SUB1 is not performed.

The substrate SUB1, the semiconductor layer SM5 and the insulating film GIF5 have translucency, and the light irradiated from the back surface SUB1b side of the substrate SUB1 is irradiated onto the resist film RP8 through the substrate SUB1, the semiconductor layer SM5 and the insulating film GIF5 in the backside exposure process. At this time, the conductor pattern CP9 functions as a mask (photomask, exposure mask, light shielding portion) similar to the conductor films CP3, CP5 and CP7. Therefore, the light not shielded by the conductor pattern CP9 (source electrode SE5, drain electrode DE5 and auxiliary pattern AP5) is irradiated onto the resist film RP8 from the back surface SUB1b side of the substrate SUB1.

After the backside exposure process as described above, the resist pattern (photoresist pattern) RP8a as shown in FIGS. 94 to 97 is formed on the insulating film GIF5 by developing the resist film RP8.

With reference to the comparison of FIGS. 90 and 91 and FIGS. 94 and 95, it can be understood that the resist pattern RP8a has a pattern shape as follows for the reasons described later. More specifically, the formed resist pattern RP8a has a pattern shape corresponding to (same as) the conductor pattern CP9 obtained when the auxiliary pattern AP5 (second pattern) is coupled to the source electrode SE5 and the drain electrode DE5 (first pattern) by removing the gap GP4, and the main patterns 21 (third pattern and fourth pattern) of the source electrode SE5 adjacent in the Y direction are separated by removing the connection pattern 23 (first connection pattern). In other words, the resist pattern RP8a is formed to have the pattern shape substantially the same as that obtained when the conductor pattern is disposed also in the gap GP4 in the conductor pattern CP9 and the connection pattern 23 is removed. Therefore, the resist pattern RP8a is formed on the conductor pattern CP9 and the gap GP4 and is not formed in other regions, and further, it is not formed on the connection pattern 23 (first connection pattern).

More specifically, similar to the resist films RP3 and RP5 and the resist film for processing the conductor pattern CP7 of the second to fourth embodiments, the resolution of the resist film for processing the conductor pattern CP9 is increased so that the resist film can resolve the dimension GS4 of the gap GP4 and the width W3a of the connection pattern 23 of the source electrode SE5 also in the present embodiment. Thus, similar to the resist films RP3 and RP5, the film thickness of the resist film for processing the conductor pattern CP9 is adjusted to be equal to or smaller than the thickness T1 of the graph of FIG. 56. Note that, in the case of the present embodiment, S1 of the vertical axis of the graph of FIG. 56 corresponds to the dimension GS4 of the gap GP4 and the width W3a of the connection pattern 23 of the source electrode SE5 (i.e., S1=GS4, W3a), and S2 of the vertical axis of the graph corresponds to the smallest one of the interval L4a, the width W1a and the intervals W4a and W5a.

By this means, the resolution limit dimension of the resist film for processing the conductor pattern CP9 becomes smaller than the dimension GS4 of the gap GP4 and the width W3a of the connection pattern 23 of the source electrode SE5, and thus the resist pattern formed by exposing and developing the resist film for processing the conductor pattern CP9 is formed to have the portion corresponding to the gap GP4 and the portion corresponding to the connection pattern 23 of the source electrode SE5. Therefore, the gap GP4 and the connection pattern 23 of the source electrode SE5 can be formed in the conductor pattern CP9.

On the other hand, similar to the resist film RP7 of the fourth embodiment, the resolution of the resist film RP8 of the present embodiment is made lower than the resist film for processing the conductor pattern CP9, thereby achieving the state where the interval L4a, the width W1a and the intervals W4a and W5a can be resolved but the dimension GS4 of the gap GP4 and the width W3a of the connection pattern 23 cannot be resolved. More specifically, the resolution limit dimension of the resist film RP8 in the backside exposure process is made larger than the dimension GS4 of the gap GP4 and the width W3a of the connection pattern 23 and made equal to or smaller than the interval L4a, the width W1a and the intervals W4a and W5a. Therefore, the film thickness of the resist film RP8 is adjusted to be larger than the thickness T1 of the graph of FIG. 56 and equal to or smaller than the thickness T2 of the graph of FIG. 56.

In this manner, the resist film RP8 cannot resolve the portion corresponding to the gap GP4, and the resist pattern RP8a after development has a pattern shape corresponding to (substantially the same as) the conductor pattern CP9 obtained when the portion corresponding to the gap GP4 is not formed and the auxiliary pattern AP5 is coupled to the source electrode SE5 and the drain electrode DE5 by removing the gap GP4.

Further, since the resist film RP8 cannot resolve the width W3a of the connection pattern 23, the resist pattern RP8a after development has a pattern shape corresponding to (substantially the same as) the conductor pattern CP9 obtained when the portion corresponding to the connection pattern 23 of the source electrode SE5 is not formed and the main patterns 21 of the source electrode SE5 adjacent in the Y direction are separated by removing the connection pattern 23.

In this manner, in the present embodiment, even if the backside exposure is performed with using the conductor pattern CP9 including the narrow gap GP4 and the linear connection pattern 23 with a narrow width functioning as a mask (photomask), the resist pattern RP8a without the portion corresponding to the gap GP4 and the connection pattern 23 can be obtained. More specifically, the resist pattern PR8a has a pattern similar to that obtained when the back surface exposure of the resist film RP8 is performed with using the conductor pattern CP9, in which the auxiliary pattern AP5 is coupled to the source electrode SE5 and the drain electrode DE5 by removing the gap GP4 and the main patterns 21 of the source electrode SE5 are separated by removing the connection pattern 23, as the mask.

Therefore, the resist pattern RP8a has a pattern in which the gap corresponding to the gap GP4 and a narrow linear portion corresponding to the connection pattern 23 are not formed and a gate electrode region RP8b corresponding to a region where the gate electrode GE5 is to be formed later and a scanning line region RP8c corresponding to a region where the scanning line GL5 is to be formed later are opened. More specifically, the resist pattern RP8a has a pattern in which the resist film does not exist in the gate electrode region RP8b and the scanning line region RP8c and the resist film exists in other regions, and the resist pattern RP8a exists also on the gap GP4 and the resist pattern RP8a does not exist on the connection pattern 23.

Since the source electrode SE5 and the drain electrode DE5 function as a mask in backside exposure and the gate electrode region RP8b is formed, the position of the gate electrode region RP8b is automatically and accurately aligned with the positions of the source electrode SE5 and the drain electrode DE5, and overlapping like the overlapping region 102 scarcely occurs. Therefore, the gate electrode GE5 to be formed later in the gate electrode region RP8b is accurately aligned with the source electrode SE5 and the drain electrode DE5.

Also, the auxiliary pattern AP5 functions as a mask in backside exposure together with the source electrode SE5 and the drain electrode DE5. Therefore, even if separately prepared photomasks such as the masks MK3 and MK4 are not used, the opening shape (planar shape) of the gate electrode region RP8b and the scanning line region PR8c can be formed to have the desired arbitrary shape by adjusting the pattern shape of the auxiliary pattern AP5 to the desired arbitrary shape. By this means, the planar shape of the gate electrode GE5 and the scanning line GL5 formed later in the gate electrode region RP8b and the scanning line region RP8c can be adjusted to a desired arbitrary shape. Also, since the auxiliary pattern AP5 is insulated from the source electrode SE5 and the drain electrode DE5 by the gap GP4, the pattern shape of the auxiliary pattern AP5 can be adjusted without adversely affecting the source electrode SE5 and the drain electrode DE5.

After forming the resist pattern RP8a in this manner, a metal film is formed on the entire front surface SUB1a of the substrate SUB1, that is, on the resist pattern RP8a and the insulating film GIF5 in the region not covered with the resist pattern RP8a, and the resist pattern RP8a is then dissolved and removed with organic solvent and the like. At this time, the metal film on the resist pattern RP8a is removed together with the resist pattern RP8a, but the metal film formed on the insulating film GIF5 exposed at the bottom of the opening region (gate electrode region RP8b and scanning line region RP8c) of the resist pattern RP8a remains without being removed. The remaining metal film becomes the conductor pattern (metal pattern, second conductor pattern) CP10 including the gate electrode GE5 and the scanning ling GL5 as shown in FIGS. 98 to 101. As the metal film for forming the conductor pattern CP10, the same metal film as that for forming the conductor pattern CP6 of the third embodiment can be used.

By performing the so-called lift-off process as described above, the conductor pattern CP10 (gate electrode GE5 and scanning line GL5) can be formed on the insulating film GIF5 of the region (gate electrode region RP8b and scanning line region RP8c) not covered with the resist pattern RP8a.

As described above, the resist pattern RP8a is formed on (immediately above) the conductor pattern CP9 and on (immediately above) the gap GP4, but is not formed on (immediately above) the connection pattern 23, and the conductor pattern CP10 is formed in the region not covered with the resist pattern RP8a. Thus, the conductor pattern CP10 is formed in alignment with the conductor pattern CP9 on the region where the conductor pattern CP9 is not formed when viewed in a plane, but the conductor pattern CP10 is not formed on (immediately above) the gap GP4. Further, the conductor pattern CP10 is not formed on (immediately above) the conductor pattern CP9 except the connection pattern 23, but is formed on (immediately above) the connection pattern 23. In the present embodiment, the region where the conductor pattern CP9 is not formed when viewed in a plane is the region in which the conductor pattern CP10 is formed in the entire region other than the gap GP4, and the region where the conductor pattern CP9 is formed and the conductor pattern CP10 is formed when viewed in a plane is only the region on (immediately above) the connection pattern 23.

In the present embodiment, the conductor pattern CP10 is formed from the gate electrode (gate electrode pattern) GE5 formed in the gate electrode region RP8b and the scanning line (scanning line pattern) GL5 formed in the scanning line region RP8c, and the gate electrode GE5 and the scanning line GL5 are formed of the conductor layer (conductor pattern) of the same layer. The scanning line GL5 corresponds to the scanning line GL of the circuit diagram of FIG. 15, and the gate electrode GE5 corresponds to the gate electrode of the transistor TR of the circuit diagram of FIG. 15.

In the present embodiment, the connection pattern 23 formed of a narrow linear pattern is provided for the source electrode SE5 in the region where the source electrode SE5 and the scanning line GL5 intersect. Because of the presence of the connection pattern 23, the source electrode SE5 can extend in the Y direction without being disconnected even at the region intersecting the scanning line GL5. Further, the width W3a of the connection pattern 23 of the source electrode SE5 is made smaller than the resolution limit dimension of the resist film RP8 in the backside exposure process, whereby it is possible to prevent the pattern corresponding to the connection pattern 23 of the source electrode SE5 from being formed in the resist pattern RP8a. Thus, the opening of the scanning line region RP8c of the resist pattern RP8a is continuously formed in the X direction without being separated even at the region intersecting the source electrode SE5. Therefore, the scanning line GL5 is formed also above (immediately above) the connection pattern 23 of the source electrode SE5 and is not disconnected even at the region intersecting the source electrode SE5. Therefore, the source electrode SE5 and the scanning line GL5 respectively extend in the X direction and the Y direction, but the source electrode SE5 nor the scanning line GL5 are disconnected at the region where they intersect. Therefore, even if photomasks such as the masks MK3 and MK4 used in the first embodiment are not used, the source electrode SE5 and the scanning line GL5 can be formed so as not to be disconnected even at the region where they intersect.

The gate electrode GE5 and the scanning line GL5 are formed on the insulating film GIF5 in this manner, and the gate electrode GE5 is disposed in alignment with the position of each pair of the drain electrode DE5 and the source electrode SE5 facing thereto. Further, a plurality of scanning lines GL5 are disposed in parallel so as to extend in the X direction without being disconnected even at the intersecting portion with the source electrode SE5, and the ends of the plurality of gate electrodes GE5 are coupled to the scanning line GL5. Thus, the gate electrodes GE5 can be electrically connected via the scanning line GL5.

In this manner, the thin film transistor TR5 in which an overlapping region (corresponding to overlapping region 102) of the gate electrode GE5 and the source electrode SE5 and the drain electrode DE5 scarcely exists and the position of the gate electrode GE5 is accurately aligned with the positions of the source electrode SE5 and the drain electrode DE5 can be formed on the substrate SUB1. The thin film transistor TR5 corresponds to the transistor TR of the circuit diagram of FIG. 15. The gate electrode GE5 is the gate electrode pattern of the transistor TR5, and the scanning line GL5 is the wiring (scanning line) pattern for connecting the gate electrodes of the plurality of transistors TR5. The gate electrode GE5 and the scanning line GL5 can be considered as patterns functioning as electrodes or wirings.

Thereafter, a protective film such as the protective film PT1 of the first embodiment is formed on the insulating film GIF5 so as to cover the conductor pattern CP10 (gate electrode GE5 and scanning line GL5), and a pixel electrode such as the pixel electrode PE1 electrically connected to the drain electrode DE5 is formed on the protective film, but the illustration and the description thereof will be omitted here.

In the present embodiment, the case of fabricating the active matrix circuit by using the auxiliary pattern AP5 of the simplest shape has been described, but the auxiliary pattern AP5 can be formed to have an arbitrary shape according to need.

For instance, the conductor pattern CP9 can be designed by determining the position and the shape of the source electrode SE5 and the drain electrode DE5 to be formed, determining the position and the shape of the gate electrode GE5 and the scanning line GL5, and then disposing the auxiliary pattern AP5 in the remaining region where they are not disposed on the front surface SUB1a of the substrate SUB1. At this time, in order to prevent the auxiliary pattern AP5 from being electrically connected to the source electrode SE5 and the drain electrode DE5, the narrow gap GP4 is formed between the auxiliary pattern AP5 and the source electrode SE5 and the drain electrode DE5. Also, the source electrode SE5 is formed from the connection pattern 23 with a narrow width at the intersecting region of the source electrode SE5 and the signal line SL5.

According to the present embodiment, the active matrix circuit can be formed by using a thin film transistor of bottom gate structure, and substantially the same effects as those of the fourth embodiment can be obtained.

Also, the following effects can be obtained in the fourth embodiment and the present embodiment. That is, in the fourth embodiment and the present embodiment, one pattern and another pattern (corresponding to main patterns 11 adjacent in the X direction in the fourth embodiment and main patterns 21 adjacent in the Y direction in the present embodiment) are coupled by the connection patterns 13 and 23 in the conductor patterns CP7 and CP9 of the lower layer. Further, the widths W3 and W3a of the connection patterns 13 and 23 are made smaller than the resolution limit dimension of the resist films RP7 and RP8 in the backside exposure process so that the connection patterns 13 and 23 do not substantially function as the mask in the backside exposure. By this means, the resist patterns RP7a and RP8a formed in the backside exposure are not formed on the upper side of (immediately above) the connection patterns 13 and 23, whereby the conductor patterns CP8 and CP10 are formed also on the upper side of (immediately above) the connection pattern 13. Therefore, the conductor patterns CP7 and CP9 of the lower layer and the conductor patterns CP8 and CP10 of the upper layer can both be formed so as to be partially overlapped by backside exposure even if a separately prepared photomask is not used. Accordingly, the degree of freedom of design of the patterns of the electrode and the wiring formed by the conductor patterns CP7, CP8, CP9 and CP10 can be significantly enhanced. For instance, the scanning lines GL4 and GL5 and the signal lines SL4 and SL5 can be formed so as to intersect with each other. Since the wirings can be intersected, the extension of wirings and the connection to an upper layer wiring to avoid the intersection become unnecessary, and the semiconductor device can be miniaturized. Further, a complicated circuit configuration can be formed on the substrate SUB1, and high-performance semiconductor device can be obtained.

### Sixth Embodiment

A method of fabricating a ring oscillator circuit will be described in the present embodiment as another example of a circuit using a thin film transistor.

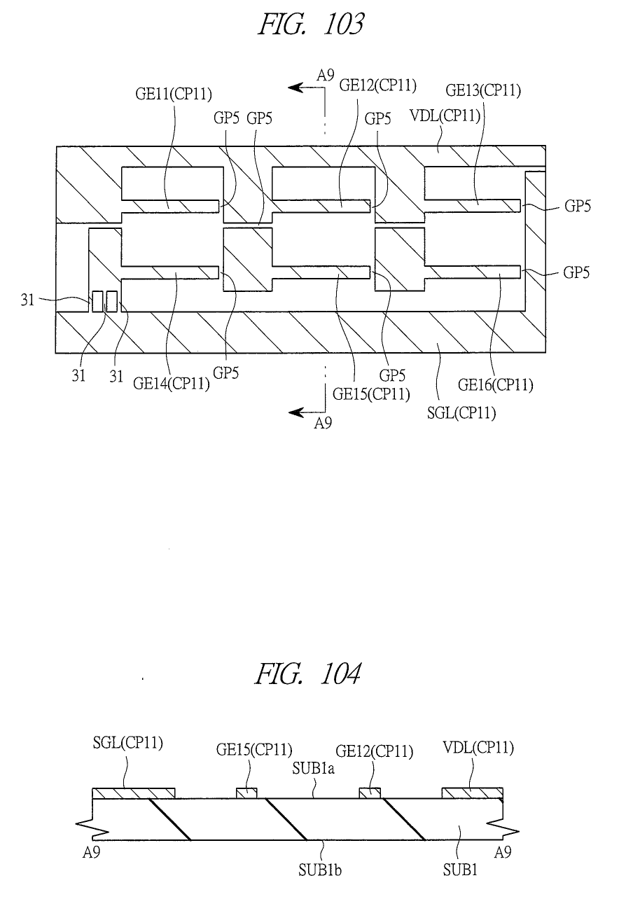

FIG. 102 is a circuit diagram of a three-stage ring oscillator circuit using a saturated MOS load inverter. The method of fabricating the ring oscillator circuit as shown in FIG. 102 using a transistor similar to the thin film transistor TR2 described in the second embodiment will be described with reference to FIG. 103 to FIG. 114.

FIGS. 103 to 114 include plan views (plan view of principal part) and cross sectional views (cross sectional view of principal part) in the manufacturing process of the ring oscillator circuit using the thin film transistor of bottom gate structure having substantially the same structure as the thin film transistor TR2 of the second embodiment as a single transistor. Of FIGS. 103 to 114, FIGS. 103, 105, 107, 109, 111 and 113 are plan views showing different processing steps of the same region. Also, FIGS. 104, 106, 108, 110, 112 and 114 correspond to cross sectional views of the line A9-A9 of FIGS. 103, 105, 107, 109, 111 and 113, respectively.

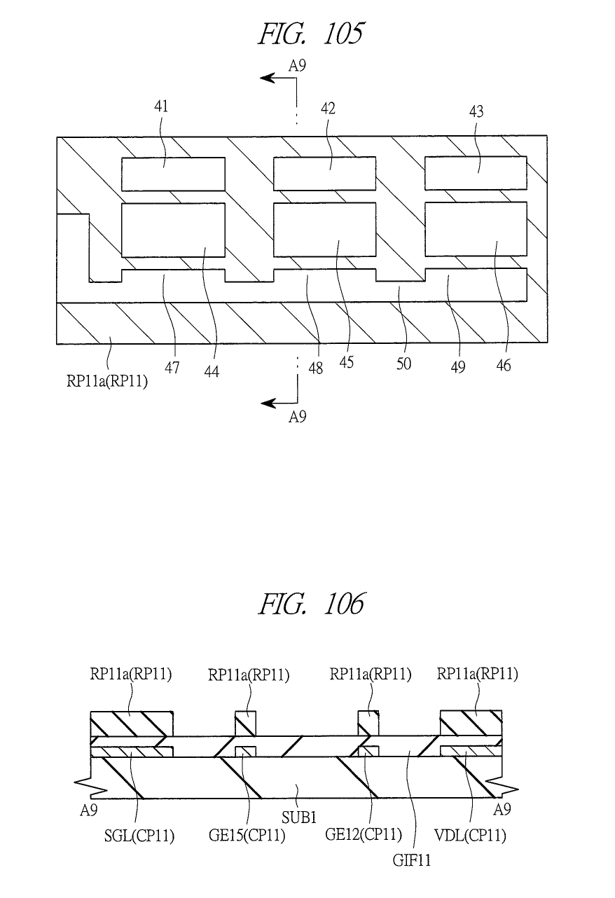

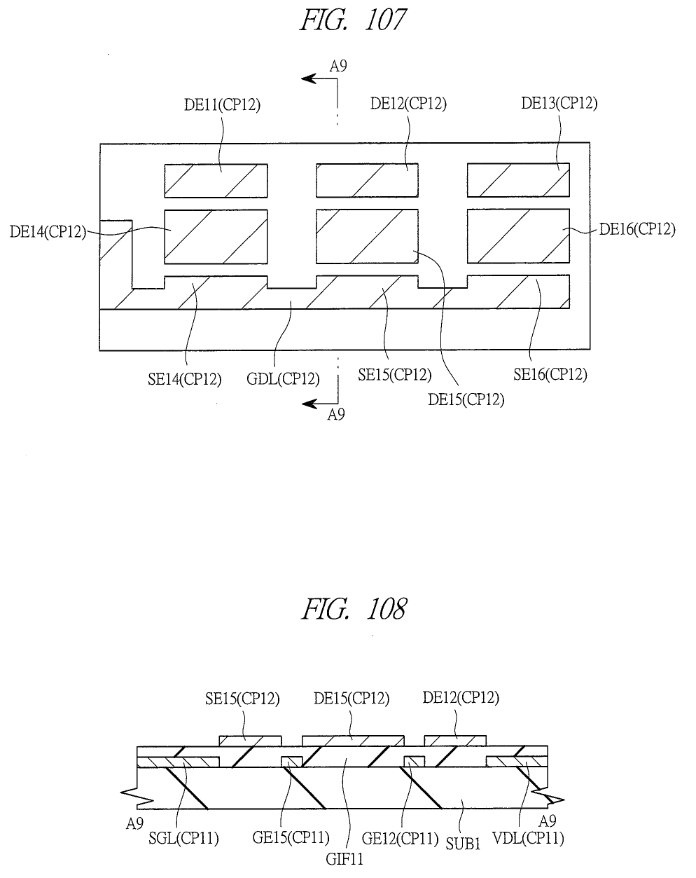

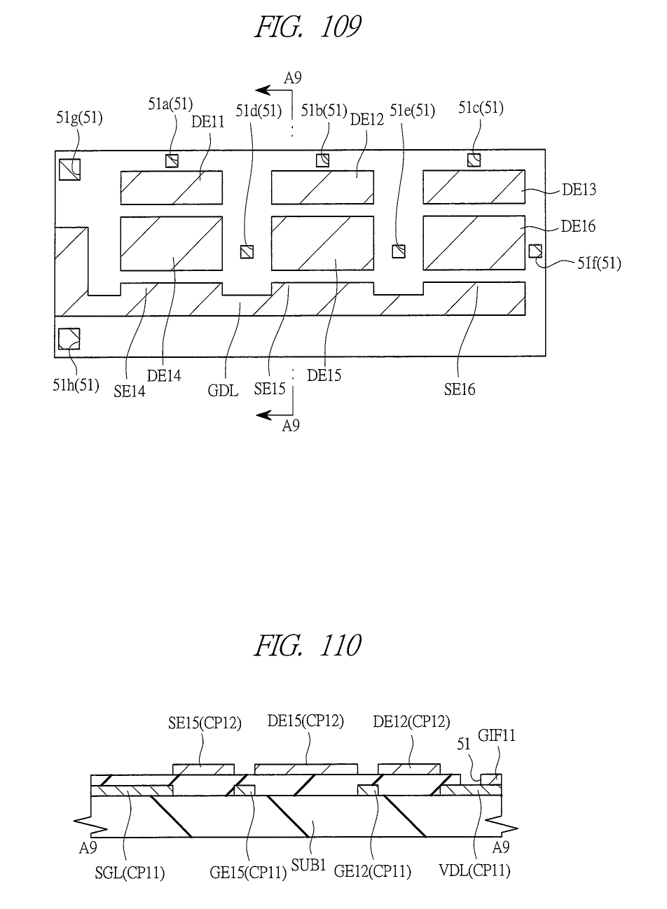

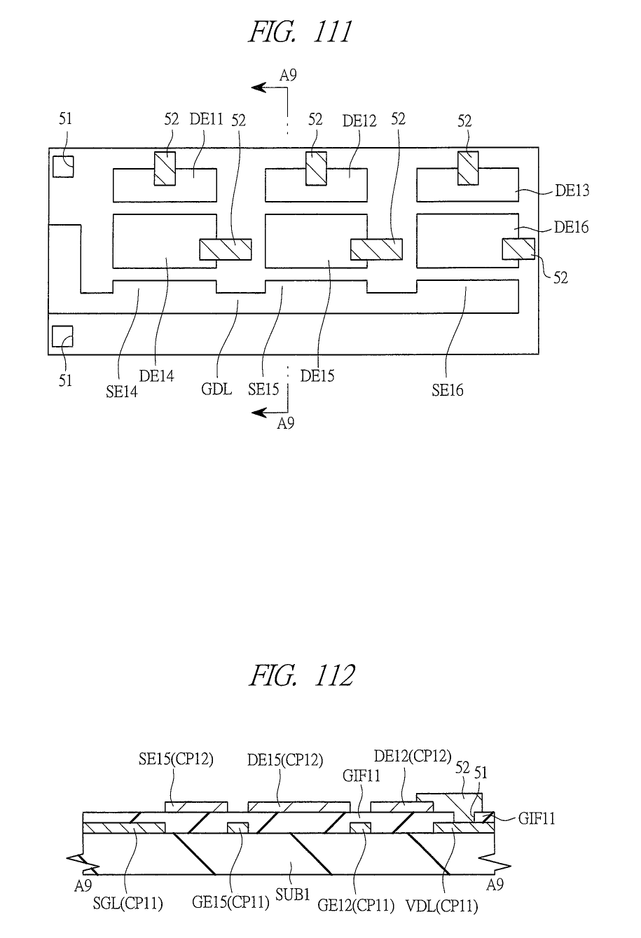

Note that FIGS. 104, 106, 108, 110, 112 and 114 are plan views, but in order to make the drawings easy to see, hatching is applied to that corresponding to the conductor pattern CP11 in FIG. 104, to the resist pattern RP11a in FIG. 105, and to that corresponding to the conductor pattern CP12 in FIG. 107. Also, hatching is applied to those corresponding to the conductor pattern CP12 and the conductor pattern CP11 exposed from the hole 51 in FIG. 109, to that corresponding to the conductor pattern 52 in FIG. 111, and to the semiconductor layer SM11 in FIG. 113.

First, the substrate SUB1 is prepared. Then, a metal film made of aluminum and the like is formed on the substrate SUB1 in the same manner as that of forming the conductor patterns CP3, CP5, CP7 and CP9 in the second to fifth embodiments, and the metal film is patterned by using the photolithography method and the etching method to form the conductor pattern CP11 on the substrate SUB1 as shown in FIGS. 103 and 104.

The conductor pattern CP11 includes a gate electrode GE11 of an initial stage load transistor TR11, a gate electrode GE12 of a second stage load transistor TR12, a gate electrode GE13 of a third stage load transistor TR13, a power supply line VDL, a gate electrode GE14 of an initial stage drive transistor TR14, a gate electrode GE15 of a second stage drive transistor TR15, a gate electrode GE16 of a third stage drive transistor TR16, and a signal line SGL.

The gate electrodes GE1, GE12 and GE13 of the load transistors TR11, TR12 and TR13 are connected to the power supply line VDL and electrically connected to each other. The gate electrode GE14 (third pattern) of the initial stage drive transistor TR14 is connected to the signal line SGL (fourth pattern) by the connection pattern (connecting part) 31 formed of a line pattern (linear pattern) with a narrow width like the connection patterns 13 and 23 of the fourth and fifth embodiments. The configuration of the connection pattern 31 is substantially the same as the connection patterns 13 and 23 of the fourth and fifth embodiments, and thus the description thereof will be omitted here.

A gap GP5 corresponding to the gaps GP1 to GP4 is provided to the conductor pattern CP11. The gap GP5 is a region where the conductor pattern CP11 is not formed. More specifically, the narrow gap GP5 is disposed between the gate electrode GE11 and the gate electrode GE12, between the gate electrode GE12 and the gate electrode GE13, between the gate electrode GE13 and the signal line SGL, between the power supply line VDL and the signal line SGL, between the gate electrode GE14 and the gate electrode GE15, and between the gate electrode GE15 and the gate electrode GE16. Further, the narrow gap GP5 is also disposed between the gate electrode GE16 and the signal line SGL, between the gate electrode GE11 and the gate electrode GE14, between the gate electrode GE12 and the gate electrode GE15, and between the gate electrode GE13 and the gate electrode GE16. Similar to the second to fifth embodiments, the dimension (interval, width) of each gap GP5 is smaller (narrower) than the gate length of the gate electrodes GE11 to GE16 also in the present embodiment.

As shown in FIGS. 105 and 106, after forming the conductor pattern CP11, the translucent insulating film (gate insulating film) GIF11 is formed on the entire front surface SUB1a of the substrate SUB1 so as to cover the conductor pattern CP11. The insulating film GIF11 is an insulating film for forming a gate insulating film. As the material for the insulating film GIF11, the same material as that of the insulating film GIF2 of the second embodiment can be used.

Next, a positive resist film (photoresist film) RP11 is formed on the entire front surface SUB1a of the substrate SUB1, that is, on the insulating film GIF11.

Next, the light is irradiated from the back surface SUB1b side of the substrate SUB1 to expose the resist film RP11 (backside exposure) in the same manner as the exposure of the resist films RP4, RP6, RP7 and RP8 of the second to fifth embodiments. In the backside exposure process, only the conductor pattern CP11 formed on the substrate SUB1 functions as a mask, the exposure photomask is not separately used, and the exposure from the front surface SUB1a side of the substrate SUB1 is not performed.

Thereafter, by developing the resist film RP11, a resist pattern (photoresist pattern) RP11a as shown in FIGS. 105 and 106 is formed on the insulating film GIF11.

In the backside exposure of the resist film RP11, the light irradiated from the back surface SUB1b side of the substrate SUB1 is transmitted through the substrate SUB1 and the insulating film GIF11 and irradiated onto the resist film RP11, and the conductor pattern CP11 functions as a mask similar to the second to fifth embodiments.

Similar to the resist films RP4, RP6, RP7 and RP8 of the second to the fifth embodiments, the resist film RP11 is adjusted so that it can resolve the gate length of the gate electrodes GE11 to GE16 but cannot resolve the dimension of the gap GP5 and the width of the connection pattern 31. More specifically, the resolution limit dimension of the resist film RP11 in the backside exposure process is made larger than the dimension of the gap GP5 and the width of the connection pattern 31 and equal to or smaller than the gate length of the gate electrodes GE11 to GE16. Thus, the film thickness of the resist film RP11 is adjusted to be larger than the thickness T1 of the graph of FIG. 56 and equal to or smaller than the thickness T2 of the graph of FIG. 56. Note that, in the present embodiment, S1 of the vertical axis of the graph of FIG. 56 corresponds to the dimension of the gap GP5 and the width of the connection pattern 31, and S2 of the vertical axis of the graph corresponds to the smallest one of the gate lengths of the gate electrodes GE11 to GE16.

By this means, for the reasons similar to the second to fifth embodiments, the resist pattern RP11a has the same pattern as the conductor pattern CP11 obtained when the gap GP5 and the connection pattern 31 are not provided (i.e., when the conductor pattern is disposed for the gap GP5 and the conductor pattern of the connection pattern 31 is removed in the conductor pattern CP11). More specifically, the resist pattern RP11a has a pattern corresponding to (same as) the conductor pattern CP11 obtained when the gate electrodes GE1, GE12, GE13, GE14, GE15 and GE16, the signal line SGL and the power supply line VDL (first and second patterns) are coupled by removing the gap GP5 and the gate electrode GE14 (third pattern) and the signal line SGL (fourth pattern) are separated by removing the connection pattern 31.

The resist pattern RP11a is a pattern having openings in the drain electrode regions 41, 42, 43, 44, 45 and 46 of the transistors TR11, TR12, TR13, TR14, TR15 and TR16, the source electrode regions 47, 48 and 49 of the transistors TR14, TR15 and TR16 and the ground line region 50.

Next, in the same manner as that of forming the conductor patterns CP4, CP6, CP8 and CP10 in the second to fifth embodiments, the conductor pattern CP12 including the drain electrodes DE11, DE12, DE13, DE14, DE15 and DE16, the source electrodes SE14, SE15 and SE16 and the ground line GDL is formed on the insulating film GIF11 of the region not covered with the resist pattern RP11a by performing the lift-off process. The drain electrodes DE11, DE12, DE13, DE14, DE15 and DE16 are respectively the drain electrodes of the transistors TR11, TR12, TR13, TR14, TR15 and TR16 and are respectively formed in the drain electrode regions 41, 42, 43, 44, 45 and 46. Also, the source electrodes SE14, SE15 and SE16 are respectively the source electrodes of the transistors TR14, TR15 and TR16 and are respectively formed in the source electrode regions 47, 48 and 49. Further, the ground line GDL is formed in the ground line region 50. The source electrodes SE14, SE15 and SE16 are connected to the ground line GDL and electrically connected to each other. Further, the drain electrodes DE11, DE12 and DE13 also serve as the source electrodes of the transistors TR11, TR12 and TR13.

Next, the electrodes (electrodes formed of conductor pattern CP12) exposed on the front surface side of the current substrate SUB and the electrodes (electrodes formed of conductor pattern CP11) below the insulating film FIG11 are made to be electrically connected. Thus, as shown in FIGS. 109 and 110, holes (opening, through hole) 51 are formed in some parts of the insulating film GIF11 with laser, and the electrodes (electrodes formed of conductor pattern CP11) below the insulating film GIF11 are exposed form the holes 51. In this case, a hole 51a for connecting the drain electrode DE11 and the power supply line VDL, a hole 51b for connecting the drain electrode DE12 and the power supply line VDL, a hole 51c for connecting the drain electrode DE13 and the power supply line VDL, a hole 51d for connecting the drain electrode DE14 and the gate electrode GE15, a hole 51e for connecting the drain electrode DE15 and the gate electrode GE16, and a hole 51f for connecting the drain electrode DE16 and the signal line SGL are formed. Furthermore, holes 51g and 51h are formed so as to extend the power supply line VDL and the signal line SGL.

Next, as shown in FIGS. 111 and 112, conductor patterns (connection line) 52 for electrically connecting the electrodes (electrodes formed of conductor pattern CP12) exposed on the front surface side of the substrate SUB and the electrodes (electrodes formed of conductor pattern CP11) exposed from the holes 51 are formed. The conductor pattern 52 can be formed by, for instance, the inkjet printing method using silver ink. By the conductor patterns 52, the drain electrode DE11 and the power supply line VDL are connected, the drain electrode DE12 and the power supply line VDL are connected, the drain electrode DE13 and the power supply line VDL are connected, the drain electrode DE14 and the gate electrode GE15 are connected, the drain electrode DE15 and the gate electrode GE16 are connected, and the drain electrode DE16 and the signal line SGL are connected.

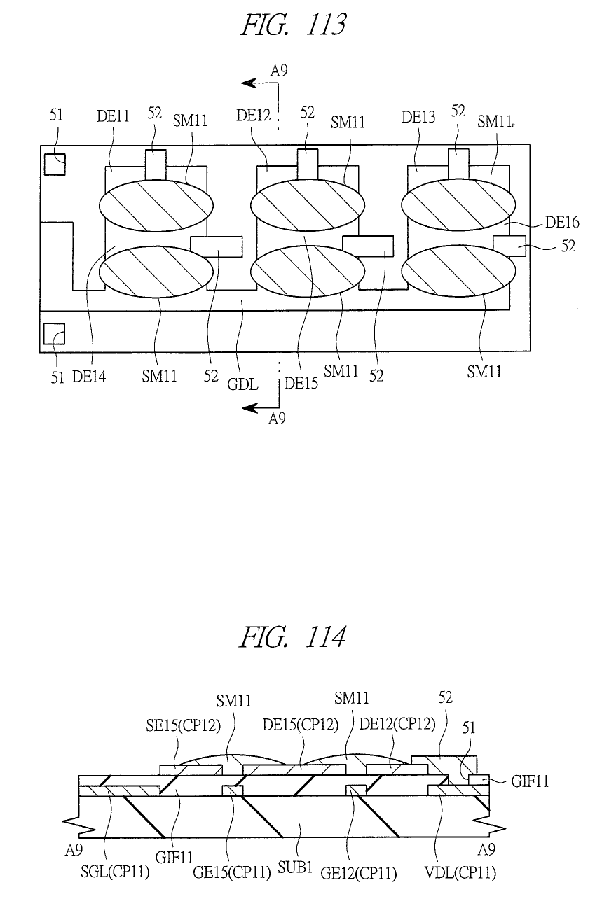

Thereafter, as shown in FIGS. 113 and 114, the semiconductor layer (semiconductor pattern) SM11 is formed in the same manner as the semiconductor layer SM2 on the upper side of each of the electrodes GE11 to GE16. As the material for forming the semiconductor layer SM11, the same material as the semiconductor layer SM2 of the second embodiment can be used. In this manner, the ring oscillator circuit as shown in FIG. 102 can be formed on the substrate SUB1.

In the present embodiment, the auxiliary pattern of an electrically unnecessary isolated pattern is not formed, but the gap S5 and the connection pattern 31 similar to the gaps GP1 to GP4 and the connection patterns 13 and 23 of the second to fifth embodiments are disposed in the conductor pattern CP11 of the lower layer, and the conductor pattern CP11 functions as the mask in the backside exposure to form the resist pattern RP11a, whereby the conductor pattern CP12 of the upper layer is formed. Therefore, in the conductor pattern CP11, respective patterns can be separated (insulated) by the gap S5 or connected by the connection pattern 31 in accordance with the necessity in the circuit. On the other hand, the resist pattern RP11a and the conductor pattern CP12 formed by using the same can be formed to have the same pattern as the conductor pattern CP11 obtained when the gap GP5 and the connection pattern 31 are removed, and the outer shape of the conductor pattern CP12 can be appropriately defined even if the conductor pattern CP11 includes the gap S5 and the connection pattern 31. Accordingly, the electrode and the wiring formed from the conductor pattern CP12 can be aligned with the electrode and the wiring formed from the conductor pattern CP11. Further, unnecessary parasitic component can be suppressed by preventing the conductor patterns from being overlapped as much as possible.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is suitably applied to the semiconductor device and the manufacturing method of the same.

What is claimed is:

1. A semiconductor device comprising:
a substrate;
a first conductor pattern formed on the substrate and including a first pattern and a second pattern spaced apart from each other via a gap;
an insulating film formed on the substrate so as to cover the first conductor pattern; and
a second conductor pattern formed on the insulating film,
wherein the second conductor pattern is formed in alignment with the first conductor pattern on a region where the first conductor pattern is not formed, and the second conductor pattern is not formed on the gap.

2. The semiconductor device according to claim 1,
wherein the first pattern is a pattern functioning as an electrode or a wiring, and
the second pattern is an isolated pattern and is a pattern considered as a floating potential.

3. The semiconductor device according to claim 2,
wherein the substrate and the insulating film have translucency.

4. The semiconductor device according to claim 3,
wherein the first pattern includes a gate electrode pattern,
the insulating film is an insulating film functioning as a gate insulating film,
the second conductor pattern includes a source electrode pattern and a drain electrode pattern, and
a dimension of the gap is smaller than a gate length of the gate electrode pattern.

5. The semiconductor device according to claim 4, further comprising:
a semiconductor layer formed on the insulating film between the source electrode pattern and the drain electrode pattern.

6. The semiconductor device according to claim 5,
wherein a dimension in a channel width direction of the semiconductor layer is larger than a dimension in the channel width direction of a portion of the gate electrode pattern positioned between the source electrode pattern and the drain electrode pattern.

7. The semiconductor device according to claim 3,
wherein the first pattern includes a source electrode pattern and a drain electrode pattern,
the insulating film is an insulating film functioning as a gate insulating film,
the second conductor pattern includes a gate electrode pattern, and
a dimension of the gap is smaller than a gate length of the gate electrode pattern.

8. The semiconductor device according to claim 7, further comprising:
a semiconductor layer formed on the substrate between the source electrode pattern and the drain electrode pattern,
wherein the insulating film is formed on the substrate so as to cover the first conductor pattern and the semiconductor layer.

9. A manufacturing method of a semiconductor device comprising the steps of:
(a) preparing a substrate;
(b) forming a first conductor pattern including a first pattern and a second pattern spaced apart from each other via a gap on the substrate;
(c) forming an insulating film on the substrate so as to cover the first conductor pattern;
(d) forming a first resist film on the insulating film;
(e) exposing the first resist film from a main surface side of the substrate on a side opposite to the side where the first conductor pattern is formed and then developing the first resist film, thereby forming a first resist pattern; and
(f) after the step (e), forming a first metal film on the insulating film not covered with the first resist pattern and then removing the first resist pattern, thereby forming a second conductor pattern formed of the first metal film on the insulating film in a region not covered with the first resist pattern,
wherein the first resist pattern has a pattern shape corresponding to the first conductor pattern obtained when the first pattern and the second pattern are coupled by removing the gap.

10. The manufacturing method of a semiconductor device according to claim 9,
wherein in the step (e), an exposure light is irradiated onto the first resist film through the substrate and the insulating film, and the first conductor pattern functions as an exposure mask.

11. The manufacturing method of a semiconductor device according to claim 10,
wherein the first pattern is a pattern functioning as an electrode or a wiring, and
the second pattern is an isolated pattern and is a pattern considered as a floating potential.

12. The manufacturing method of a semiconductor device according to claim 10,
wherein the first resist film is a positive resist film,
the first resist pattern is formed on the first conductor pattern and the gap, and
the second conductor pattern is formed in alignment with the first conductor pattern and the second conductor pattern is not formed on the gap.

13. The manufacturing method of a semiconductor device according to claim 10,
wherein a resolution limit dimension of the resist film is larger than a dimension of the gap.

14. The manufacturing method of a semiconductor device according to claim 10,
wherein the first pattern includes a gate electrode pattern and the second conductor pattern includes a source electrode pattern and a drain electrode pattern, or the first pattern includes a source electrode pattern and a drain electrode pattern and the second conductor pattern includes a gate electrode pattern.

15. The manufacturing method of a semiconductor device according to claim 10,
wherein the step (b) includes:
(b1) forming a second metal film on the substrate;
(b2) forming a second resist film on the second metal film;
(b3) exposing and developing the second resist film, thereby forming a second resist pattern; and
(b4) patterning the second metal film by etching using the second resist pattern as an etching mask, thereby forming the first conductor pattern, and
resolution of the first resist film is lower than that of the second resist film.

16. A manufacturing method of a semiconductor device comprising the steps of:
(a) preparing a substrate;
(b) forming a first conductor pattern including a third pattern, a fourth pattern and a first connection pattern which couples the third and fourth patterns on the substrate;
(c) forming an insulating film on the substrate so as to cover the first conductor pattern;
(d) forming a first resist film on the insulating film;
(e) exposing the first resist film from a main surface side of the substrate on a side opposite to the side where the first conductor pattern is formed and then developing the first resist film, thereby forming a first resist pattern; and
(f) after the step (e), forming a first metal film on the insulating film not covered with the first resist pattern and then removing the first resist pattern, thereby forming a second conductor pattern formed of the first metal film on the insulating film in a region not covered with the first resist pattern,
wherein the first resist pattern has a pattern shape corresponding to the first conductor pattern obtained when the third pattern and the fourth pattern are separated by removing the first connection pattern.

17. The manufacturing method of a semiconductor device according to claim 16,
wherein in the step (e), an exposure light is irradiated onto the first resist film through the substrate and the insulating film, and the first conductor pattern functions as an exposure mask.

18. The manufacturing method of a semiconductor device according to claim 17,
wherein the third pattern and the fourth pattern are patterns functioning as electrodes or wirings.

19. The manufacturing method of a semiconductor device according to claim 17,
wherein the first resist film is a positive resist film,
the first resist pattern is formed on the first conductor pattern but is not formed on the first connection pattern, and
the second conductor pattern is formed in alignment with the first conductor pattern and the second conductor pattern is formed also on the first connection pattern.

20. The manufacturing method of a semiconductor device according to claim 17,
wherein a resolution limit dimension of the resist film is larger than a width of the first connection pattern.
